(19) United States
(12) Patent Application Publication
(10) Pub. No.: US 2023/0287016 A1
(43) Pub. Date: Sep. 14, 2023

(54) FUSED POLYCYCLIC COMPOUND AND LIGHT EMITTING DEVICE INCLUDING THE SAME

(71) Applicants: Samsung Display Co., Ltd., Yongin-si (KR); Seoul National University R&DB Foundation, Seoul (KR); University-Industry Cooperation Group of Kyung Hee University, Yongin-si (KR)

(72) Inventors: MI EUN JUN, Hwaseong-si (KR); CHANGWOONG CHU, Hwaseong-si (KR); Soo Young PARK, Seoul (KR); Jongwook PARK, Seoul (KR); Dongmin PARK, Seoul (KR); Chi Hyun RYOO, Seoul (KR); Seyoung JUNG, Seoul (KR)

(73) Assignees: Samsung Display Co., Ltd., Yongin-si (KR); Seoul National University R&DB Foundation, Seoul (KR); University-Industry Cooperation Group of Kyung Hee University, Yongin-si (KR)

(21) Appl. No.: 18/104,988

(22) Filed: Feb. 2, 2023

(30) Foreign Application Priority Data
Mar. 11, 2022 (KR) 10-2022-0031001

(51) Int. Cl. C07F 7/08; H10K 50/11; H10K 85/60; H10K 85/40; H10K 85/30

(52) U.S. Cl. CPC C07F 7/0812; H10K 50/11; H10K 85/658; H10K 85/40; H10K 85/654; H10K 85/6572; H10K 85/346

(57) ABSTRACT

Embodiments provide a light emitting device that includes a first electrode, a second electrode facing the first electrode, and an emission layer disposed between the first electrode and the second electrode, wherein the emission layer includes a first compound represented by Formula 1, which is explained in the specification:

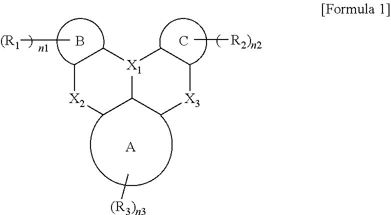

### CROSS-REFERENCE TO RELATED APPLICATION(S)

This application claims priority to and benefits of Korean Patent Application No. 10-2022-0031001 under 35 U.S.C. § 119, filed on Mar. 11, 2022, in the Korean Intellectual Property Office, the entire contents of which are incorporated herein by reference.

### BACKGROUND

### 1. Technical Field

The disclosure relates to a light emitting device including a novel fused polycyclic compound used as a luminescent material.

### 2. Description of the Related Art

Active development continues for an organic electroluminescence display apparatus as an image display apparatus. Unlike liquid crystal display apparatuses and the like, the organic electroluminescence display apparatus is a so-called self-luminescent display apparatus in which holes and electrons respectively injected from a first electrode and a second electrode recombine in an emission layer, so that a luminescent material in the emission layer emits light to achieve display.

In the application of an organic electroluminescence device to a display apparatus, there is a demand for an organic electroluminescence device having a low driving voltage, high luminous efficiency, and a long service life, and continuous development is required on materials for an organic electroluminescence device which are capable of stably attaining such characteristics.

In order to implement an organic electroluminescence device with high efficiency, technologies pertaining to phosphorescence emission which uses energy in a triplet state or to delayed fluorescence emission which uses the generation of singlet excitons by the collision of triplet excitons (triplet-triplet annihilation, TTA) are being developed, and development is currently directed to a material for thermally activated delayed fluorescence (TADF) using a delayed fluorescence mechanism.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting device in which luminous efficiency and a device service life are improved.

The disclosure also provides a fused polycyclic compound capable of improving luminous efficiency and a device service life of a light emitting device.

An embodiment provides a light emitting device which may include a first electrode, a second electrode facing the first electrode, and an emission layer disposed between the first electrode and the second electrode, wherein the emission layer includes a first compound represented by Formula 1:

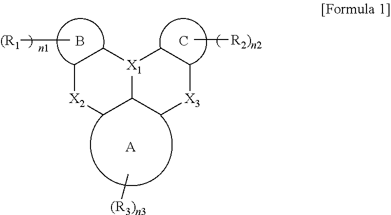

In Formula 1, A, B, and C may each independently be a monocyclic aromatic hydrocarbon ring having 6 to 30 ring-forming carbon atoms, or a monocyclic aromatic heterocycle having 2 to 30 ring-forming carbon atoms; X₁ may be B, P, P═O, P═S, Al, Ga, As, Si(R₄), or Ge(R₅); X₂ and X₃ may each independently be O, S, Se, or N(R₆); R₁ to R₃ may each independently be a hydrogen atom, a deuterium atom, a halogen atom, a substituted or unsubstituted alkyl group having 1 to 20 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, a group represented by Formula 2, or may be bonded to an adjacent group to form a ring; at least one of R₁ to R₃ may each independently be a group represented by Formula 2; R₄ to R₆ may each independently be a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring; n1 and n2 may each independently be an integer from 1 to 4; and n3 may be an integer from 1 to 3.

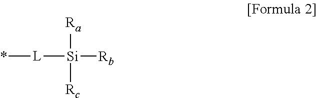

In Formula 2, Rₐ to R_{c} may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; L may be a substituted or unsubstituted arylene group having 6 to 30 ring-forming carbon atoms, or a substituted or unsubstituted heteroarylene group having 2 to 30 ring-forming carbon atoms; and [symbol] represents a bonding site to Formula 1.

In an embodiment, the first compound represented by Formula 1 may be represented by Formula 3:

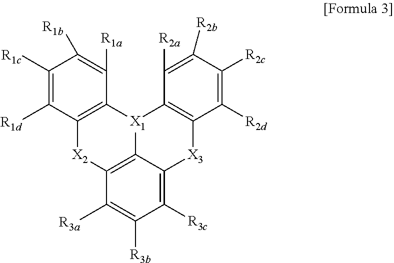

In Formula 3, R₁ₐ to R_{1d}, R₂ₐ to R_{2d}, and R₃ₐ to R_{3c} may each independently be a hydrogen atom, a deuterium atom, a halogen atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, a group represented by Formula 2, or may be bonded to an adjacent group to form a ring; and at least one of R₁ₐ to R_{1d}, R₂ₐ to R_{2d}, and R₃ₐ to R_{3c} may each independently be a group represented by Formula 2.

In Formula 3, X₁ to X₃ are each the same as defined in Formula 1.

In an embodiment, the first compound represented by Formula 3 may be represented by any one of Formula 4-1 to Formula 4-4:

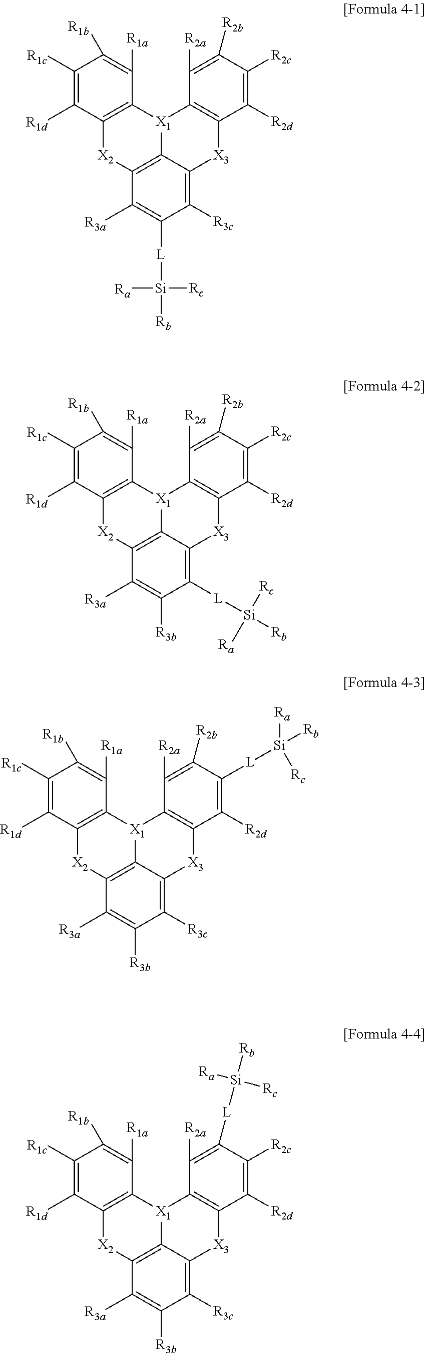

In Formula 4-1 to Formula 4-4, X₁ to X₃, L, Rₐ to R_{c}, R₁ₐ to R_{1d}, R₂ₐ to R_{2d}, and R₃ₐ to R_{3c} are each the same as defined in Formula 1, Formula 2, and Formula 3.

In an embodiment, the first compound represented by Formula 3 may be represented by any one of Formula 5-1 to Formula 5-4:

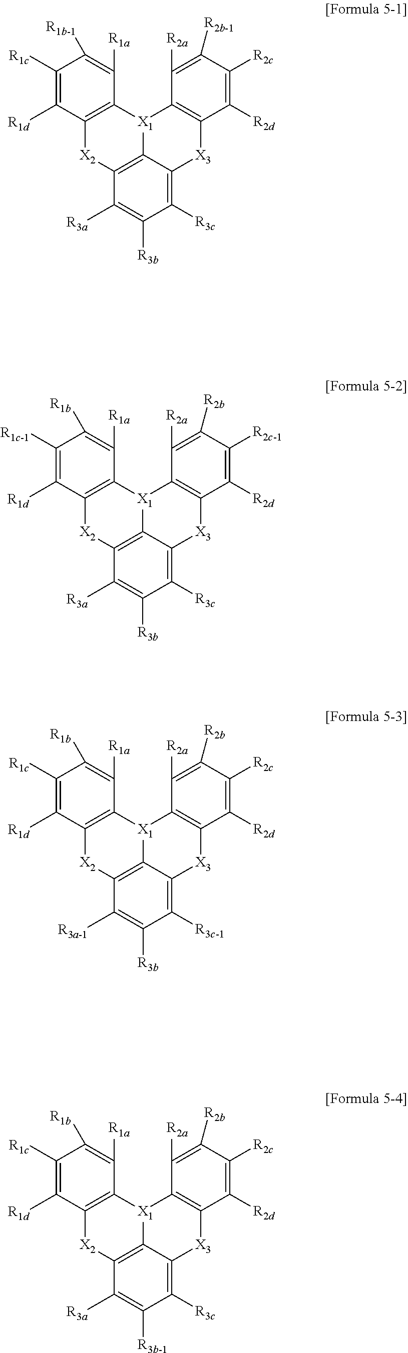

In Formula 5-1 to Formula 5-4, R_{1b-1}, R_{2b-1}, R_{1c-1}, R_{2c-1}, and R₃ₐ₋₁ to R_{3c-1} may each independently be a substituted or unsubstituted alkyl group having 1 to 10 carbon atoms, a substituted or unsubstituted aryl group having 6 to 30 ring-forming carbon atoms, a substituted or unsubstituted heteroaryl group having 2 to 30 ring-forming carbon atoms, or a group represented by Formula 2.

In Formula 5-1 to Formula 5-4, X₁ to X₃, R₁ₐ to R_{1d}, R₂ₐ to R_{2d}, and R₃ₐ to R_{3c} are each the same as defined in Formula 1 and Formula 3.

In an embodiment, the first compound represented by Formula 3 may be represented by any one of Formula 6-1 to Formula 6-4:

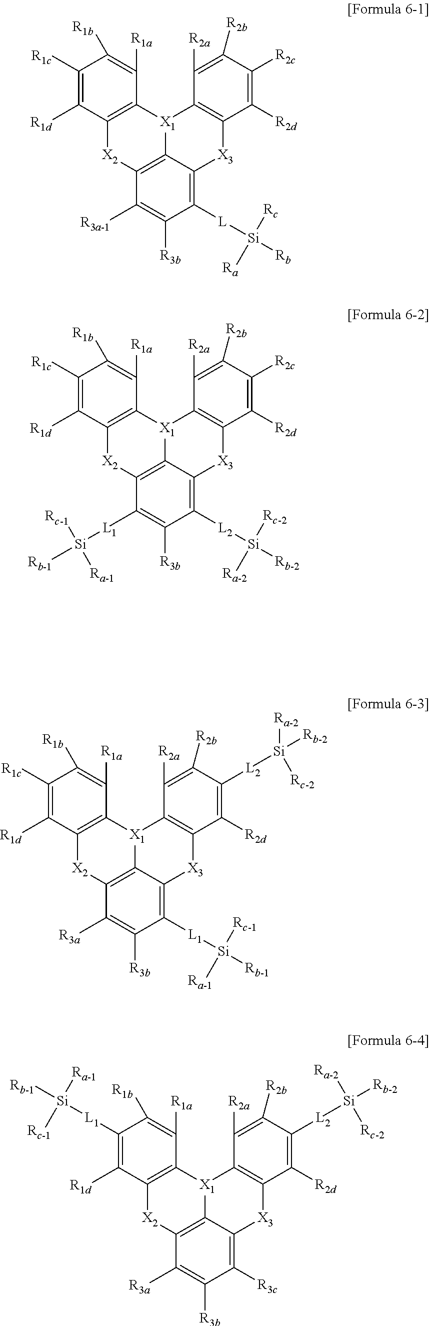

In Formula 6-1 to Formula 64, R₃ₐ₋₁ may be a substituted or unsubstituted aryl group having 6 to 30 ring-forming carbon atoms, or a substituted or unsubstituted heteroaryl group having 2 to 30 ring-forming carbon atoms; Rₐ₋₁ to R_{c-1} and Rₐ₋₂ to R_{c-2} may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and L₁ and L₂ may each independently be a substituted or unsubstituted arylene group having 6 to 30 ring-forming carbon atoms, or a substituted or unsubstituted heteroarylene group having 2 to 30 ring-forming carbon atoms.

In Formula 6-1 to Formula 6-4, X₁ to X₃, L, Rₐ to R_{c}, R₁ₐ to R_{1d}, R₂ₐ to R_{2d}, and R₃ₐ to R_{3c} are each the same as defined in Formula 1, Formula 2, and Formula 3.

In an embodiment, in Formula 6-1, R₃ₐ₋₁ may be a group represented by any one of Formula 7-1 to Formula 7-4:

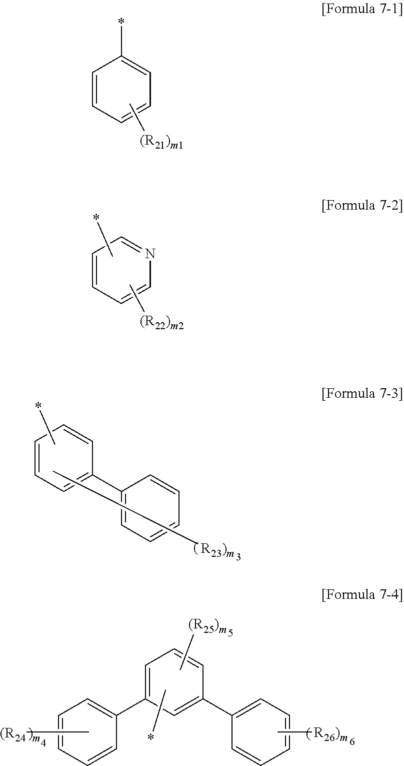

In Formula 7-1 to Formula 7-4, R₂₁ to R₂₆ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; m₁, m₄, and m₆ may each independently be an integer from 0 to 5; m₂ may be an integer from 0 to 4; m₃ may be an integer from 0 to 9; and m₅ may be an integer from 0 to 3.

In an embodiment, the first compound represented by Formula 3 may be represented by any one of Formula 8-1 to Formula 8-3:

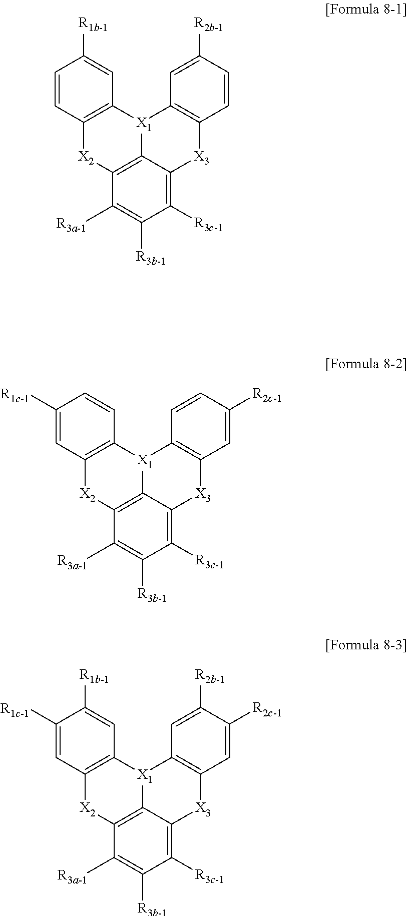

In Formula 8-1 to Formula 8-3, R_{1b-1}, R_{2b-1}, R_{1c-1}, R_{2c-1}, and R₃ₐ₋₁ to R_{3c-1} may each independently be a hydrogen atom, a substituted or unsubstituted t-butyl group, a substituted or unsubstituted phenyl group, a substituted or unsubstituted biphenyl group, a substituted or unsubstituted terphenyl group, a substituted or unsubstituted pyridine group, a substituted or unsubstituted carbazole group, or a group represented by Formula 2; and at least one of R_{1b-1}, R_{2b-1}, R_{1c-1}, R_{2c-1}, and R₃ₐ₋₁ to R_{3c-1} may each independently be a group represented by Formula 2.

In Formula 8-1 to Formula 8-3 above, X₁ to X₃ are each the same as defined in Formula 1.

In an embodiment, the first compound represented by Formula 3 may be represented by any one of Formula 9-1 to Formula 9-6:

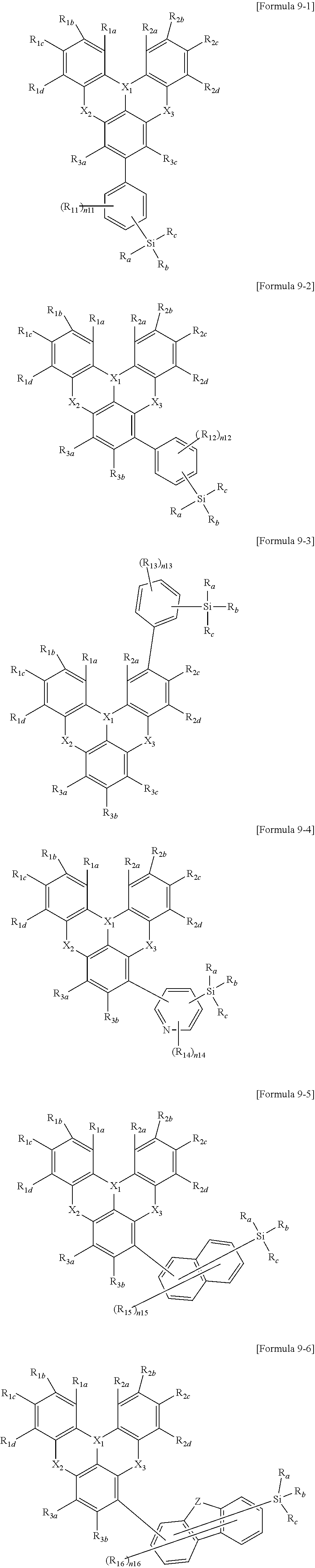

In Formula 9-1 to Formula 9-6, Z may be N(R₁₇), O, or S; R₁₁ to R₁₇ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; n11 to n13 may each independently be an integer from 0 to 4; n14 may be an integer from 0 to 3; and n15 and n16 may each independently be an integer from 0 to 6.

In Formula 9-1 to Formula 9-6, X₁ to X₃, Rₐ to R_{c}, R₁ₐ to R_{1d}, R₂ₐ to R_{2d}, and R₃ₐ to R_{3c} are each the same as defined in Formula 1, Formula 2, and Formula 3.

In an embodiment, the first compound represented by Formula 1 may be represented by any one of Formula 10-1 to Formula 10-6:

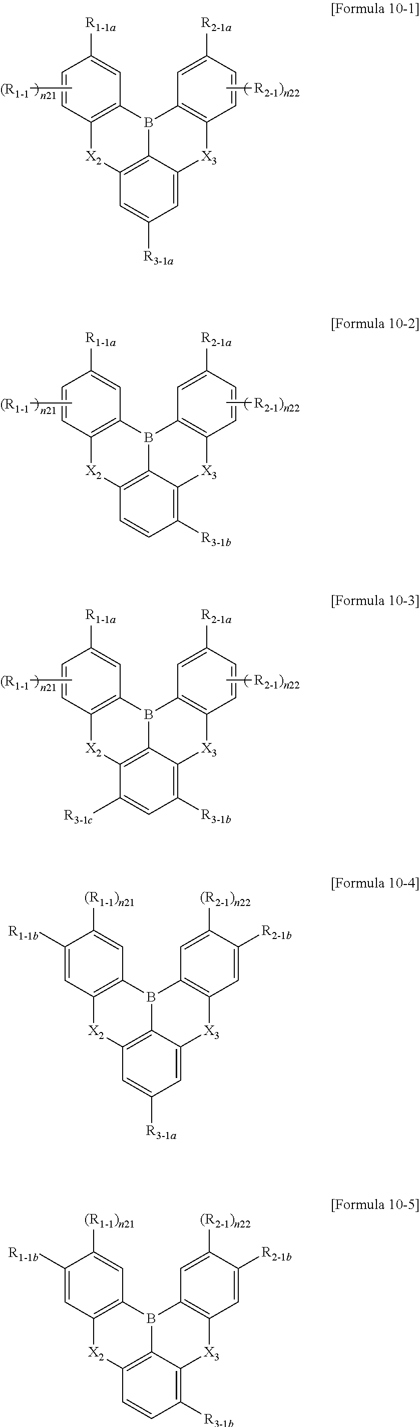

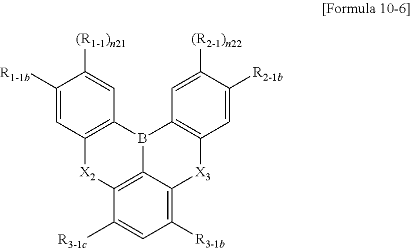

In Formula 10-1 to Formula 10-6, R₁₋₁ and R₂₋₁ may each independently be a hydrogen atom, a deuterium atom, a halogen atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, a group represented by Formula 2, or may be bonded to an adjacent group to form a ring; R₁₋₁ₐ, R_{1-1b}, R₂₋₁ₐ, and R_{2-1b} may each independently be a substituted or unsubstituted t-butyl group, an aryl group having 6 to 30 ring-forming carbon atoms which is substituted with a t-butyl group, or a substituted or unsubstituted carbazole group; R₃₋₁ₐ to R_{3-1c} may each independently be a group represented by Formula 2; and n21 and n22 may each independently be an integer from 0 to 3.

In Formula 10-1 to Formula 10-6, X₂ and X₃ are each the same as defined in Formula 1.

In an embodiment, the emission layer may further include a second compound represented by Formula H-1:

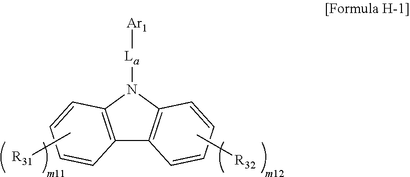

In Formula H-1, Lₐ may be a direct linkage, a substituted or unsubstituted arylene group having 6 to 30 ring-forming carbon atoms, or a substituted or unsubstituted heteroarylene group having 2 to 30 ring-forming carbon atoms; Ar₁ may be a substituted or unsubstituted aryl group having 6 to 30 ring-forming carbon atoms, or a substituted or unsubstituted heteroaryl group having 2 to 30 ring-forming carbon atoms; R₃₁ and R₃₂ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and m11 and m12 may each independently be an integer from 0 to 4.

In an embodiment, the emission layer may further include a third compound represented by Formula D-1:

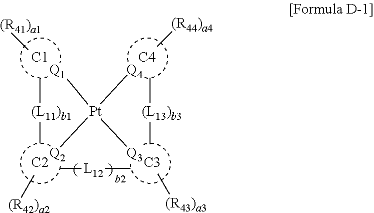

In Formula D-1, Q₁ to Q₄ may each independently be C or N; C1 to C4 may each independently be a substituted or unsubstituted hydrocarbon ring group having 5 to 30 ring-forming carbon atoms, or a substituted or unsubstituted heterocycle having 2 to 30 ring-forming carbon atoms; R₄₁ to R₄₆ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring; a1 to a4 may each independently be an integer from 0 to 4; L₁₁ to L₁₃ may each independently be a direct linkage,

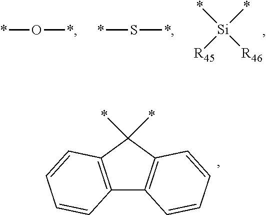

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; and b1 to b3 may each independently be 0 or 1.

In an embodiment, the emission layer may further include a fourth compound represented by Formula D-2:

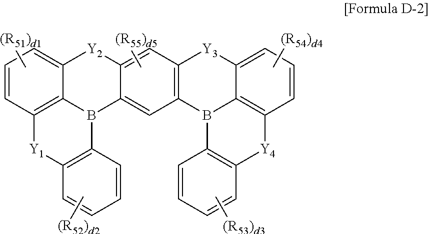

In Formula D-2, Y₁ to Y₄ may each independently be N(R₅₆), O, or S; R₅₁ to R₅₆ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring; d1 and d4 may each independently be an integer from 0 to 3; d2 and d3 may each independently be an integer from 0 to 4; and d5 may be an integer from 0 to 2.

In an embodiment, the first compound represented by Formula 1 may include at least one compound selected from Compound Group 1, which is explained below.

An embodiment provides a fused polycyclic compound which may be represented by Formula 1.

In an embodiment, the fused polycyclic compound represented by Formula 1 may be represented by Formula 3, which is explained herein.

In an embodiment, the fused polycyclic compound represented by Formula 3 may be represented by any one of Formula 4-1 to Formula 4-4, which are explained herein.

In an embodiment, the fused polycyclic compound represented by Formula 3 may be represented by any one of Formula 6-1 to Formula 6-4, which are explained herein.

In an embodiment, the fused polycyclic compound represented by Formula 3 may be represented by any one of Formula 8-1 to Formula 8-3, which are explained herein.

In an embodiment, the fused polycyclic compound represented by Formula 3 may be represented by any one of Formula 9-1 to Formula 9-6, which are explained herein.

In an embodiment, the fused polycyclic compound represented by Formula 1 may be selected from Compound Group 1, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a plan view of a display apparatus according to an embodiment;

FIG. 2 is a schematic cross-sectional view of a display apparatus according to an embodiment;

FIG. 3 is a schematic cross-sectional view illustrating a light emitting device according to an embodiment;

FIG. 4 is a schematic cross-sectional view illustrating a light emitting device according to an embodiment;

FIG. 5 is a schematic cross-sectional view illustrating a light emitting device according to an embodiment;

FIG. 6 is a schematic cross-sectional view illustrating a light emitting device according to an embodiment;

FIG. 7 is a schematic cross-sectional view of a display apparatus according to an embodiment;

FIG. 8 is a schematic cross-sectional view of a display apparatus according to an embodiment;

FIG. 9 is a schematic cross-sectional view illustrating a display apparatus according to an embodiment; and

FIG. 10 is a schematic cross-sectional view illustrating a display apparatus according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring, or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent substituted for an atom which is substituted with a corresponding substituent, or as a substituent sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear, branched, or cyclic. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, an alkenyl group may be linear or branched. The number of carbon atoms in an alkenyl group is not specifically limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 30 ring-forming carbon atoms.

In the specification, an aryl group may be any functional group or substituent derived from an aromatic hydrocarbon ring. The aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a heterocyclic group may be any functional group or substituent derived from a ring that includes at least one of B, O, N, P, S, Si, or Se as a heteroatom. The heterocyclic group may be an aliphatic heterocyclic group or an aromatic heterocyclic group. An aromatic heterocyclic group may be an heteroaryl group. An aliphatic heterocycle or an aromatic heterocycle may each independently be monocyclic or polycyclic.

In the specification, a heterocyclic group may include at least one of B, O, N, P, S, Si, or Se as a heteroatom. If a heterocyclic group contains two or more heteroatoms, the two or more heteroatoms may be the same as or different from each other. A heterocyclic group may be monocyclic or polycyclic, and a heterocyclic group may be a heteroaryl group. The number of ring-forming carbon atoms in a heterocyclic group may be 2 to 30, 2 to 20, or 2 to 10.

In the specification, a heteroaryl group may include at least one of B, O, N, P, S, Si, or Se as a heteroatom. If a heterocyclic group includes two or more heteroatoms, the two or more heteroatoms may be the same as or different from each other. The heteroaryl group may be monocyclic or polycyclic. The number of ring-forming carbon atoms in a heteroaryl group may be 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of the aryl group may be applied to an arylene group, except that the arylene group is a divalent group. In the specification, the above description of the heteroaryl group may be applied to a heteroarylene group, except that the heteroarylene group is a divalent group.

In the specification, a silyl group may be an alkyl silyl group or an aryl silyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, a thio group may be an alkylthio group or an arylthio group. A thio group may be a sulfur atom that is bonded to an alkyl group or an aryl group as defined herein. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but embodiments are not limited thereto.

In the specification, an oxy group may be an oxygen atom that is bonded to an alkyl group or an aryl group as defined herein. An oxy group may be an alkoxy group or an aryl oxy group. The alkoxy group may be linear, branched, or cyclic. The number of carbon atoms in an alkoxy group is not specifically limited, but may be, for example, 1 to 20 or 1 to 10. Examples of an oxy group may include methoxy, ethoxy, n-propoxy, isopropoxy, butoxy, pentyloxy, hexyloxy, octyloxy, nonyloxy, decyloxy, benzyloxy, etc., but embodiments are not limited thereto.

In the specification, the number of carbon atoms in an amine group is not specifically limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, etc., but embodiments are not limited thereto.

In the specification, a direct linkage may be a single bond.

In the specification, the symbols

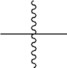

and [symbol] each represent a bonding site to a neighboring atom.

Hereinafter, embodiments will be described with reference to the drawings.

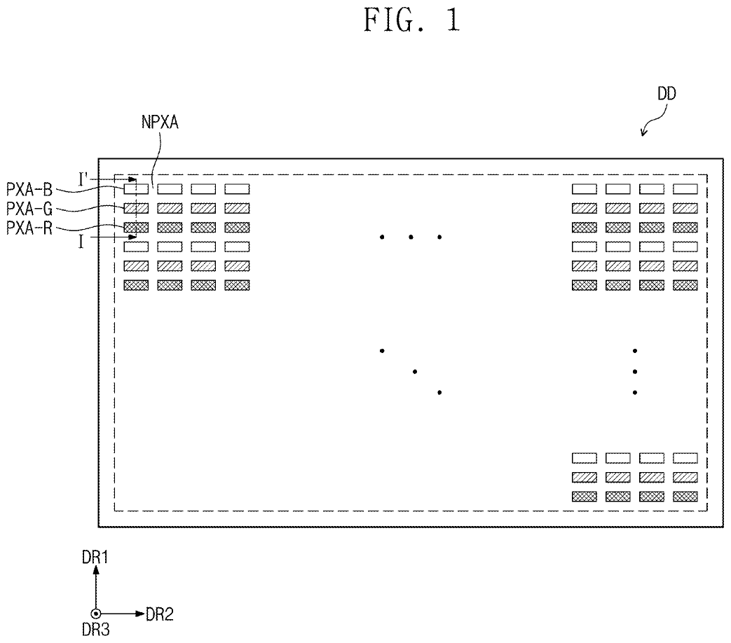

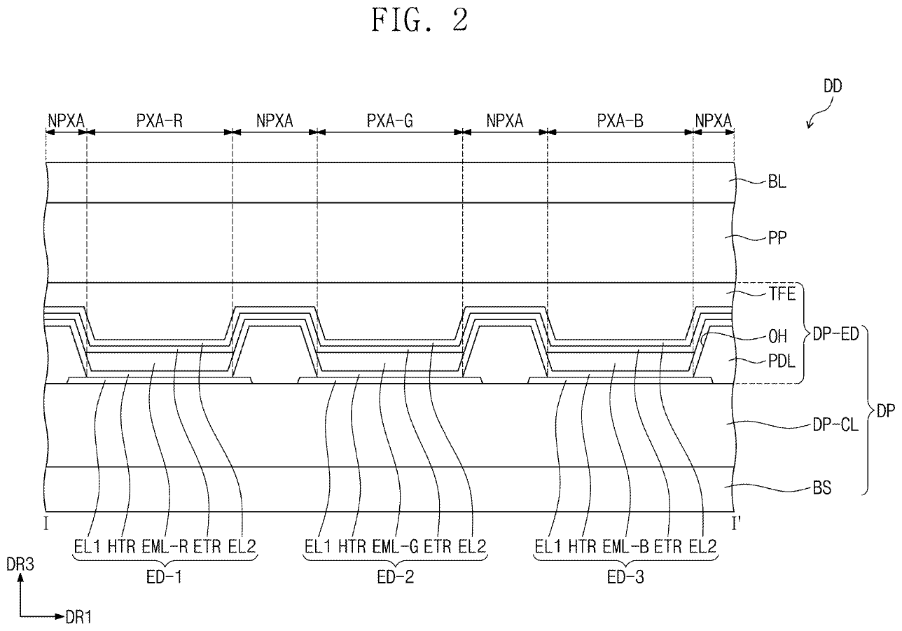

FIG. 1 is a plan view illustrating an embodiment of a display apparatus DD. FIG. 2 is a schematic cross-sectional view of the display apparatus DD according to an embodiment. FIG. 2 is a schematic cross-sectional view illustrating a part taken along line I-I′ of FIG. 1.

The display apparatus DD may include a display panel DP and an optical layer PP disposed on the display panel DP. The display panel DP includes light emitting devices ED-1, ED-2, and ED-3. The display apparatus DD may include multiples of each of the light emitting devices ED-1, ED-2, and ED-3. The optical layer PP may be disposed on the display panel DP and may control light reflected at the display panel DP from an external light. The optical layer PP may include, for example, a polarization layer or a color filter layer. Although not shown in the drawings, in an embodiment, the optical layer PP may be omitted from the display apparatus DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display apparatus DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, or an epoxy-based resin.

The display panel DP may include a base layer BS, a circuit layer DP-CL provided on the base layer BS, and a display device layer DP-ED. The display device layer DP-ED may include a pixel defining film PDL, the light emitting devices ED-1, ED-2, and ED-3 disposed between portions of the pixel defining film PDL, and an encapsulation layer TFE disposed on the light emitting devices ED-1, ED-2, and ED-3.

The base layer BS may provide a base surface on which the display device layer DP-ED is disposed. The base layer BS may be a glass substrate, a metal substrate, a plastic substrate, etc. However, the embodiment is not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). Each of the transistors (not shown) may include a control electrode, an input electrode, and an output electrode. For example, the circuit layer DP-CL may include a switching transistor and a driving transistor for driving the light emitting devices ED-1, ED-2, and ED-3 of the display device layer DP-ED.

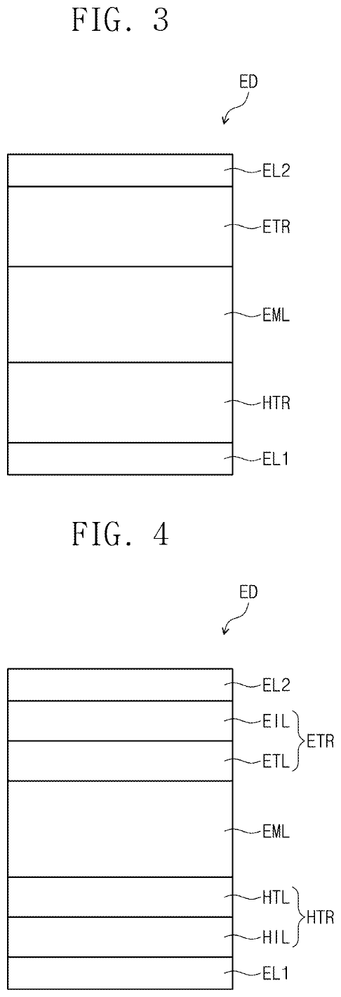

Each of the light emitting devices ED-1, ED-2, and ED-3 may have a structure of a light emitting device ED of an embodiment according to one of FIGS. 3 to 6, which will be described later. Each of the light emitting devices ED-1, ED-2, and ED-3 may include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting devices ED-1, ED-2, and ED-3 are disposed in openings OH defined in the pixel defining film PDL, and the hole transport region HTR, the electron transport region ETR, and the second electrode EL2 are each provided as a common layer for all of the light emitting devices ED-1, ED-2, and ED-3. However, embodiments are not limited thereto. Although not illustrated in FIG. 2, in an embodiment, the hole transport region HTR and the electron transport region ETR may each be provided by being patterned inside the openings OH defined in the pixel defining film PDL. For example, in an embodiment, the hole transport region HTR, the emission layers EML-R, EML-G, and EML-B, and the electron transport region ETR of the light emitting devices ED-1, ED-2, and ED-3 may each be provided by being patterned by an inkjet printing method.

The encapsulation layer TFE may cover the light emitting devices ED-1, ED-2, and ED-3. The encapsulation layer TFE may seal the display device layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film may protect the display device layer DP-ED from moisture and/or oxygen, and the encapsulation-organic film may protect the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display apparatus DD may include a non-light emitting region NPXA and light emitting regions PXA-R, PXA-G, and PXA-B. The light emitting regions PXA-R, PXA-G, and PXA-B may each be a region in which light respectively generated by the light emitting devices ED-1, ED-2, and ED-3 is emitted. The light emitting regions PXA-R, PXA-G, and PXA-B may be spaced apart from each other in a plan view.

Each of the light emitting regions PXA-R, PXA-G, and PXA-B may be a region separated by the pixel defining film PDL. The non-light emitting areas NPXA may be areas between the adjacent light emitting areas PXA-R, PXA-G, and PXA-B, which correspond to the pixel defining film PDL. For example, in an embodiment, the light emitting regions PXA-R, PXA-G, and PXA-B may each respectively correspond to a pixel. The pixel defining film PDL may separate the light emitting devices ED-1, ED-2, and ED-3. The emission layers EML-R, EML-G, and EML-B of the light emitting devices ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting devices ED-1, ED-2, and ED-3. In the display apparatus DD according to an embodiment illustrated in FIGS. 1 and 2, three light emitting regions PXA-R, PXA-G, and PXA-B, which respectively emit red light, green light, and blue light are illustrated as an example. For example, the display apparatus DD according to an embodiment may include the red light emitting region PXA-R, the green light emitting region PXA-G, and the blue light emitting region PXA-B which are separated from each other.

In the display apparatus DD according to an embodiment, the light emitting devices ED-1, ED-2, and ED-3 may emit light having wavelengths different from each other. For example, in an embodiment, the display apparatus DD may include a first light emitting device ED-1 that emits red light, a second light emitting device ED-2 that emits green light, and a third light emitting device ED-3 that emits blue light. For example, the red light emitting region PXA-R, the green light emitting region PXA-G, and the blue light emitting region PXA-B of the display apparatus DD may respectively correspond to the first light emitting device ED-1, the second light emitting device ED-2, and the third light emitting device ED-3.

However, embodiments are not limited thereto, and the first to third light emitting devices ED-1, ED-2, and ED-3 may emit light in a same wavelength range or at least one light emitting device may emit light in a wavelength range that is different from the others. For example, the first to third light emitting devices ED-1, ED-2, and ED-3 may all emit blue light.

The light emitting regions PXA-R, PXA-G, and PXA-B in the display apparatus DD according to an embodiment may be arranged in a stripe configuration. Referring to FIG. 1, the red light emitting regions PXA-R, the green light emitting regions PXA-G, and the blue light emitting regions PXA-B may each be arranged along a second directional axis DR2. In another embodiment, the red light emitting region PXA-R, the green light emitting region PXA-G, and the blue light emitting region PXA-B may be alternately arranged in this order along a first directional axis DR1.

FIGS. 1 and 2 illustrate that the light emitting regions PXA-R, PXA-G, and PXA-B each have a similar area, but embodiments are not limited thereto. Thus, the light emitting regions PXA-R, PXA-G, and PXA-B may have different areas from each other according to a wavelength range of emitted light. For example, the areas of the light emitting regions PXA-R, PXA-G, and PXA-B may be areas in a plan view that are defined by the first directional axis DR1 and the second directional axis DR2.

An arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics which are required in the display apparatus DD. For example, the light emitting regions PXA-R, PXA-G, and PXA-B may be arranged in a pentile configuration (for example, in a PENTILE™ configuration) or in a diamond configuration (for example, in a Diamond Pixel™ configuration).

In an embodiment, the areas of the light emitting regions PXA-R, PXA-G, and PXA-B may be different from each other. For example, in an embodiment, an area of the green light emitting region PXA-G may be smaller than an area of the blue light emitting region PXA-B, but embodiments are not limited thereto.

Hereinafter, FIGS. 3 to 6 are each a schematic cross-sectional view illustrating a light emitting device according to an embodiment. The light emitting devices ED according to embodiments may each include a first electrode EL1, a hole transport region HTR, an emission layer EML, an electron transport region ETR, and a second electrode EL2 which may be stacked in that order, as shown in FIG. 3.

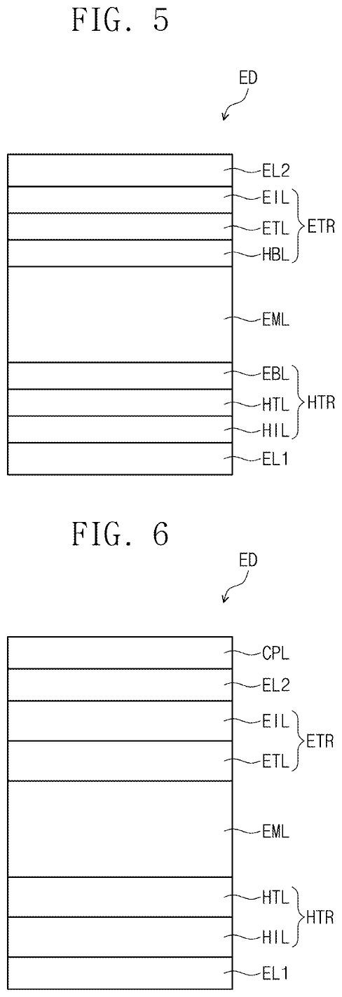

In comparison to FIG. 3, FIG. 4 illustrates a schematic cross-sectional view of a light emitting device ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 illustrates a schematic cross-sectional view of a light emitting device ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 illustrates a schematic cross-sectional view of a light emitting device ED according to an embodiment that includes a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. For example, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. The first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR is provided on the first electrode EL1. The hole transport region HTR may include at least one of a hole injection layer HIL, a hole transport layer HTL, a buffer layer (not shown), an emission-auxiliary layer (not shown), or an electron blocking layer EBL. A thickness of the hole transport region HTR may be, for example, in a range of about 50 Å to about 15,000 Å.

The hole transport region HTR may be a layer formed of a single material, a layer formed of different materials, or a structure including multiple layers formed of different materials.

For example, the hole transport region HTR may have a single layer structure of a hole injection layer HIL or a hole transport layer HTL, or may have a single layer structure formed of a hole injection material and a hole transport material. In other embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods, such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1:

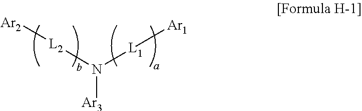

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In Formula H-1, Ar₃ may be a substituted or unsubstituted aryl group having 6 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In still another embodiment, the compound represented by Formula H-1 may be a carbazole-based compound in which at least one of Ar₁ or Ar₂ includes a substituted or unsubstituted carbazole group, or a fluorene-based compound in which at least one of Ar₁ or Ar₂ includes a substituted or unsubstituted fluorene group.

The compound represented by Formula H-1 may be any one selected from Compound Group H. However, the compounds listed in Compound Group H are only examples, and the compounds represented by Formula H-1 are not limited to Compound Group H:

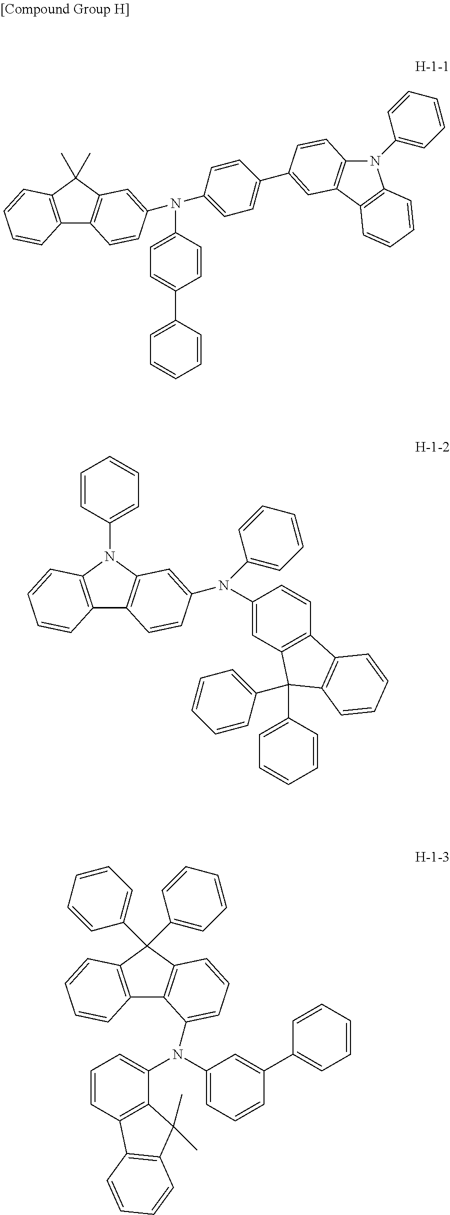 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

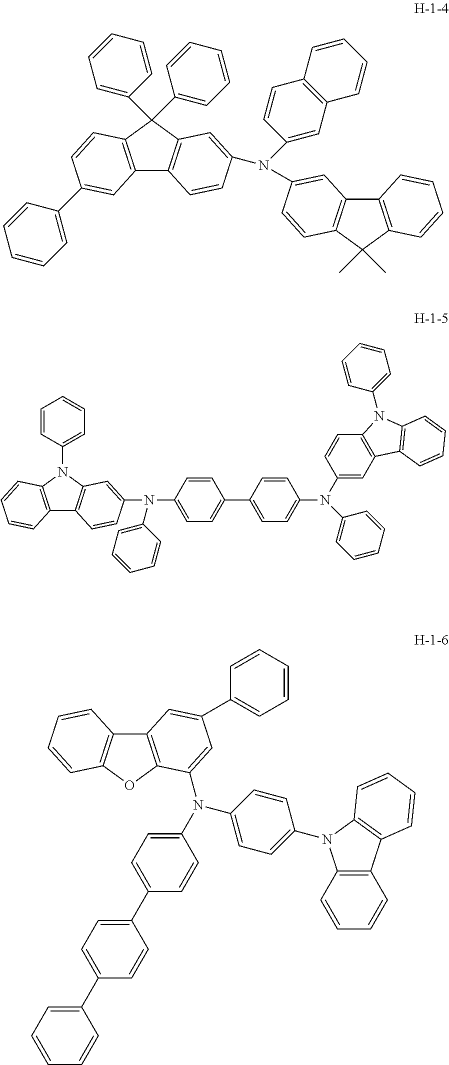 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

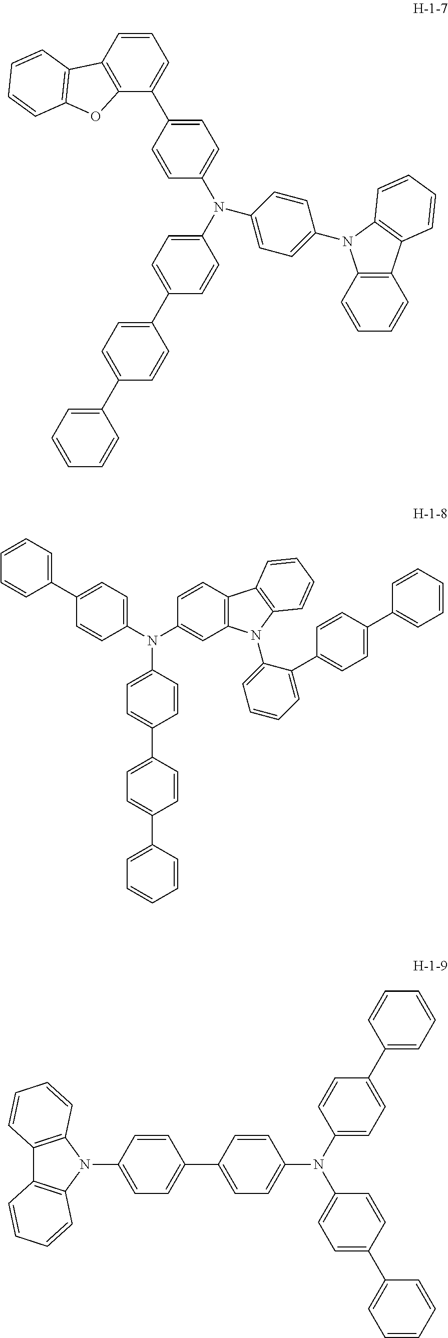 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

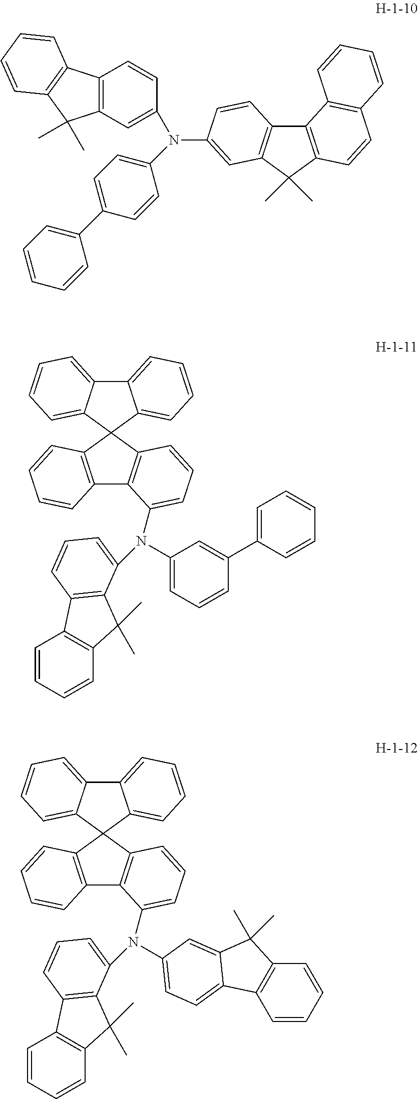 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

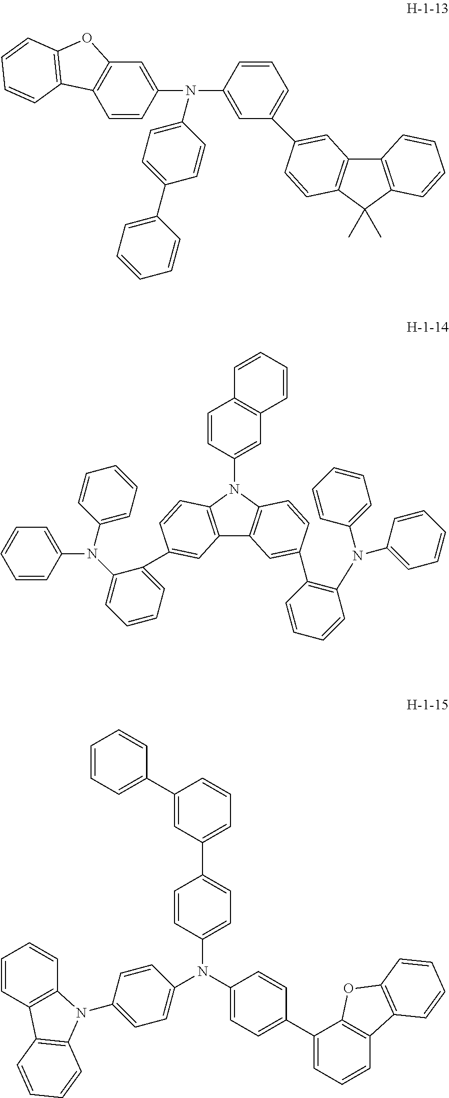 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

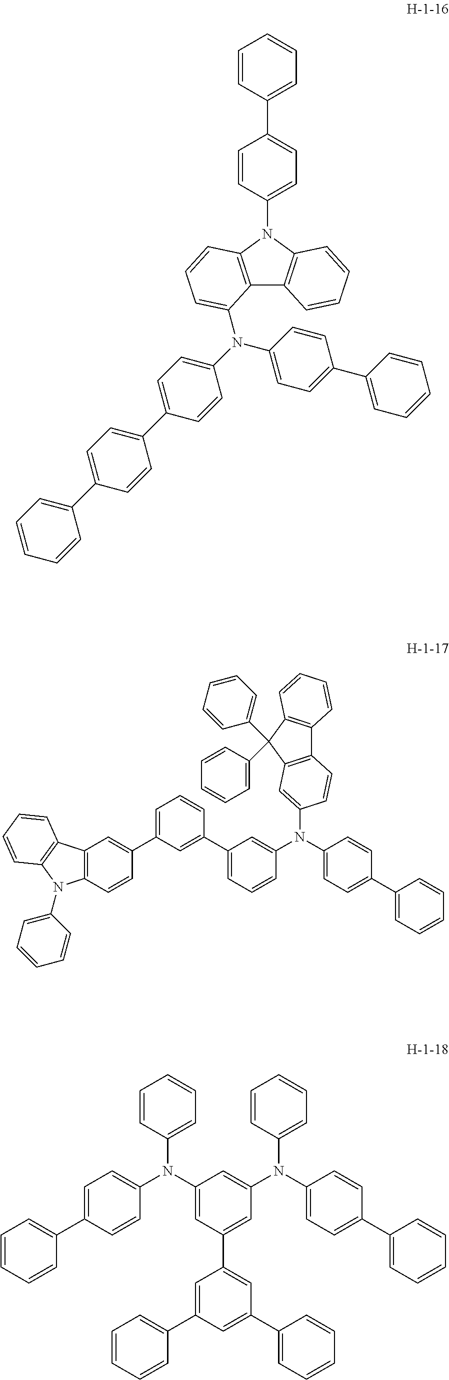 [SMILES: c1ccc(-c2ccc(-c3ccc(N(c4ccc(-c5ccccc5)cc4)c4cccc5c4c4ccccc4n5-c4ccc(-c5ccccc5)cc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

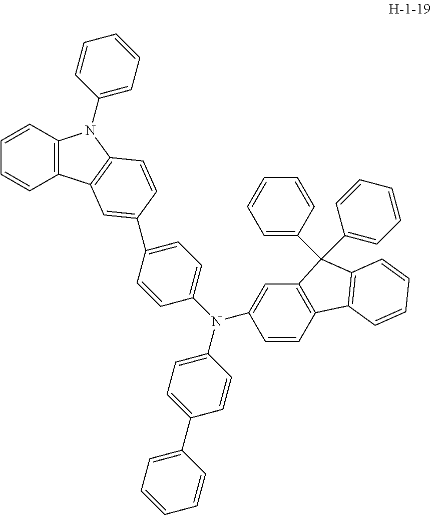 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N(2-naphthyl)-N-phenylamino]-triphenyl amine (2-TNATA), poly(3,4-ethylenedioxythiophene)/poly(4-styrenesulfonate) (PEDOT/PSS), polyaniline/dodecylbenzenesulfonic acid (PANI/DB SA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have, for example, a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) or an electron blocking layer EBL, in addition to the hole injection layer HIL and the hole transport layer HTL. The buffer layer (not shown) may compensate for a resonance distance according to a wavelength of light emitted from the emission layer EML and may thus increase light emission efficiency. A material that may be included in the hole transport region HTR may be used as a material for the buffer layer (not shown). The electron blocking layer EBL may prevent the injection of electrons from the electron transport region ETR to the hole transport region HTR.

The emission layer EML is provided on the hole transport region HTR. The emission layer EML may have a thickness, for example, in a range of about 100 Å to about 1,000 Å. For example, the emission layer EML may have a thickness in a range of about 100 Å to about 300 Å. The emission layer EML may be a layer formed of a single material, a layer formed of different materials, or a structure having multiple layers formed of different materials.

The emission layer EML in the light emitting device ED according to an embodiment may include a fused polycyclic compound according to an embodiment. In an embodiment, the emission layer EML may include the fused polycyclic compound according to an embodiment as a host. The fused polycyclic compound according to an embodiment may be a host material of the emission layer EML. In the specification, the fused polycyclic compound according to an embodiment, which will be described later, may be referred to as a first compound.

The fused polycyclic compound according to an embodiment may have a structure in which three aromatic rings are fused around at least one heteroatom selected from the group consisting of a boron atom, a phosphorus atom, an aluminum atom, a gallium atom, an arsenic atom, a silicon atom, and a germanium atom, and at least two heteroatoms selected from the group consisting of an oxygen atom, a sulfur atom, a selenium atom, and a nitrogen atom are included as a fused ring-constituting atom. The fused polycyclic compound according to an embodiment is a compound in which at least one silyl group is substituted at a fused ring core. The at least one silyl group substituted at the fused polycyclic compound according to an embodiment may be bonded to the fused ring core via a linker rather than via a direct linkage.

The fused polycyclic compound according to an embodiment may be represented by Formula 1:

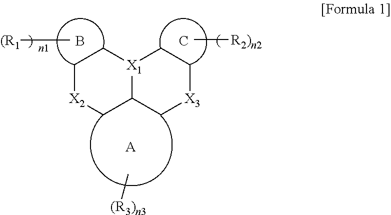

In Formula 1, A, B, and C may each independently be a monocyclic aromatic hydrocarbon ring having 6 to 30 ring-forming carbon atoms, or a monocyclic aromatic heterocycle having 2 to 30 ring-forming carbon atoms. For example, A, B, and C may each independently be a 5-membered or 6-membered aromatic hydrocarbon ring, or a 5-membered or 6-membered aromatic heterocycle. In an embodiment, A, B, and C may each independently be a 6-membered aromatic hydrocarbon ring, or a 6-membered aromatic heterocycle. For example, A, B, and C may each be a benzene ring.

In Formula 1, X₁ may be B, P, P═O, P═S, Al, Ga, As, Si(R₄), or Ge(R₅). In an embodiment, X₁ may be B.

In Formula 1, X₂ and X₃ may each independently be O, S, Se, or N(R₆). In an embodiment, X₂ and X₃ may each be O.

In Formula 1, R₁ to R₃ may each independently be a hydrogen atom, a deuterium atom, a halogen atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, a group represented by Formula 2, or may be bonded to an adjacent group to form a ring. For example, R₁ to R₃ may each independently be a hydrogen atom, a deuterium atom, a substituted or unsubstituted t-butyl group, a substituted or unsubstituted phenyl group, a substituted or unsubstituted pyridine group, a substituted or unsubstituted biphenyl group, a substituted or unsubstituted terphenyl group, or a substituted or unsubstituted carbazole group.

In Formula 1, at least one of R₁ to R₃ may each independently by a group represented by Formula 2. Thus, the fused polycyclic compound represented by Formula 1 according to an embodiment may include at least one group represented by Formula 2 as a substituent of the fused ring core. For example, among R₁ to R₃, R₃ may be a group represented by Formula 2. Thus, R₁ and R₂, which are not represented by Formula 2, may each independently be a hydrogen atom, a deuterium atom, a halogen atom, a substituted or unsubstituted alkyl group having 1 to 20 carbon group, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring.

In Formula 1, R₄ to R₆ may each independently be a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring.

In Formula 1, n1 represents the number of R₁ groups, and may be an integer from 1 to 4. In Formula 1, n2 represents the number of R₂ groups, and may be an integer from 1 to 4. In Formula 1, n3 represents the number of R₃ groups, and may be an integer from 1 to 3. When each of n1 to n3 is 2 or more, multiple groups of each of R₁ to R₃ may each be the same or at least one thereof may be different from the others.

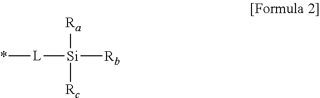

In Formula 2, Rₐ to R_{c}, may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₐ to R_{c} may each independently be a substituted or unsubstituted phenyl group, or a substituted or unsubstituted pyridine group.

In Formula 2, L may be a substituted or unsubstituted arylene group having 6 to 30 ring-forming carbon atoms, or a substituted or unsubstituted heteroarylene group having 2 to 30 ring-forming carbon atoms. For example, L may be a substituted or unsubstituted phenylene group, a substituted or unsubstituted divalent terphenyl group, a substituted or unsubstituted divalent naphthyl group, or a substituted or unsubstituted divalent carbazole group.

In Formula 2, [symbol] represents a bonding site to Formula 1.

The fused polycyclic compound according to an embodiment includes a structure represented by Formula 1. The fused polycyclic compound according to an embodiment has a planar skeleton structure containing a boron atom at the center thereof, and includes a group represented by Formula 2 as a substituent which includes a silyl group that is bonded to the planar skeleton structure. For example, the fused polycyclic compound according to an embodiment includes, as a substituent, a silyl group bonded to at least one carbon atom of an aromatic ring which constitutes the fused ring. The silyl group may be bonded to the fused ring core represented by Formula 1 via an arylene group linker or via a heteroarylene group linker.

In an embodiment, the fused polycyclic compound represented by Formula 1 may be represented by Formula 3:

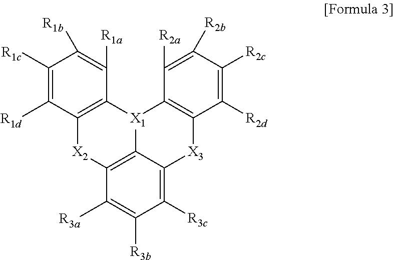

Formula 3 represents a case wherein in Formula 1, A, B, and C are each a benzene ring.

In Formula 3, R₁ₐ to R_{1d}, R₂ₐ to R_{2d}, and R₃ₐ to R_{3c} may each independently be a hydrogen atom, a deuterium atom, a halogen atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, a group represented by Formula 2, or may be bonded to an adjacent group to form a ring. For example, R₁ₐ to R_{1d}, R₂ₐ to R_{2d}, and R₃ₐ to R_{3c} may each independently be a hydrogen atom, a deuterium atom, a substituted or unsubstituted t-butyl group, a substituted or unsubstituted phenyl group, a substituted or unsubstituted pyridine group, a substituted or unsubstituted biphenyl group, a substituted or unsubstituted terphenyl group, or a substituted or unsubstituted carbazole group.

In Formula 3, at least one of R₁ₐ to R_{1d}, R₂ₐ to R_{2d}, and R₃ₐ to R_{3c} may each independently be a group represented by Formula 2. For example, the fused polycyclic compound represented by Formula 3 according to an embodiment may include at least one group represented by Formula 2 as a substituent of the fused ring core.

In Formula 3, X₁ to X₃ are each the same as described in Formula 1.

In an embodiment, the fused polycyclic compound represented by Formula 3 may be represented by any one of Formula 4-1 to Formula 4-4:

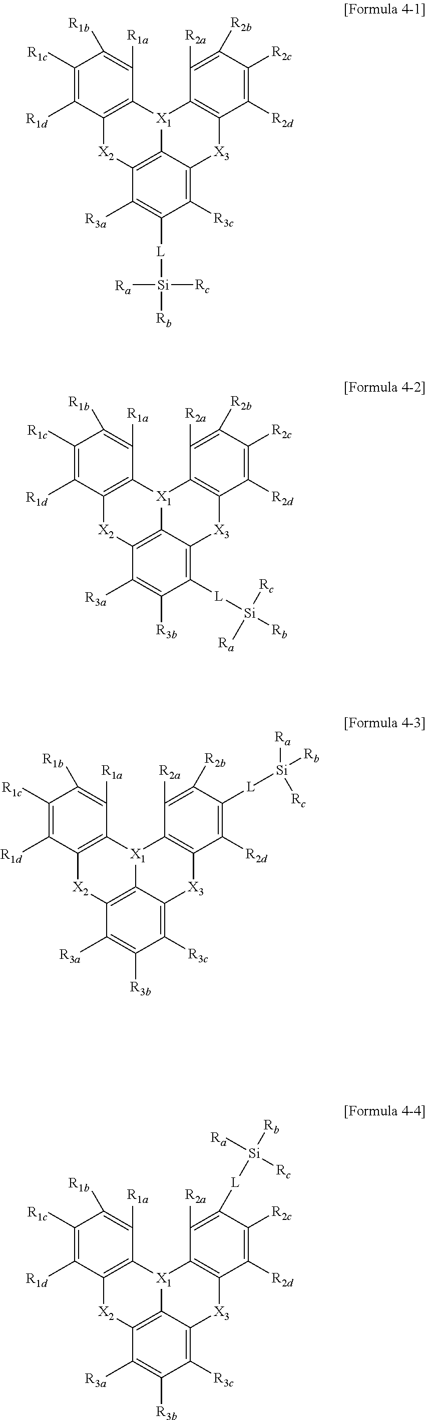

Formula 4-1 to Formula 4-4 each represent a case wherein a bonding position of L in Formula 2 is specified to the fused ring core of Formula 3. Formula 4-1 represents a case wherein in Formula 3, R_{3b} is a group represented by Formula 2. Formula 4-2 represents a case wherein in Formula 3, R_{3c} is a group represented by Formula 2. Formula 4-3 represents a case wherein in Formula 3, R_{2c} is a group represented by Formula 2. Formula 4-4 represents a case where in Formula 3, R_{2b} is a group represented by Formula 2.

In Formula 4-1 to Formula 4-4, X₁ to X₃, L, Rₐ to R_{c}, R₁ₐ to R_{1d}, R₂ₐ to R_{2d}, and R₃ₐ to R_{3c} are each the same as defined in Formula 1, Formula 2, and Formula 3.

In an embodiment, the fused polycyclic compound represented by Formula 3 may be represented by any one of Formula 5-1 to Formula 5-4:

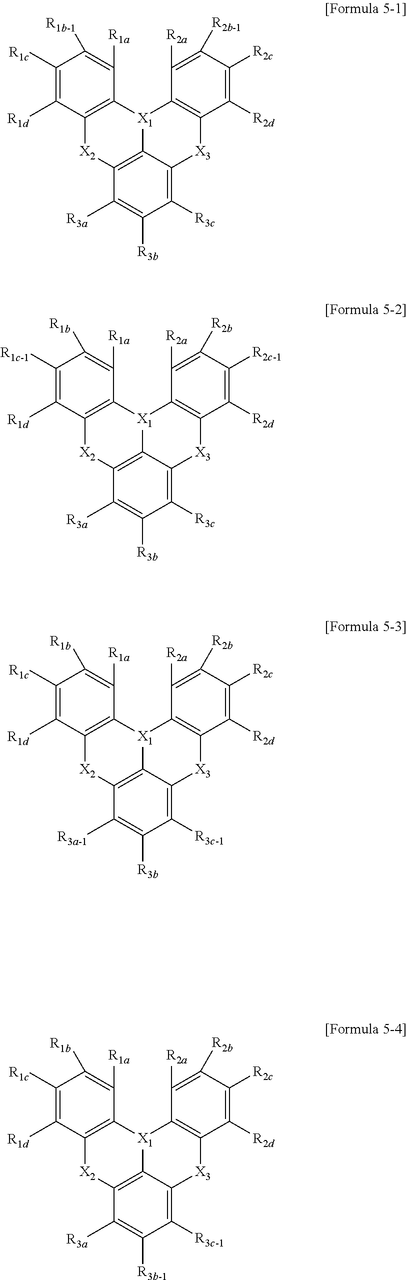

Formula 5-1 to Formula 5-4 each represent a case wherein the substituents R_{1b}, R_{1c}, R_{2b}, R_{2c}, and R₃ₐ to R_{3c}, in Formula 3 are further defined. Formula 5-1 represents a case wherein R_{1b} and R_{2b} in Formula 3 are further defined. Formula 5-2 represents a case wherein R_{1c} and R_{2c} in Formula 3 are further defined. Formula 5-3 represents a case wherein R₃ₐ and R_{3c} in Formula 3 are further defined. Formula 5-4 represents a case wherein R_{3b} in Formula 3 is further defined.

In Formula 5-1 to Formula 5-4, R_{1b-1}, R_{2b-1}, R_{1c-1}, R_{2c-1}, and R₃ₐ₋₁ to R_{3c-1} may each independently be a substituted or unsubstituted alkyl group having 1 to 10 carbon atoms, a substituted or unsubstituted aryl group having 6 to 30 ring-forming carbon atoms, a substituted or unsubstituted heteroaryl group having 2 to 30 ring-forming carbon atoms, or a group represented by Formula 2. For example, R_{1b-1}, R_{2b-1}, R_{1c-1}, R_{2c-1}, and R₃ₐ₋₁ to R_{3c-1} may each independently be a substituted or unsubstituted t-butyl group, a substituted or unsubstituted phenyl group, a substituted or unsubstituted biphenyl group, a substituted or unsubstituted carbazole group, or a group represented by Formula 2.

In Formula 5-1 to Formula 5-4, X₁ to X₃, R₁ₐ to R_{1d}, R₂ₐ to R_{2d}, and R₃ₐ to R_{3c} are each the same as defined in Formula 1 and Formula 3.

In an embodiment, the fused polycyclic compound represented by Formula 3 may be represented by any one of Formula 6-1 to Formula 6-4:

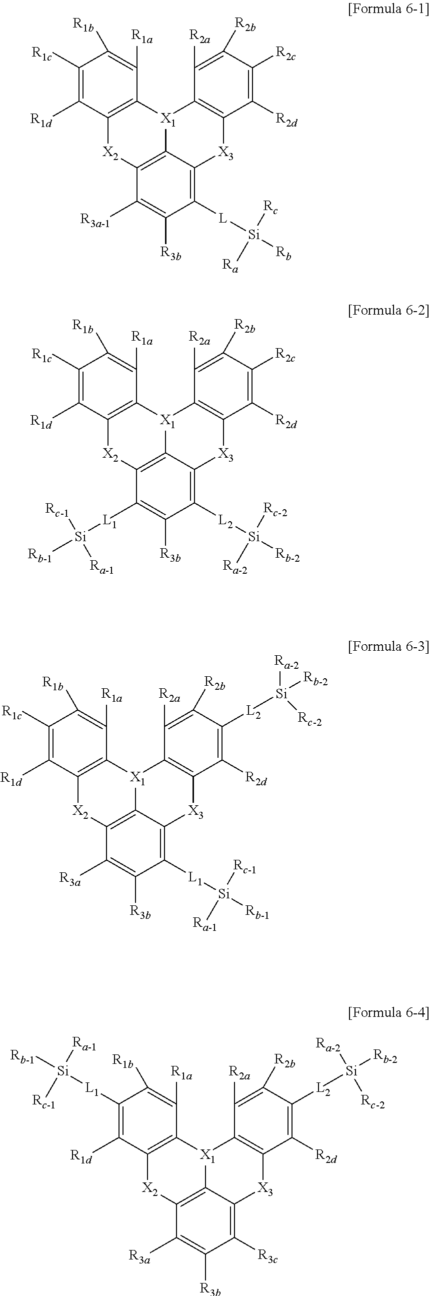

Formula 6-1 to Formula 6-4 each represent a case wherein substituents R_{1c}, R_{2c}, R₃ₐ, and R_{3c} in Formula 3 are further defined. Formula 6-1 represents a case wherein in Formula 3, R_{3c} is a group represented by Formula 2. Formula 6-2 represents a case wherein in Formula 3, R₃ₐ and R_{3c} are each independently a group represented by Formula 2. Formula 6-3 represents case wherein in Formula 3, R_{2c} and R_{3c} are each independently a group represented by Formula 2. Formula 6-4 represents a case wherein in Formula 3, R_{1c} and R_{2c} are each independently a group represented by Formula 2.

In Formula 6-1, R₃ₐ₋₁ may be a substituted or unsubstituted aryl group having 6 to 30 ring-forming carbon atoms, or a substituted or unsubstituted heteroaryl group having 2 to 30 ring-forming carbon atoms. For example, R₃ₐ₋₁ may be a substituted or unsubstituted phenyl group, a substituted or unsubstituted pyridine group, a substituted or unsubstituted biphenyl group, or a substituted or unsubstituted terphenyl group.

In Formula 6-2 to Formula 6-4, Rₐ₋₁ to R_{c-1} and Rₐ₋₂ to R_{c-2} may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R_{a_1} to R_{c-1} and Rₐ₋₂ to R_{c-2} may each independently be a substituted or unsubstituted phenyl group, or a substituted or unsubstituted pyridine group.

In Formula 6-2 to Formula 6-4, L₁ and L₂ may each independently be a substituted or unsubstituted arylene group having 6 to 30 ring-forming carbon atoms, or a substituted or unsubstituted heteroarylene group having 2 to 30 ring-forming carbon atoms. For example, L₁ and L₂ may each independently be a substituted or unsubstituted phenylene group, a substituted or unsubstituted divalent terphenyl group, a substituted or unsubstituted divalent pyridine group, a substituted or unsubstituted divalent naphthyl group, or a substituted or unsubstituted divalent carbazole group.

In Formula 6-1 to Formula 6-4, X₁ to X₃, L, Rₐ to R_{c}, R₁ₐ to R_{1d}, R₂ₐ to R_{2d}, and R₃ₐ to R_{3c} are each the same as defined in Formula 1, Formula 2, and Formula 3.

In an embodiment, in Formula 6-1, R₃ₐ₋₁ may be a group represented by any one of Formula 7-1 to Formula 7-4:

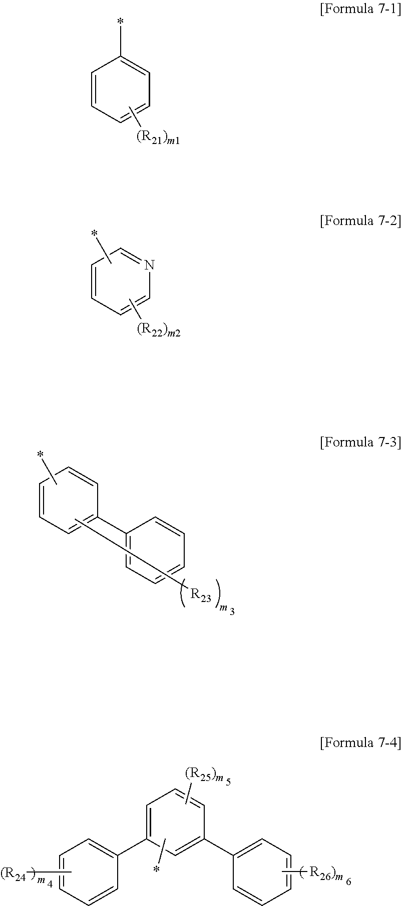

In Formula 7-1 to Formula 7-4, R₂₁ to R₂₆ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₂₁ to R₂₆ may each independently be a hydrogen atom, a substituted or unsubstituted t-butyl group, or a substituted or unsubstituted phenyl group.

In Formula 7-1 to Formula 7-4, m₁, m₄, and m₆ may each independently be an integer from 0 to 5, m₂ may be an integer from 0 to 4, m₃ may be an integer from 0 to 9, and m₅ may be an integer from 0 to 3.

If each of m₁, m₄, and m₆ is 0, the fused polycyclic compound according to an embodiment may not be substituted with R₂₁, R₂₄, and R₂₆. A case where m₁, m₄, and m₆ are each 5 and multiple groups of each of R₂₁, R₂₄, and R₂₆ are each a hydrogen atom may be the same as a case where m1, m4, and m6 are each 0. If each of m₁, m₄, and m₆ is 2 or more, multiple groups of each of R₂₁, R₂₄, and R₂₆ may each be the same or at least one thereof may be different from the others.

If m₂ is 0, the fused polycyclic compound according to an embodiment may not be substituted with R₂₂. A case where m₂ is 4 and R₂₂ groups are each a hydrogen atom may be the same as a case where m₂ is 0. If m₂ is 2 or more, multiple R₂₂ groups may be all the same or at least one thereof may be different from the others.

If m₃ is 0, the fused polycyclic compound according to an embodiment may not be substituted with R₂₃. A case where m₃ is 9 and R₂₃ groups are each a hydrogen atom may be the same as a case where m₃ is 0. If m₃ is 2 or more, multiple R₂₃ groups may be all the same or at least one thereof may be different from the others.

If m₅ is 0, the fused polycyclic compound according to an embodiment may not be substituted with R₂₅. A case where m₅ is 3 and R₂₅ groups are each a hydrogen atom may be the same as a case where m₅ is 0. If m₂ is 2 or more, multiple R₂₅ groups may be all the same or at least one thereof may be different from the others.

In an embodiment, the fused polycyclic compound represented by Formula 3 may be represented by any one of Formula 8-1 to Formula 8-3:

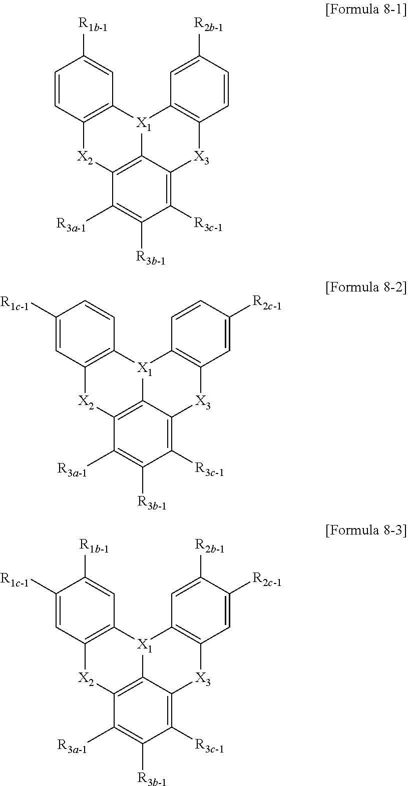

Formula 8-1 to Formula 8-3 each represent a case wherein substituents R₁ₐ to R_{1d}, R₂ₐ to R_{2d}, and R₃ₐ to R_{3c}, in Formula 3 are further defined.

In Formula 8-1 to Formula 8-3, R_{1b-1}, R_{2b-1}, R_{1c-1}, R_{2c-1}, and R₃ₐ₋₁ to R_{3c-1} may each independently be a hydrogen atom, a substituted or unsubstituted t-butyl group, a substituted or unsubstituted phenyl group, a substituted or unsubstituted biphenyl group, a substituted or unsubstituted terphenyl group, a substituted or unsubstituted pyridine group, a substituted or unsubstituted carbazole group, or a group represented by Formula 2.

In Formula 8-1 to Formula 8-3, at least one of R_{1b-1}, R_{2b-1}, R_{1c-1}, R_{2c-1}, and R₃ₐ₋₁ to R_{3c-1} may each independently be a group represented by Formula 2. For example, R₃ₐ₋₁ may be a group represented by Formula 2.

In Formula 8-1 to Formula 8-3, X₁ to X₃ are each the same as defined in Formula 1.

In an embodiment, the fused polycyclic compound represented by Formula 3 may be represented by any one of Formula 9-1 to Formula 9-6:

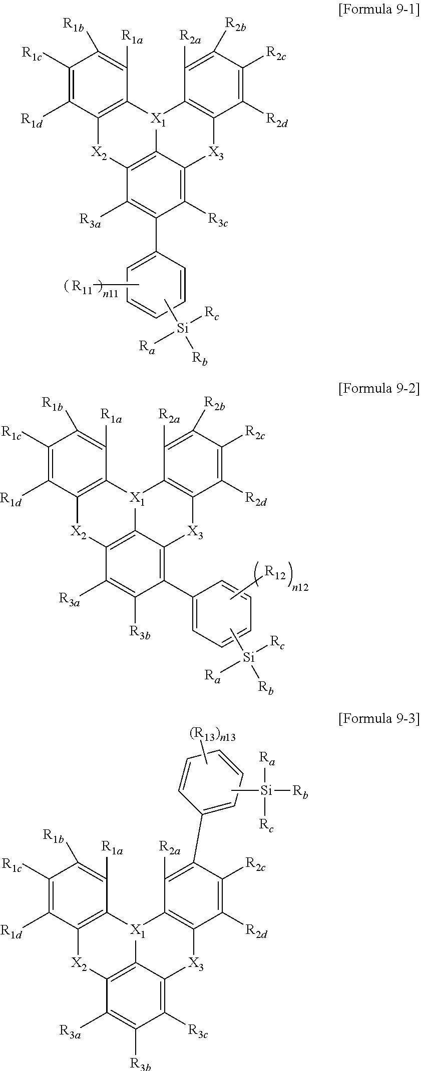

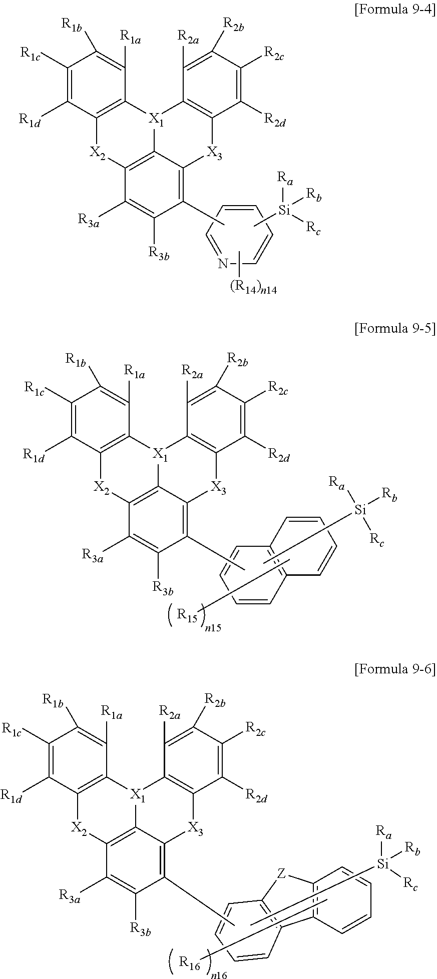

Formula 9-1 to Formula 9-6 each represent a case wherein in Formula 3, a bonding position of Formula 2 to the fused ring core is further defined, and L in Formula 2 is further defined. Formula 9-1 represents a case wherein in Formula 3, R_{3b} is a group represented by Formula 2, and L in Formula 2 is a substituted or unsubstituted phenylene group. Formula 9-2 represents a case wherein in Formula 3, R_{3c} is a group represented by Formula 2, and L in Formula 2 is a substituted or unsubstituted phenylene group. Formula 9-3 represents a case wherein in Formula 3, R_{2b} is a group represented by Formula 2, and L in Formula 2 is a substituted or unsubstituted phenylene group. Formula 9-4 represents a case wherein in Formula 3, R_{3c} is a group represented by Formula 2, and L in Formula 2 is a substituted or unsubstituted divalent pyridine group. Formula 9-5 represents a case wherein in Formula 3, R_{3c} is a group represented by Formula 2, and L in Formula 2 is a substituted or unsubstituted divalent naphthyl group. Formula 9-6 represents a case wherein in Formula 3, R_{3c} is a group represented by Formula 2, and L in Formula 2 is a substituted or unsubstituted divalent dibenzofuran group, a substituted or unsubstituted divalent dibenzothiophene group, or a substituted or unsubstituted divalent carbazole group.

In Formula 9-6, Z may be N(R₁₇), O, or S. In an embodiment, Z may be N(R₁₇).

In Formula 9-1 to Formula 9-6, R₁₁ to R₁₇ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, RH to R₁₇ may each independently be a hydrogen atom or a substituted or unsubstituted phenyl group.

In Formula 9-1 to Formula 9-3, n11 to n13 may each independently be an integer from 0 to 4. If n11 to n13 are each 0, the fused polycyclic compound according to an embodiment may not be substituted with R₁₁ to R₁₃. A case wherein in Formula 9-1 to Formula 9-3, n11 to n13 are each 4 and multiple groups of each of R₁₁ to R₁₃ are each a hydrogen atom may be the same as a case where n11 to n13 are each 0 in Formula 9-1 to Formula 9-3. When n11 to n13 are each 2 or more, multiple groups of each of R₁₁ to R₁₃ may each be the same or at least one thereof may be different from the others.

In Formula 9-4, n14 may be an integer from 0 to 3. A case wherein in Formula 9-4, n14 is 3 and multiple R₁₄ groups are each a hydrogen atom may be the same as a case where n14 is 0 in Formula 9-4. In Formula 9-4, if n14 is 2 or more, multiple R₁₄ groups may be all the same or at least one thereof may be different from the others.

In Formula 9-5 and Formula 9-6, n15 and n16 may each independently be an integer from 0 to 6. If n15 and n16 are each 0, the fused polycyclic compound of an embodiment may not be substituted with R₁₅ and R₁₆. A case wherein in Formula 9-5 and Formula 9-6, n15 and n16 are each 6 and multiple groups of each of R₁₅ and R₁₆ are each a hydrogen atom may be the same as a case where n15 and n16 are each 0 in Formula 9-5 and Formula 9-6. When n15 and n16 are each 2 or more, multiple groups of each of R₁₅ and R₁₆ may each be the same or at least one thereof may be different from the others.

In Formula 9-1 to Formula 9-6, X₁ to X₃, Rₐ to R_{c}, R₁ₐ to R_{1d}, R₂ₐ to R_{2d}, and R₃ₐ to R_{3c} are each the same as described in Formula 1, Formula 2, and Formula 3.

In an embodiment, the fused polycyclic compound represented by Formula 1 may be represented by any one of Formula 10-1 to Formula 10-6:

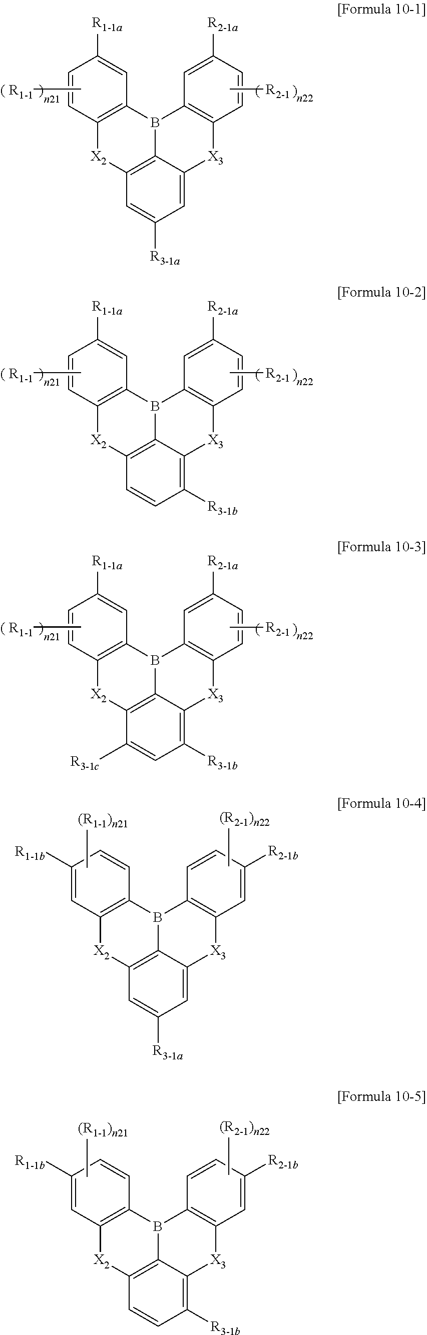

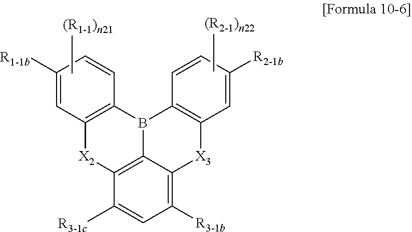

Formula 10-1 to Formula 10-6 each represent a case wherein in Formula 1, A, B, and C are each a benzene ring; X₁ is B; and R₁ to R₃ and n1 to n3 are further defined. Formula 10-1 represents a case wherein in Formula 1, R₁ and R₂ are each substituted at a meta-position to a boron atom, and one R₃ is substituted at a para-position to a boron atom. Formula 10-2 represents a case wherein in Formula 1, R₁ and R₂ are each substituted at a meta-position to a boron atom, and one R₃ is substituted at a meta-position to a boron atom. Formula 10-3 represents a case wherein in Formula 1, R₁ and R₂ are each substituted at a meta-position to a boron atom, and two R₃ groups are each substituted at a meta-position to a boron atom. Formula 10-4 represents a case wherein in Formula 1, R₁ and R₂ are each substituted at a para-position to a boron atom, and one R₃ is substituted at a para-position to a boron atom. Formula 10-5 represents a case wherein in Formula 1, R₁ and R₂ are each substituted at a para-position to a boron atom, and one R₃ is substituted at a meta-position to a boron atom. Formula 10-6 represents a case wherein in Formula 1, R₁ and R₂ are each substituted at a para-position to a boron atom, and two R₃ groups are each substituted at a meta-position to a boron atom.

In Formula 10-1 to Formula 10-6, R₁₋₁ and R₂₋₁ may each independently be a hydrogen atom, a deuterium atom, a halogen atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, a group represented by Formula 2, or may be bonded to an adjacent group to form a ring. For example, R₁₋₁ and R₂₋₂ may each be a hydrogen atom.

In Formula 10-1 to Formula 10-6, R₁₋₁ₐ, R_{1-1b}, R₂₋₁ₐ, and R_{2-1b} may each independently be a substituted or unsubstituted t-butyl group, an aryl group having 6 to 30 ring-forming carbon atoms which is substituted with a t-butyl group, or a substituted or unsubstituted carbazole group. For example, R₁₋₁ₐ, R_{1-1b}, R₂₋₁ₐ, and R_{2-1b} may each independently be an unsubstituted t-butyl group, a phenyl group substituted with an unsubstituted t-butyl group, or an unsubstituted carbazole group.

In Formula 10-1 to Formula 10-6, R₃₋₁ₐ to R_{3-1c} may each independently be a group represented by Formula 2.

In Formula 10-1 to Formula 10-6, n21 and n22 may each independently be an integer from 0 to 3. If n21 and n22 are each 0, the fused polycyclic compound according to an embodiment may not be substituted with R₁₋₁ and R₂₋₁. A case wherein in Formula 10-1 to Formula 10-6, n21 and n22 are each 3 and multiple groups of each of R₁₋₁ and R₂₋₁ are each a hydrogen atom may be the same as a case where n21 and n22 are each 0 in Formula 10-1 to Formula 10-6. If n21 and n22 are each 2 or more, multiple groups of each of R₁₋₁ and R₂₋₁ may each be the same or at least one thereof may be different from the others.

In Formula 10-1 to Formula 10-6, X₂ and X₃ are each the same as described in Formula 1.

In an embodiment, in Formula 2, L may be represented by any one of Formula 11-1 to Formula 11-7:

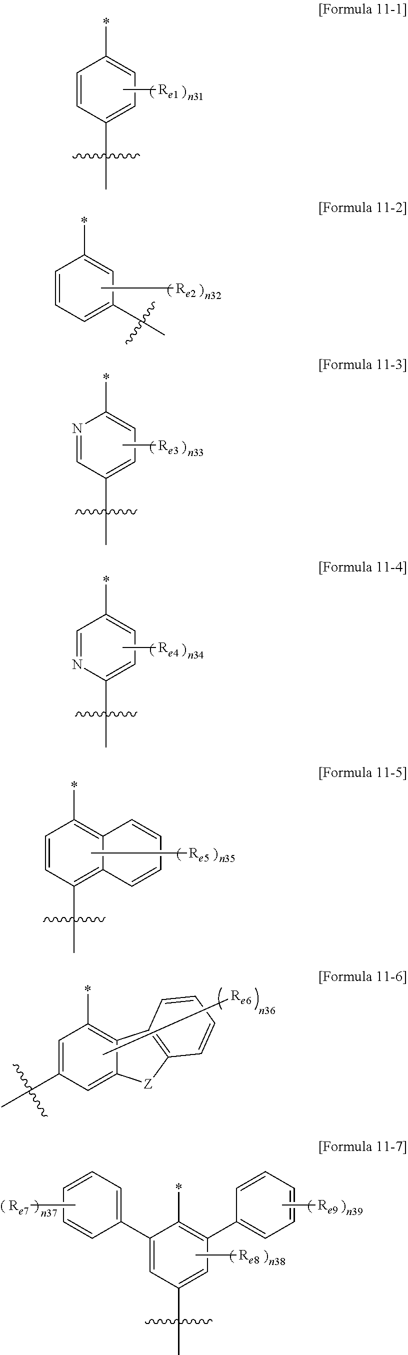

In Formula 11-1 to Formula 11-7, Rₑ₁ to Rₑ₉ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₑ₁ to Rₑ₉ may each independently be a hydrogen atom, or a substituted or unsubstituted methyl group.

In Formula 11-1 and Formula 11-2, n31 and n32 may each independently be an integer from 0 to 4. If n31 and n32 are each 0, the fused polycyclic compound according to an embodiment may not be substituted with Rₑ₁ and Rₑ₂. A case wherein in Formula 11-1 and Formula 11-2, n31 and n32 are each 4 and multiple groups of each of Rₑ₁ and Rₑ₂ are each a hydrogen atom may be the same as a case where n31 and n32 are each 0 in Formula 11-1 and Formula 11-2. When n31 and n32 are each 2 or more, multiple groups of each of Rₑ₁ and Rₑ₂ may each be the same or at least one thereof may be different from the others.

In Formula 11-3 and Formula 11-4, n33 and n34 may each independently be an integer from 0 to 3. If n33 and n34 are each 0, the fused polycyclic compound according to an embodiment may not be substituted with Rₑ₃ and Rₑ₄. A case wherein in Formula 11-3 and Formula 11-4, n33 and n34 are each 3 and multiple groups of each of Rₑ₃ and Rₑ₄ are each a hydrogen atom may be the same as a case where n33 and n34 are each 0 in Formula 11-3 and Formula 11-4. When n33 and n34 are each 2 or more, multiple groups of each of Rₑ₃ and Rₑ₄ may each be the same or at least one thereof may be different from the others.

In Formula 11-5 and Formula 11-6, n35 and n36 may each independently be an integer from 0 to 6. If n35 and n36 are each 0, the fused polycyclic compound according to an embodiment may not be substituted with Rₑ₅ and Rₑ₆. A case wherein in Formula 11-5 and Formula 11-6, n35 and n36 are each 6 and multiple groups of each of Rₑ₅ and Rₑ₆ are each a hydrogen atom may be the same as a case where n35 and n36 are each 0 in Formula 11-5 and Formula 11-6. When n35 and n36 are each 2 or more, multiple groups of each of Rₑ₅ and Rₑ₆ may each be the same or at least one thereof may be different from the others.

In Formula 11-7, n37 and n39 may each independently be an integer from 0 to 5. If n37 and n39 are each 0, the fused polycyclic compound according to an embodiment may not be substituted with Rₑ₇ and Rₑ₉. In Formula 11-7, a case where n37 and n39 are each 5 and multiple groups of each of Rₑ₇ and Rₑ₉ are each a hydrogen atom may be the same as a case where n37 and n39 are each 0 in Formula 11-7. When n37 and n39 are each 2 or more, multiple groups of each of Rₑ₇ and Rₑ₉ may each be the same or at least one thereof may be different from the others.

In Formula 11-7, n38 may be an integer from 0 to 2. In Formula 11-7, a case where n38 is 2 and multiple Res groups are all hydrogen atoms may be the same as a case where n38 is 0 in Formula 11-7. In Formula 11-7, if n38 is 2, multiple Rₑ₈ groups may be all the same or at least one thereof may be different from the others.

In Formula 11-1 to Formula 11-7, [symbol] represents a bonding site to Formula 1, and

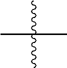

represents a bonding site to a silicon atom in Formula 2.

In Formula 11-7, Z is the same as described in Formula 9-6.

The fused polycyclic compound according to an embodiment may be any one selected from Compound Group 1. The light emitting device ED according to an embodiment may include at least one fused polycyclic compound selected from Compound Group 1 in the emission layer EML.

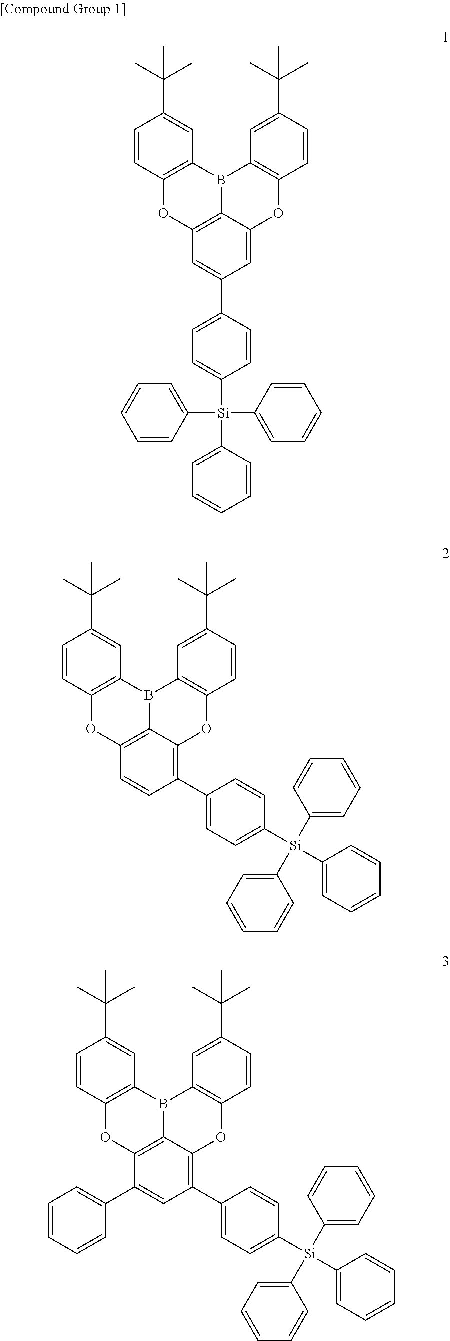

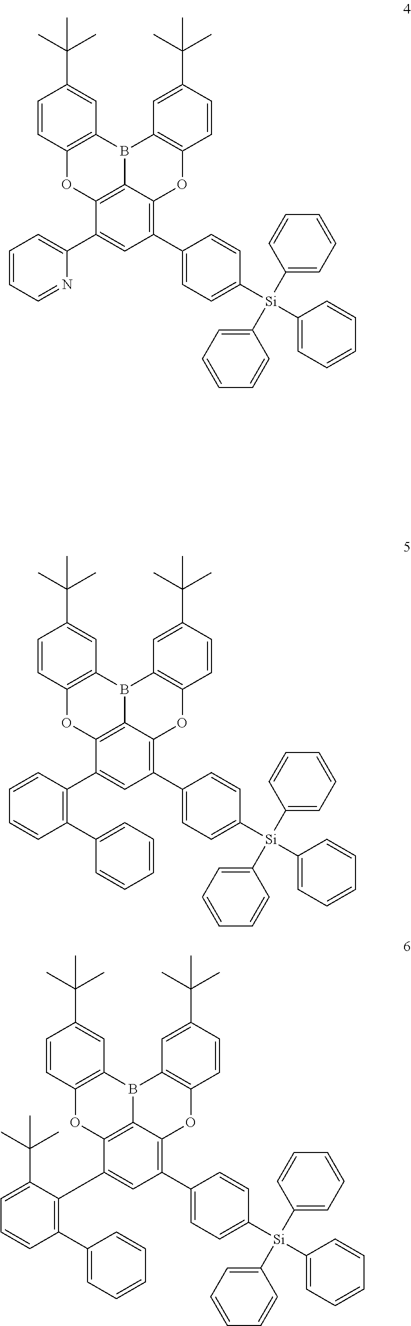

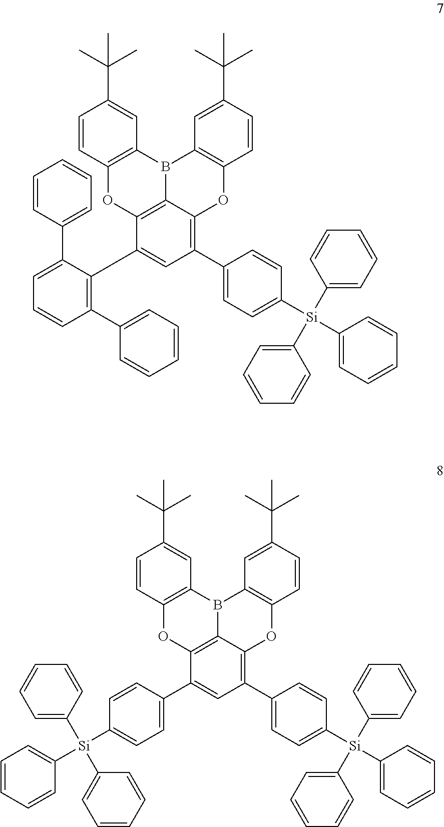 [SMILES: CC(C)(C)c1ccc2c(c1)B1c3cc(C(C)(C)C)ccc3Oc3c(-c4c(-c5ccccc5)cccc4-c4ccccc4)cc(-c4ccc([Si](c5ccccc5)(c5ccccc5)c5ccccc5)cc4)c(c31)O2 ; CC(C)(C)c1ccc2c(c1)B1c3cc(C(C)(C)C)ccc3Oc3c(-c4ccc([Si](c5ccccc5)(c5ccccc5)c5ccccc5)cc4)cc(-c4ccc([Si](c5ccccc5)(c5ccccc5)c5ccccc5)cc4)c(c31)O2]

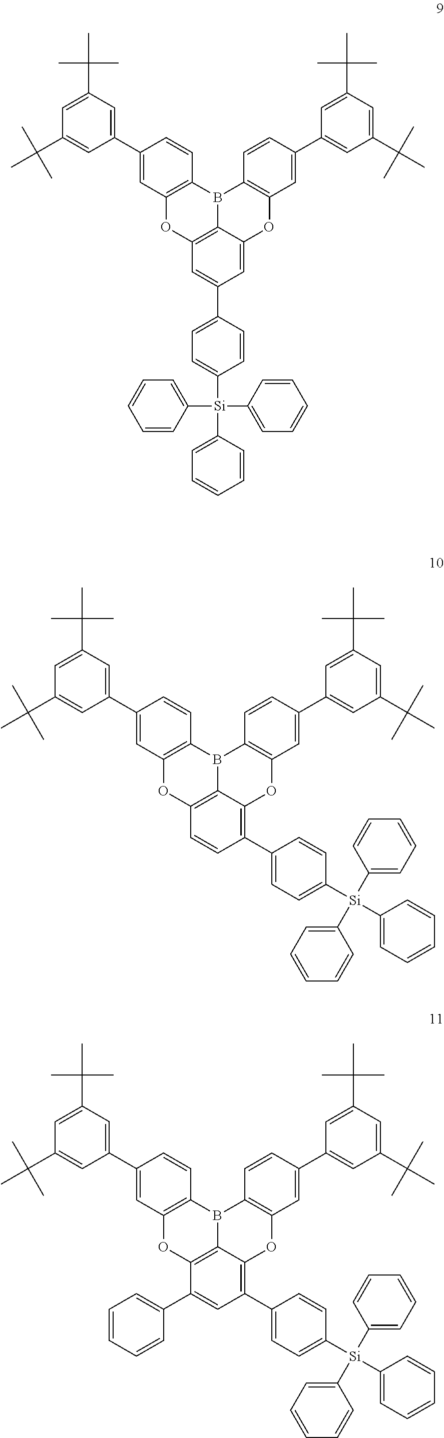

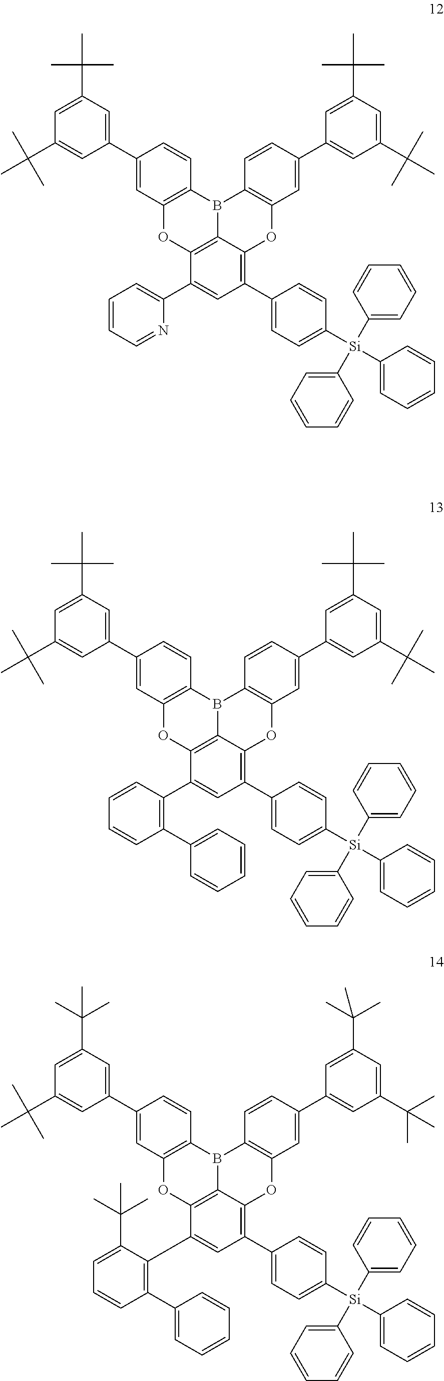 [SMILES: CC(C)(C)c1cc(-c2ccc3c(c2)Oc2c(-c4ccc([Si](c5ccccc5)(c5ccccc5)c5ccccc5)cc4)cc(-c4ccccn4)c4c2B3c2ccc(-c3cc(C(C)(C)C)cc(C(C)(C)C)c3)cc2O4)cc(C(C)(C)C)c1 ; CC(C)(C)c1cc(-c2ccc3c(c2)Oc2c(-c4ccc([Si](c5ccccc5)(c5ccccc5)c5ccccc5)cc4)cc(-c4ccccc4-c4ccccc4)c4c2B3c2ccc(-c3cc(C(C)(C)C)cc(C(C)(C)C)c3)cc2O4)cc(C(C)(C)C)c1 ; CC(C)(C)c1cc(-c2ccc3c(c2)Oc2c(-c4ccc([Si](c5ccccc5)(c5ccccc5)c5ccccc5)cc4)cc(-c4c(-c5ccccc5)cccc4C(C)(C)C)c4c2B3c2ccc(-c3cc(C(C)(C)C)cc(C(C)(C)C)c3)cc2O4)cc(C(C)(C)C)c1]

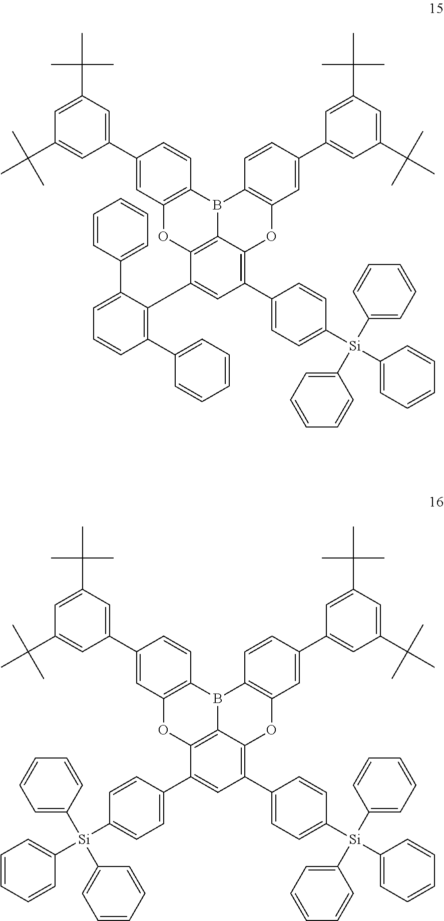 [SMILES: CC(C)(C)c1cc(-c2ccc3c(c2)Oc2c(-c4ccc([Si](c5ccccc5)(c5ccccc5)c5ccccc5)cc4)cc(-c4c(-c5ccccc5)cccc4-c4ccccc4)c4c2B3c2ccc(-c3cc(C(C)(C)C)cc(C(C)(C)C)c3)cc2O4)cc(C(C)(C)C)c1 ; CC(C)(C)c1cc(-c2ccc3c(c2)Oc2c(-c4ccc([Si](c5ccccc5)(c5ccccc5)c5ccccc5)cc4)cc(-c4ccc([Si](c5ccccc5)(c5ccccc5)c5ccccc5)cc4)c4c2B3c2ccc(-c3cc(C(C)(C)C)cc(C(C)(C)C)c3)cc2O4)cc(C(C)(C)C)c1]

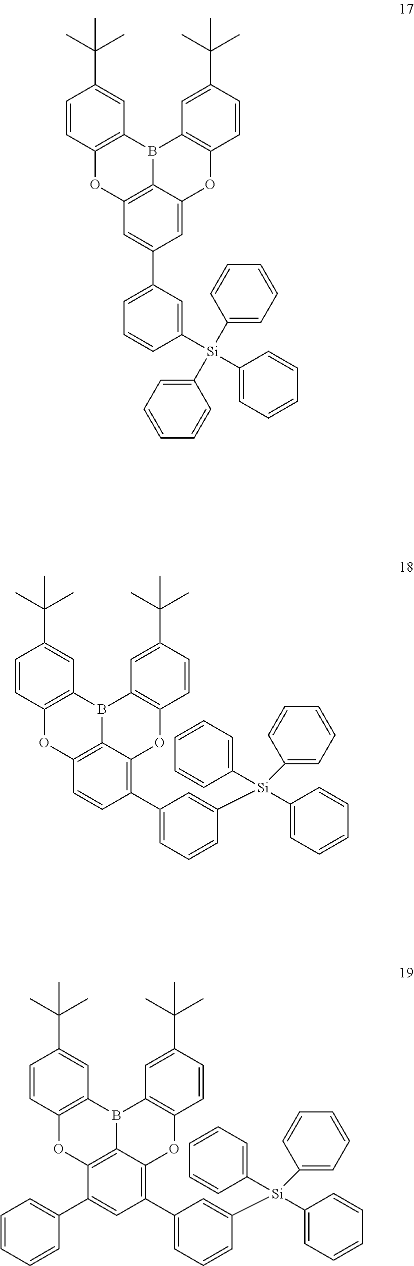 [SMILES: CC(C)(C)c1ccc2c(c1)B1c3cc(C(C)(C)C)ccc3Oc3cc(-c4cccc([Si](c5ccccc5)(c5ccccc5)c5ccccc5)c4)cc(c31)O2 ; CC(C)(C)c1ccc2c(c1)B1c3cc(C(C)(C)C)ccc3Oc3c(-c4cccc([Si](c5ccccc5)(c5ccccc5)c5ccccc5)c4)ccc(c31)O2 ; CC(C)(C)c1ccc2c(c1)B1c3cc(C(C)(C)C)ccc3Oc3c(-c4cccc([Si](c5ccccc5)(c5ccccc5)c5ccccc5)c4)cc(-c4ccccc4)c(c31)O2]

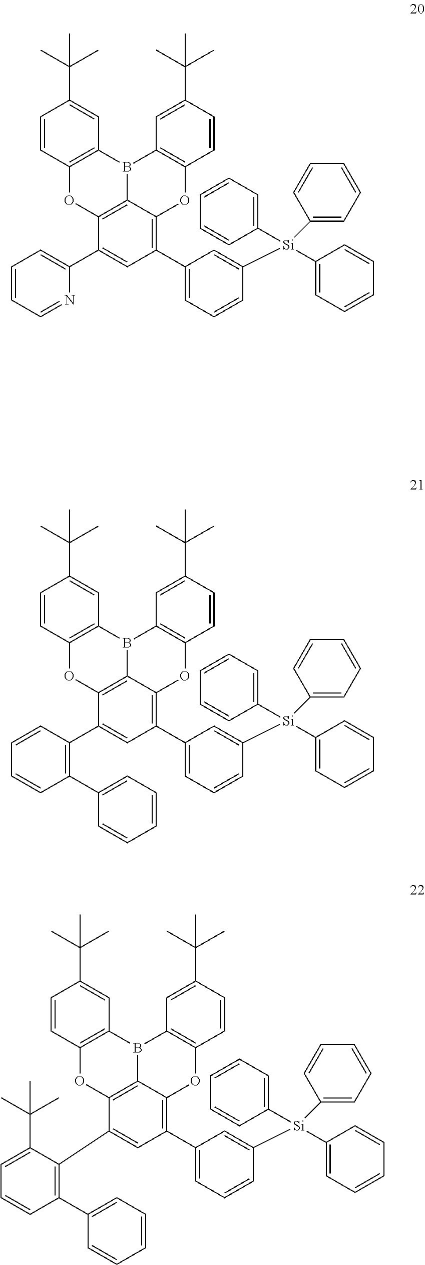 [SMILES: CC(C)(C)c1ccc2c(c1)B1c3cc(C(C)(C)C)ccc3Oc3c(-c4ccccn4)cc(-c4cccc([Si](c5ccccc5)(c5ccccc5)c5ccccc5)c4)c(c31)O2 ; CC(C)(C)c1ccc2c(c1)B1c3cc(C(C)(C)C)ccc3Oc3c(-c4ccccc4-c4ccccc4)cc(-c4cccc([Si](c5ccccc5)(c5ccccc5)c5ccccc5)c4)c(c31)O2 ; CC(C)(C)c1ccc2c(c1)B1c3cc(C(C)(C)C)ccc3Oc3c(-c4c(-c5ccccc5)cccc4C(C)(C)C)cc(-c4cccc([Si](c5ccccc5)(c5ccccc5)c5ccccc5)c4)c(c31)O2]

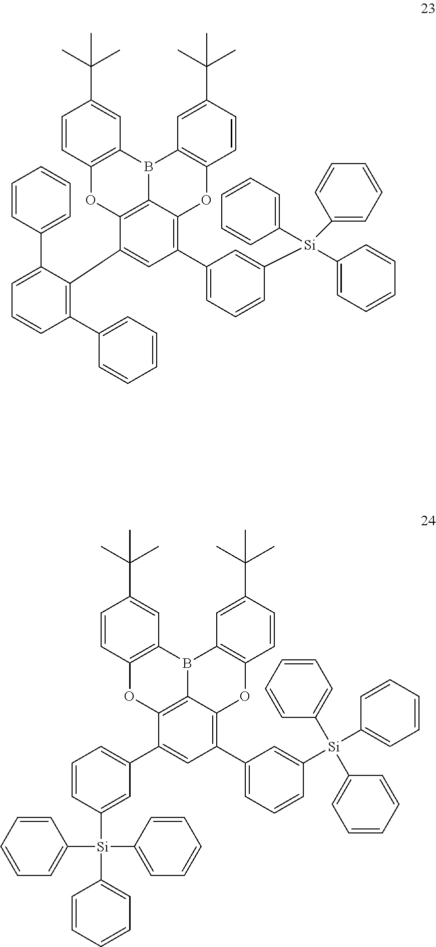 [SMILES: CC(C)(C)c1ccc2c(c1)B1c3cc(C(C)(C)C)ccc3Oc3c(-c4c(-c5ccccc5)cccc4-c4ccccc4)cc(-c4cccc([Si](c5ccccc5)(c5ccccc5)c5ccccc5)c4)c(c31)O2 ; CC(C)(C)c1ccc2c(c1)B1c3cc(C(C)(C)C)ccc3Oc3c(-c4cccc([Si](c5ccccc5)(c5ccccc5)c5ccccc5)c4)cc(-c4cccc([Si](c5ccccc5)(c5ccccc5)c5ccccc5)c4)c(c31)O2]

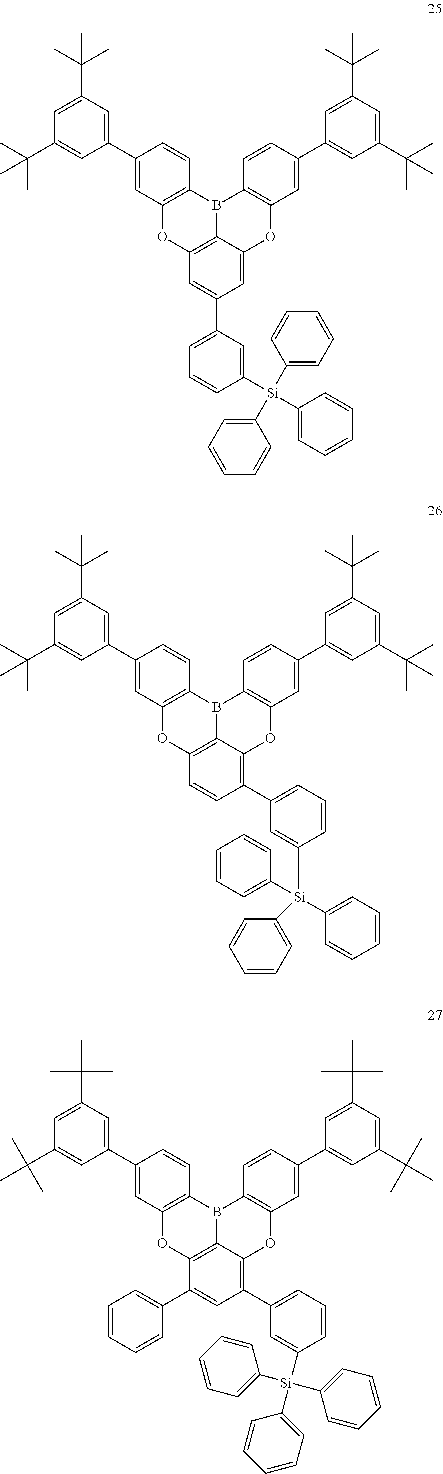

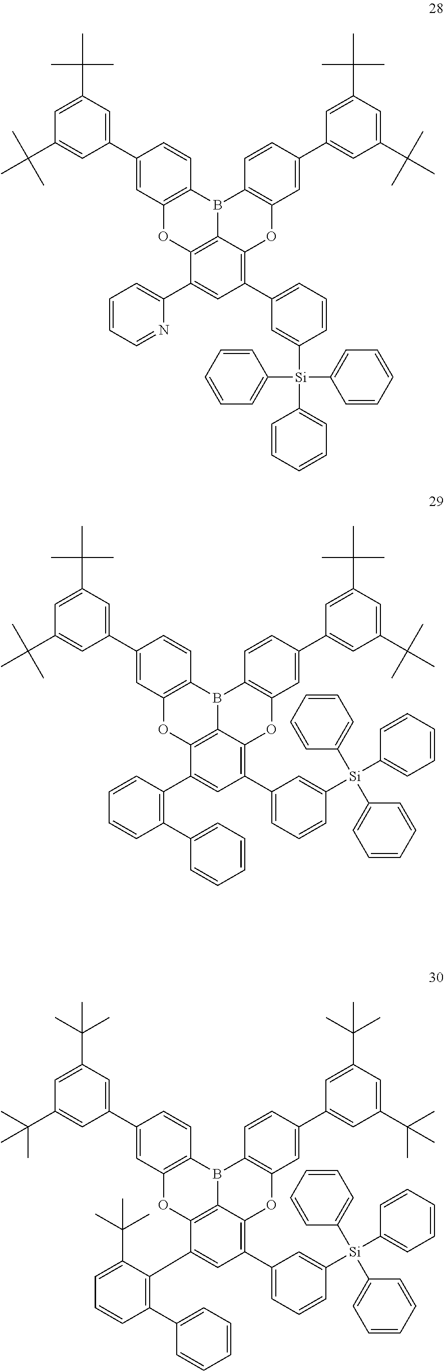

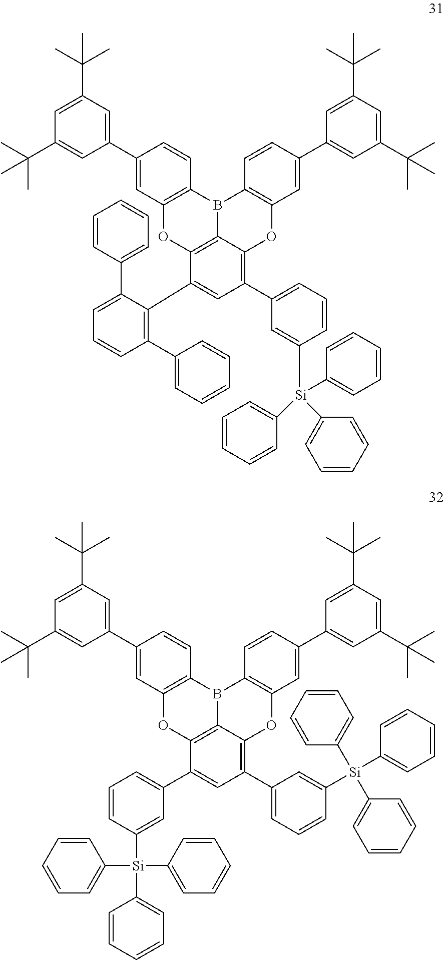

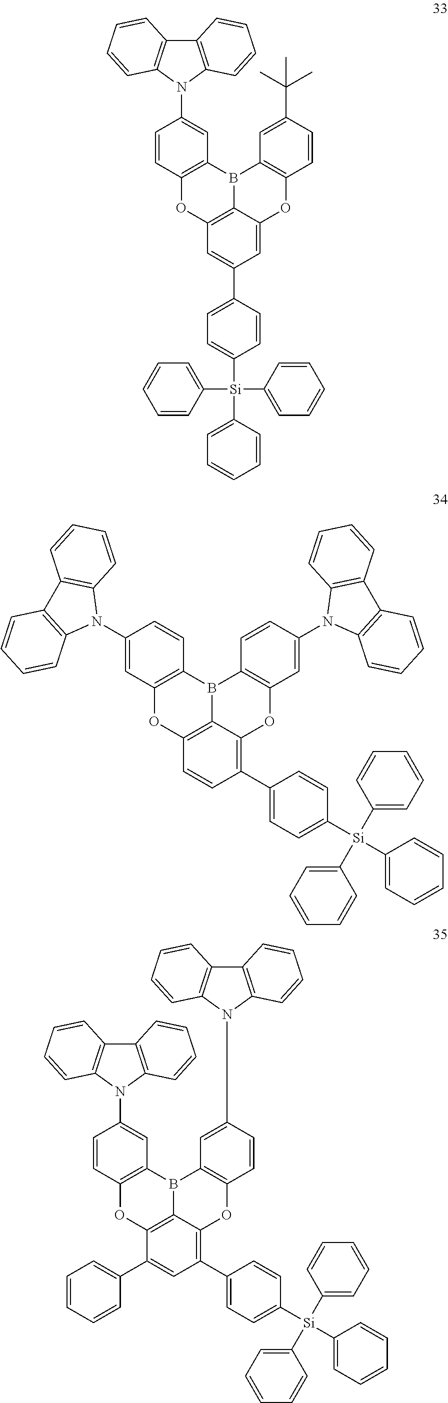

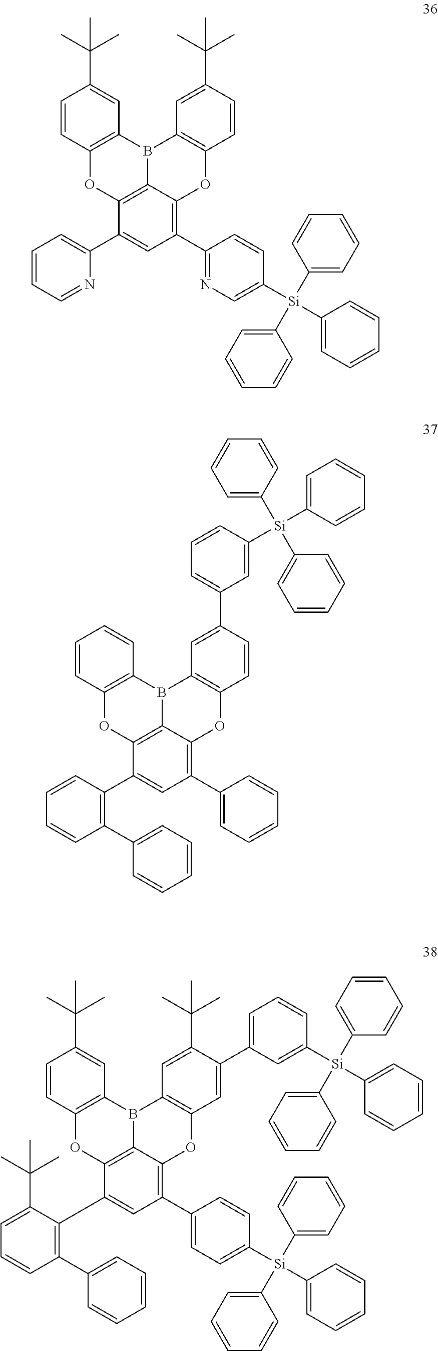 [SMILES: CC(C)(C)c1ccc2c(c1)B1c3cc(C(C)(C)C)ccc3Oc3c(-c4ccc([Si](c5ccccc5)(c5ccccc5)c5ccccc5)cn4)cc(-c4ccccn4)c(c31)O2 ; c1ccc(-c2ccccc2-c2cc(-c3ccccc3)c3c4c2Oc2ccccc2B4c2cc(-c4cccc([Si](c5ccccc5)(c5ccccc5)c5ccccc5)c4)ccc2O3)cc1 ; CC(C)(C)c1ccc2c(c1)B1c3cc(C(C)(C)C)c(-c4cccc([Si](c5ccccc5)(c5ccccc5)c5ccccc5)c4)cc3Oc3c(-c4ccc([Si](c5ccccc5)(c5ccccc5)c5ccccc5)cc4)cc(-c4c(-c5ccccc5)cccc4C(C)(C)C)c(c31)O2]

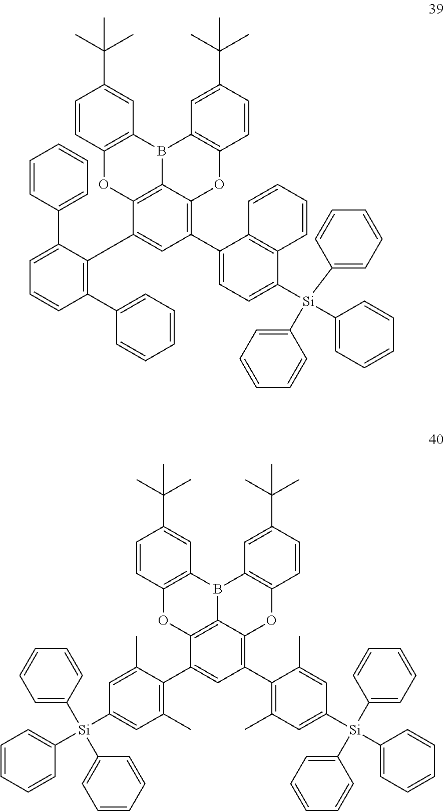 [SMILES: CC(C)(C)c1ccc2c(c1)B1c3cc(C(C)(C)C)ccc3Oc3c(-c4ccc([Si](c5ccccc5)(c5ccccc5)c5ccccc5)c5ccccc45)cc(-c4c(-c5ccccc5)cccc4-c4ccccc4)c(c31)O2 ; Cc1cc([Si](c2ccccc2)(c2ccccc2)c2ccccc2)cc(C)c1-c1cc(-c2c(C)cc([Si](c3ccccc3)(c3ccccc3)c3ccccc3)cc2C)c2c3c1Oc1ccc(C(C)(C)C)cc1B3c1cc(C(C)(C)C)ccc1O2]

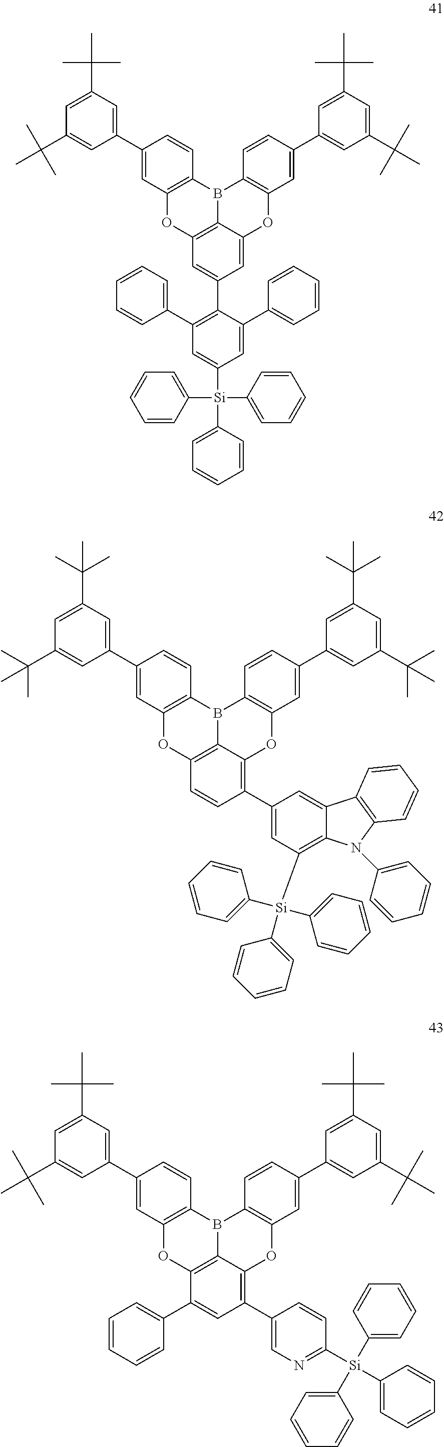

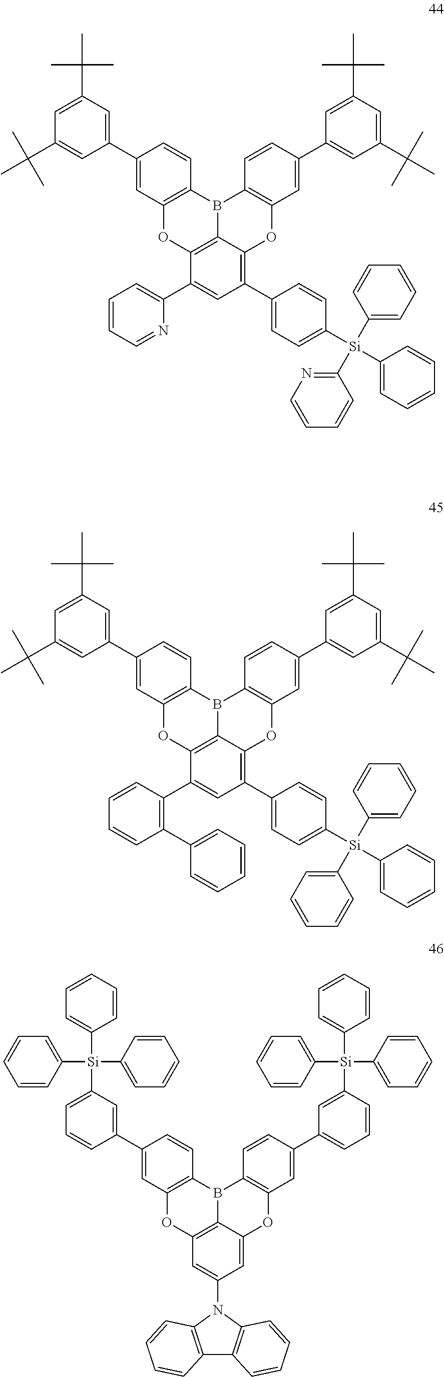 [SMILES: CC(C)(C)c1cc(-c2ccc3c(c2)Oc2c(-c4ccc([Si](c5ccccc5)(c5ccccc5)c5ccccn5)cc4)cc(-c4ccccn4)c4c2B3c2ccc(-c3cc(C(C)(C)C)cc(C(C)(C)C)c3)cc2O4)cc(C(C)(C)C)c1 ; CC(C)(C)c1cc(-c2ccc3c(c2)Oc2c(-c4ccc([Si](c5ccccc5)(c5ccccc5)c5ccccc5)cc4)cc(-c4ccccc4-c4ccccc4)c4c2B3c2ccc(-c3cc(C(C)(C)C)cc(C(C)(C)C)c3)cc2O4)cc(C(C)(C)C)c1 ; c1ccc([Si](c2ccccc2)(c2ccccc2)c2cccc(-c3ccc4c(c3)Oc3cc(-n5c6ccccc6c6ccccc65)cc5c3B4c3ccc(-c4cccc([Si](c6ccccc6)(c6ccccc6)c6ccccc6)c4)cc3O5)c2)cc1]

The fused polycyclic compound represented by Formula 1 according to an embodiment includes at least one group represented by Formula 2 containing a silyl group as a substituent of an aromatic ring of the fused ring core, and thus may exhibit high thermal characteristics, and high triplet energy (T1).

The fused polycyclic compound represented by Formula 1 according to an embodiment includes at least one group represented by Formula 2, and the silyl group in Formula 2 may be bonded to an aromatic ring of the fused ring core in Formula 1 via a linker, which is represented by L. The group represented by Formula 2 has a structure in which alkyl groups or aryl groups represented by Rₐ to R_{c} are bonded to a silicon atom. The group represented by Formula 2 having such a structure may be bonded to the fused polycyclic compound via a linker, and thus the fused polycyclic compound may have a high glass transition temperature and a high melting point. Therefore, when the fused polycyclic compound represented by Formula 1 above is applied to a light emitting device according to an embodiment, crystallization of an organic compound due to joule heating generated during the operation of the light emitting device is reduced, and thus the luminous efficiency and device service life characteristics of the light emitting device may be improved. The fused polycyclic compound according to an embodiment includes at least one group represented by Formula 2 as a substituent of the fused ring core, thereby increasing the rigidity of the molecule, so that a high triplet energy (T1) may be maintained, so that when the fused polycyclic compound is applied as a phosphorescent host or as a delayed fluorescent host in the light emitting device according to an embodiment, high luminous efficiency may be achieved. The fused polycyclic compound of an embodiment includes at least one bulky substituent in addition the group represented by Formula 2, so that intermolecular distance may be increased through steric hindrance, and thereby reducing interactions with a dopant compound. Thus, when the fused polycyclic compound is applied to a light emitting device, color purity may be improved and thin film uniformity may also be improved, and so that luminous efficiency and device service life characteristics may be further improved.

In an embodiment, the emission layer EML may include a host and a dopant, and the emission layer EML may include the above-described fused polycyclic compound as a host. The fused polycyclic compound represented by Formula 1 according to an embodiment may be a host material of the emission layer.

For example, the emission layer EML in the light emitting device ED according to an embodiment may include a host for emitting phosphorescence and a dopant for emitting phosphorescence, and the emission layer EML may include the above-described fused polycyclic compound of an embodiment as a host for emitting phosphorescence. In another embodiment, the emission layer EML in the light emitting device ED may include a host for emitting fluorescence and a dopant for emitting fluorescence, and the emission layer EML may include the above-described fused polycyclic compound of an embodiment as a host for emitting fluorescence.

The emission layer EML in the organic electroluminescence device ED according to an embodiment may include a host for emitting a delayed fluorescence and a dopant for emitting a delayed fluorescence, and the emission layer EML may include the above-described fused polycyclic compound according to an embodiment as a host for emitting delayed fluorescence. The emission layer EML in the light emitting device ED according to an embodiment may include a host for emitting a blue thermally activated delayed fluorescence (TADF) and a dopant for emitting a blue TADF, and the emission layer EML may include the above-described fused polycyclic compound according to an embodiment as a host for emitting a blue TADF. The emission layer EML may include at least one fused polycyclic compound selected from Compound Group 1 as described herein as a host material of the emission layer EML.

The emission layer EML in the light emitting device ED according to an embodiment may include a host. The host may serve to deliver energy to a dopant without emitting light in the light emitting device ED. The emission layer EML may include at least one kind of host. For example, the emission layer EML may include two or more kinds of different hosts. However, embodiments are not limited thereto, and the emission layer EML may include one kind of host, or a mixture of two or more kinds of different hosts.

In an embodiment, the emission layer EML may include two different hosts. The host may include a first compound represented by Formula 1, and a second compound that is different from the first compound. In an embodiment, the host may include a first compound represented by Formula 1, and a second compound represented by Formula H-1.

The emission layer EML according to an embodiment may include a second compound which may include a carbazole group derivative moiety. The second compound may be represented by Formula H-1:

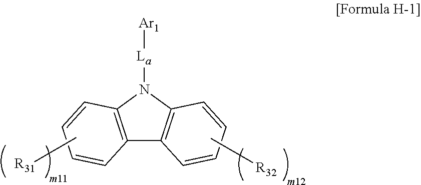

In Formula H-1, Lₐ may be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, Ar₁ may be a substituted or unsubstituted aryl group having 6 to 30 ring-forming carbon atoms, or a substituted or unsubstituted heteroaryl group having 2 to 30 ring-forming carbon atoms.

In Formula H-1, R₃₁ and R₃₂ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₃₁ and R₃₂ may each independently be a hydrogen atom or a deuterium atom.

In Formula H-1, m11 and m12 may each independently be an integer from 0 to 4. If m11 and m12 are each 0, the second compound according to an embodiment may not be substituted with R₃₁ and R₃₂. In Formula H-1, a case where m11 and m12 are each 4 and multiple groups of each of R₃₁ and R₃₂ are each a hydrogen atom may be the same as a case where m11 and m12 in Formula H-1 are each 0. When m11 and m12 are each 2 or more, multiple groups of each of R₃₁ and R₃₂ may each be the same or at least one thereof may be different from the others. For example, in Formula H-1, m11 and m12 may each be 0. Thus, the carbazole group in Formula H-1 may be unsubstituted.

In Formula H-1, Lₐ may be, for example, a direct linkage, a phenylene group, a divalent biphenyl group, a divalent carbazole group, etc., but embodiments are not limited thereto. Furthermore, Ar₁ may be, for example, a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

When the emission layer EML of the light emitting device ED according to an embodiment includes the first compound represented by Formula 1 and the second compound represented by Formula H-1 in the emission layer EML, the light emitting device ED may exhibit excellent luminous efficiency and long service life characteristics.

The emission layer EML in the light emitting device ED according to an embodiment may further include a third compound in addition to a first compound represented by Formula 1 as described herein. The emission layer EML may include, as the third compound, an organometallic complex containing platinum (Pt) as a central metal atom and ligands linked to the central metal atom. The emission layer EML in the light emitting device ED according to an embodiment may include a compound represented by Formula D-1 as the third compound:

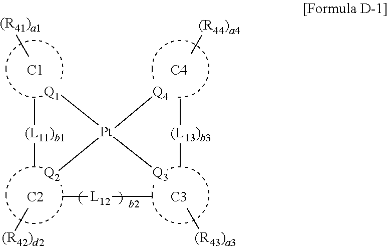

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

In Formula D-1, L₁₁ to L₁₃ may each independently be a direct linkage,

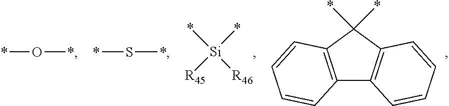

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, [symbol] represents a bonding site to one of C1 to C4.

In Formula D-1, b 1 to b3 may each independently be 0 or 1. If b1 is 0, C1 and C2 may not be linked to each other. If b2 is 0, C2 and C3 may not be linked to each other. If b3 is 0, C3 and C4 may not be linked to each other.

In Formula D-1, R₄₁ to R₄₆ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. For example, R₄₁ to R₄₆ may each independently be a methyl group or a t-butyl group.

In Formula D-1, a1 to a4 may each independently be an integer from 0 to 4. When a1 to a4 are each 2 or more, multiple groups of each of R₄₁ to R₄₄ may each be the same or at least one thereof may be different.

In an embodiment, in Formula D-1, C1 to C4 may each independently be a substituted or unsubstituted hydrocarbon ring or a substituted or unsubstituted heterocycle represented by any one of C-1 to C-4:

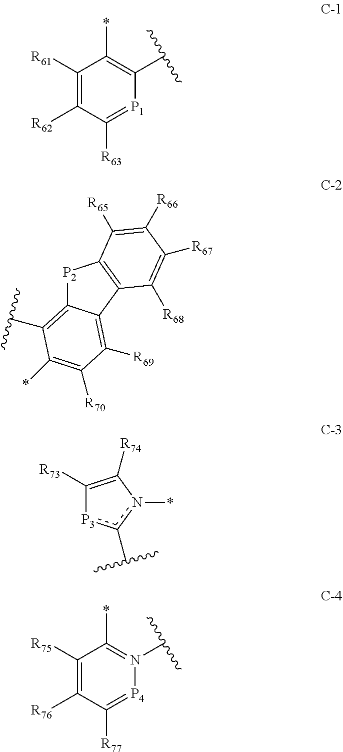

In C-1 to C-4, P₁ may be

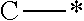 [SMILES: *C]

or C(R₆₄), P₂ may be

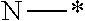 [SMILES: *N]

or N(R₇₁), P₃ may be

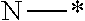 [SMILES: *N]

or N(R₇₂), and P₄ may be

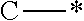 [SMILES: *C]

or C(R₇₈). In C-1 to C-4, R₆₁ to R₇₈ may each independently be a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring.

In C-1 to C-4,

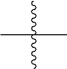

represents a bonding site to Pt that is a central metal atom, and [symbol] represents a bonding site to a neighboring cyclic group (C1 to C4) or to a linker (L₁₁ to L₁₃).

The third compound represented by Formula D-1 may be a phosphorescent dopant. In an embodiment, the third compound may be a light emitting dopant which emits blue light, and the emission layer EML may emit phosphorescence. For example, the emission layer EML may emit blue phosphorescence.

The emission layer EML in the light emitting device ED according to an embodiment may further include a fourth compound in addition a first compound represented by Formula 1 as described herein. The emission layer EML in the light emitting device ED according to an embodiment may include a compound represented by Formula D-2 as the fourth compound. The compound represented by Formula D-2 may be used as a thermally activated delayed fluorescent dopant material.

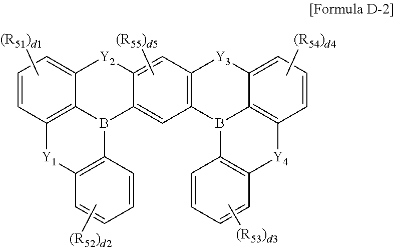

In Formula D-2, Y₁ to Y₄ may each independently be N(R₅₆), O or S.

In Formula D-2, R₅₁ to R₅₆ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring.

In Formula D-2, d1 and d4 may each independently be an integer from 0 to 3. In Formula D-2, d2 and d3 may each independently be an integer from 0 to 4. In Formula D-2, d5 may be an integer from 0 to 2. If d1 to d5 are each 0, the compound represented by Formula D-2 may not be substituted with R₅₁ to R₅₅. When d1 to d5 are each 2 or more, multiple groups of each of R₅₁ to R₅₅ may each be the same or at least one thereof may be different from the others.

The compound represented by Formula D-2 may be selected from Compounds BD-1 to BD-5. However, Compounds BD-1 to BD-5 are only examples, and the compound represented by Formula D-2 is not limited to Compounds BD-1 to BD-5:

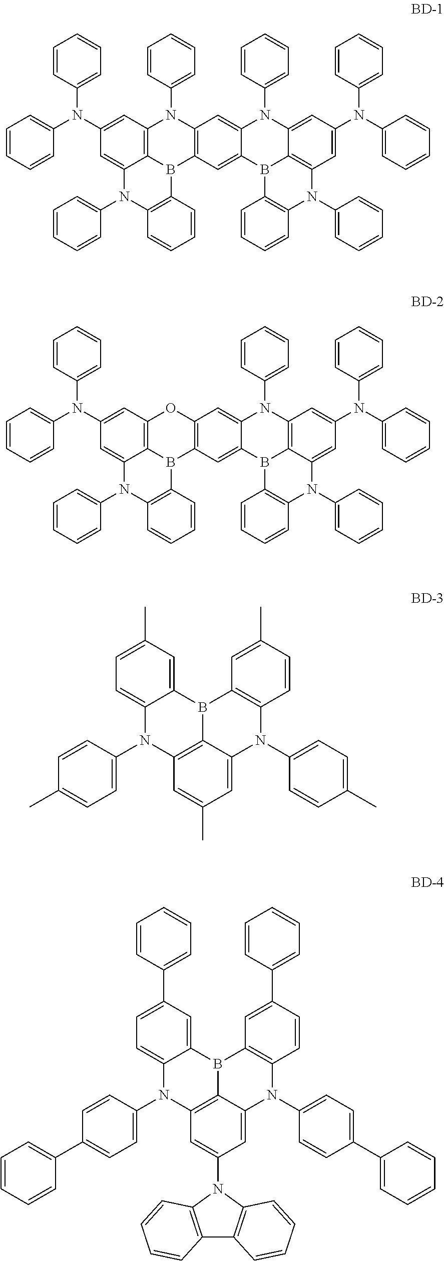

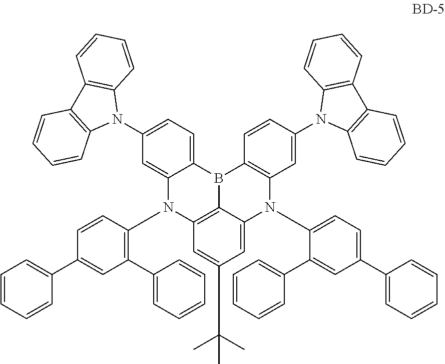 [SMILES: CC(C)(C)c1cc2c3c(c1)N(c1ccc(-c4ccccc4)cc1-c1ccccc1)c1cc(-n4c5ccccc5c5ccccc54)ccc1B3c1ccc(-n3c4ccccc4c4ccccc43)cc1N2c1ccc(-c2ccccc2)cc1-c1ccccc1]

The fourth compound represented by Formula D-2 as described herein may be a delayed fluorescent dopant. In an embodiment, the fourth compound may be a light emitting dopant which emits blue light, and the emission layer EML may emit delayed fluorescence. For example, the emission layer EML may emit blue delayed fluorescence.

In an embodiment, the second compound represented by Formula H-1 may be selected from Compound Group 2. The emission layer EML may include at least one compound selected from Compound Group 2 as a host material.

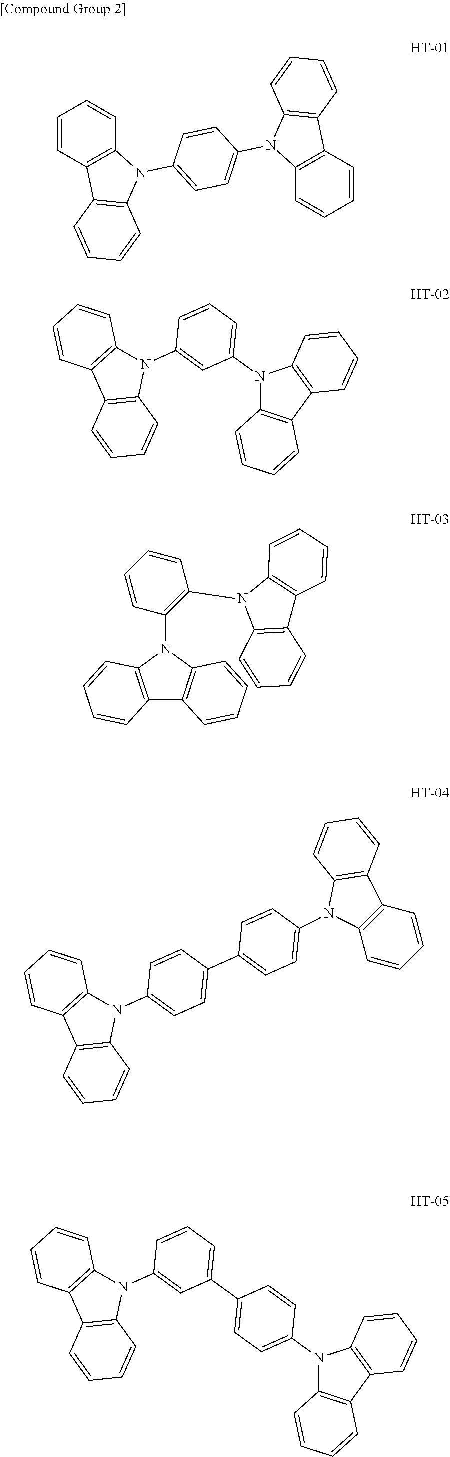 [SMILES: c1ccc2c(c1)c1ccccc1n2-c1ccc(-n2c3ccccc3c3ccccc32)cc1 ; c1cc(-n2c3ccccc3c3ccccc32)cc(-n2c3ccccc3c3ccccc32)c1 ; c1ccc(-n2c3ccccc3c3ccccc32)c(-n2c3ccccc3c3ccccc32)c1 ; c1ccc2c(c1)c1ccccc1n2-c1ccc(-c2ccc(-n3c4ccccc4c4ccccc43)cc2)cc1 ; c1cc(-c2ccc(-n3c4ccccc4c4ccccc43)cc2)cc(-n2c3ccccc3c3ccccc32)c1]

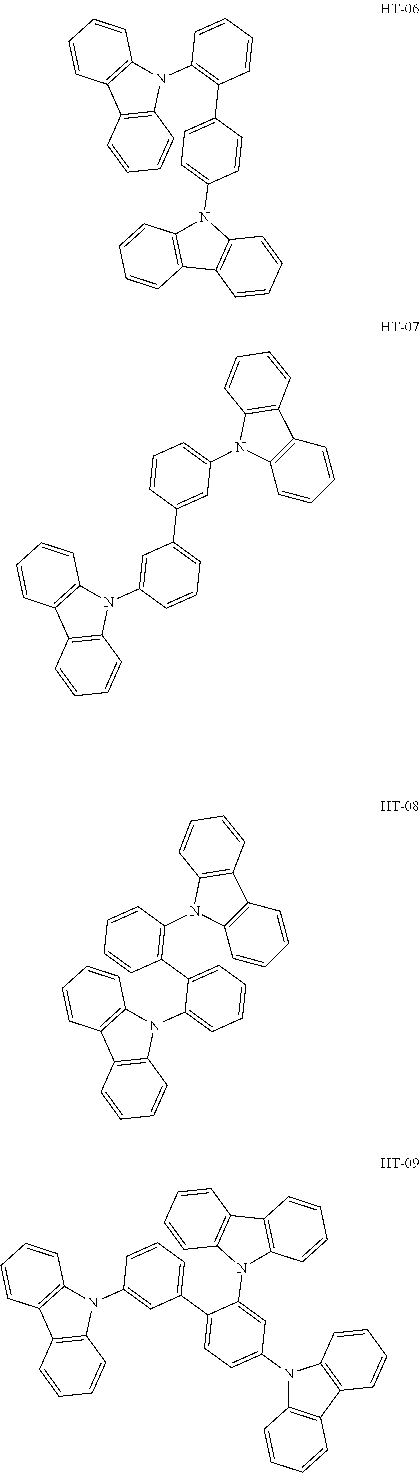 [SMILES: c1ccc(-n2c3ccccc3c3ccccc32)c(-c2ccc(-n3c4ccccc4c4ccccc43)cc2)c1 ; c1cc(-c2cccc(-n3c4ccccc4c4ccccc43)c2)cc(-n2c3ccccc3c3ccccc32)c1 ; c1ccc(-n2c3ccccc3c3ccccc32)c(-c2ccccc2-n2c3ccccc3c3ccccc32)c1 ; c1cc(-c2ccc(-n3c4ccccc4c4ccccc43)cc2-n2c3ccccc3c3ccccc32)cc(-n2c3ccccc3c3ccccc32)c1]

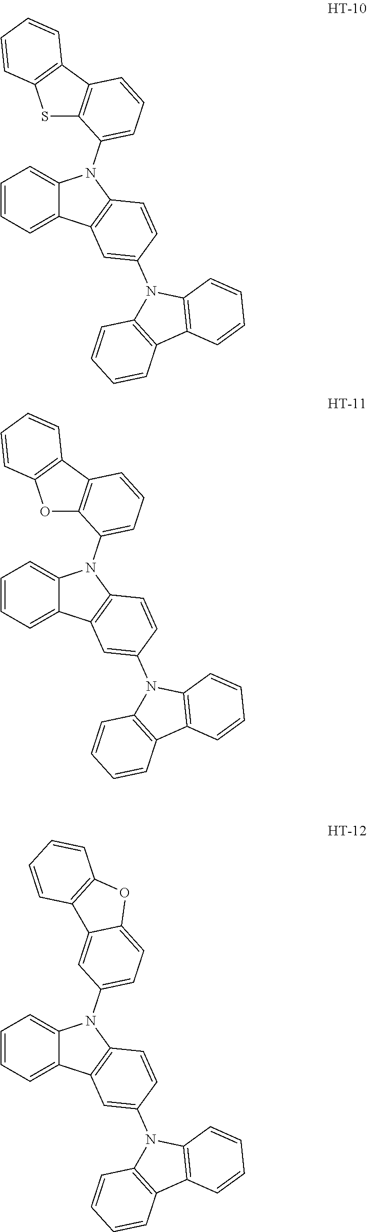 [SMILES: c1ccc2c(c1)sc1c(-n3c4ccccc4c4cc(-n5c6ccccc6c6ccccc65)ccc43)cccc12 ; c1ccc2c(c1)oc1c(-n3c4ccccc4c4cc(-n5c6ccccc6c6ccccc65)ccc43)cccc12 ; c1ccc2c(c1)oc1ccc(-n3c4ccccc4c4cc(-n5c6ccccc6c6ccccc65)ccc43)cc12]

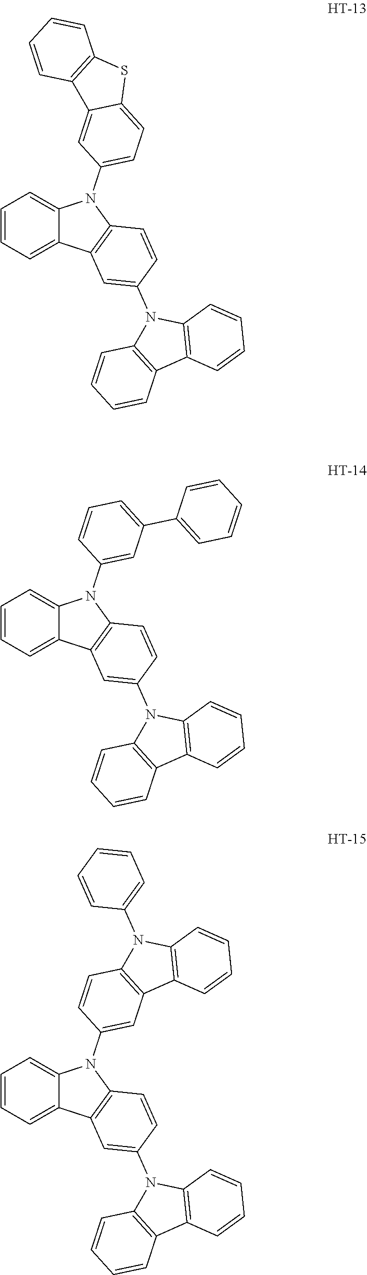

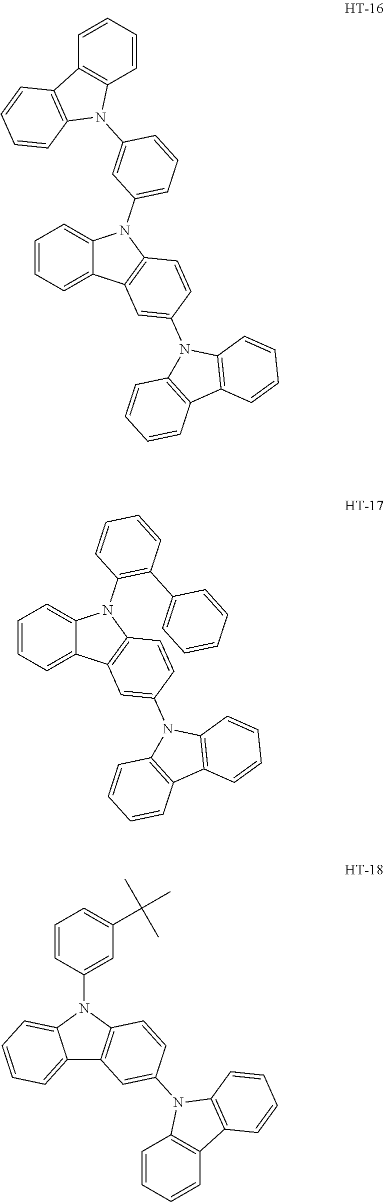 [SMILES: c1cc(-n2c3ccccc3c3ccccc32)cc(-n2c3ccccc3c3cc(-n4c5ccccc5c5ccccc54)ccc32)c1 ; c1ccc(-c2ccccc2-n2c3ccccc3c3cc(-n4c5ccccc5c5ccccc54)ccc32)cc1 ; CC(C)(C)c1cccc(-n2c3ccccc3c3cc(-n4c5ccccc5c5ccccc54)ccc32)c1]

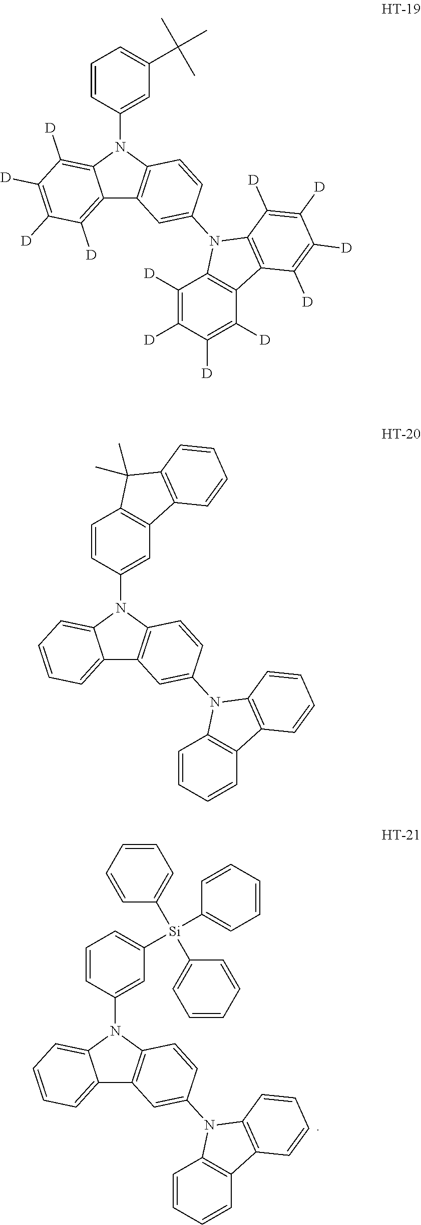 [SMILES: [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; CC1(C)c2ccccc2-c2cc(-n3c4ccccc4c4cc(-n5c6ccccc6c6ccccc65)ccc43)ccc21 ; c1ccc([Si](c2ccccc2)(c2ccccc2)c2cccc(-n3c4ccccc4c4cc(-n5c6ccccc6c6ccccc65)ccc43)c2)cc1]

In an embodiment, the third compound represented by Formula D-1 may be selected from Compound Group 3. The emission layer EML may include at least one compound selected from Compound Group 3 as a phosphorescent dopant material.

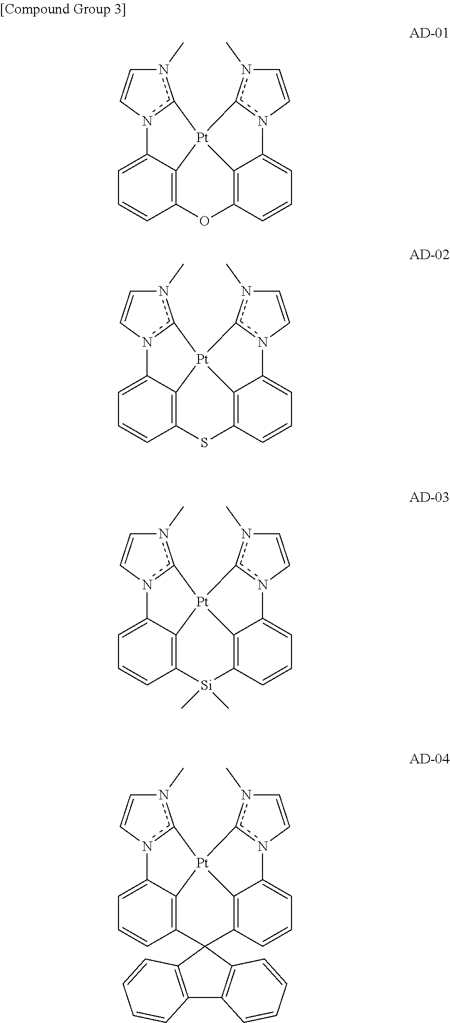

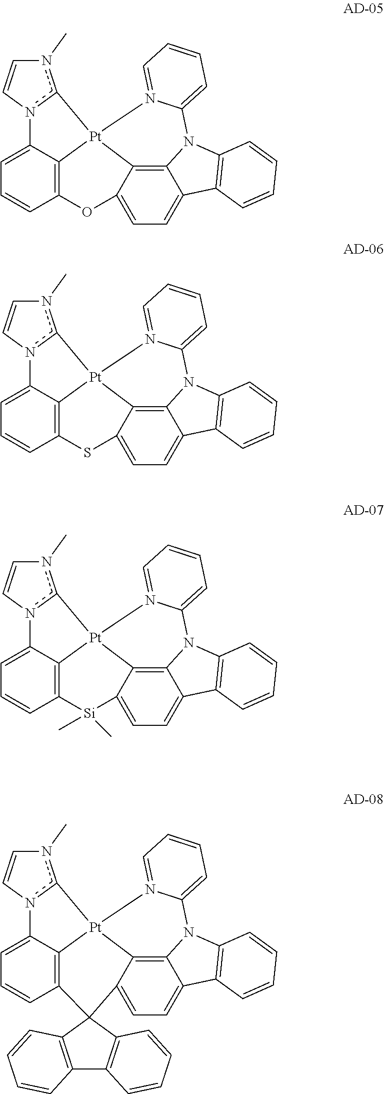

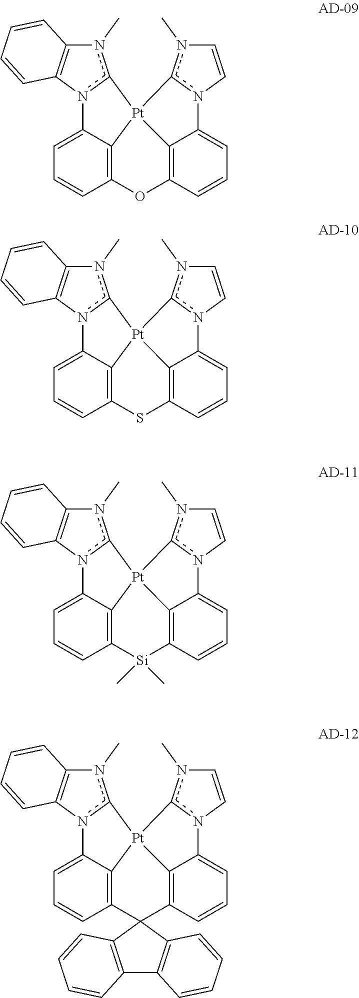

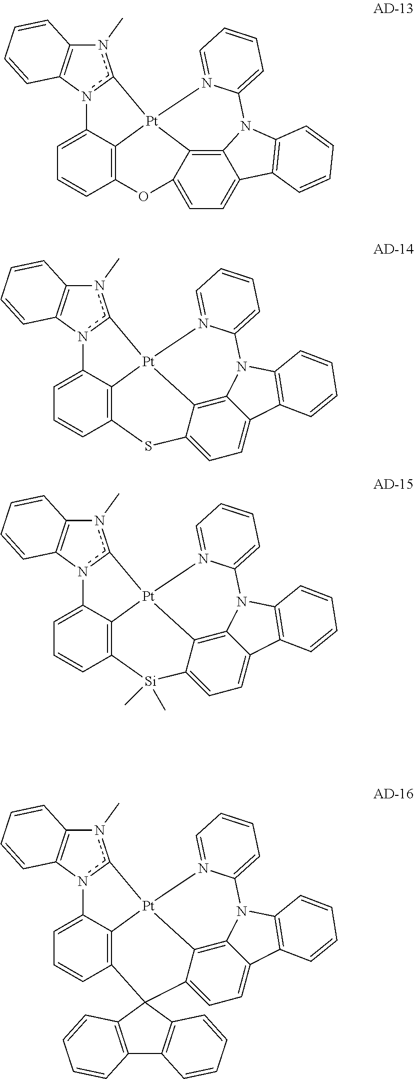

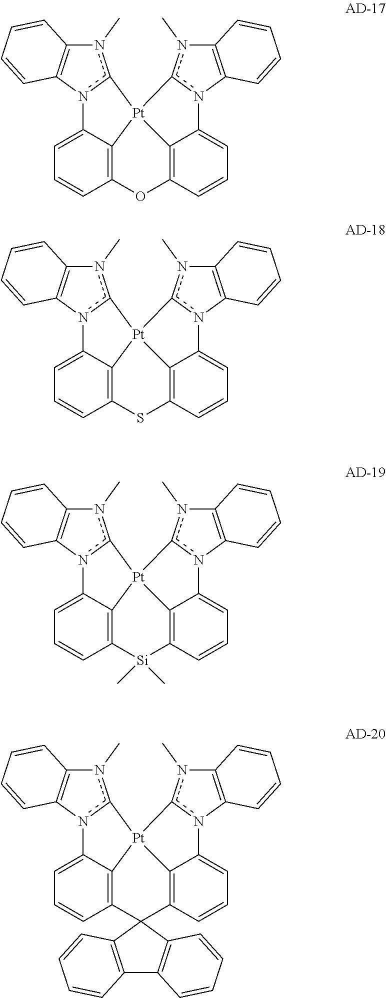

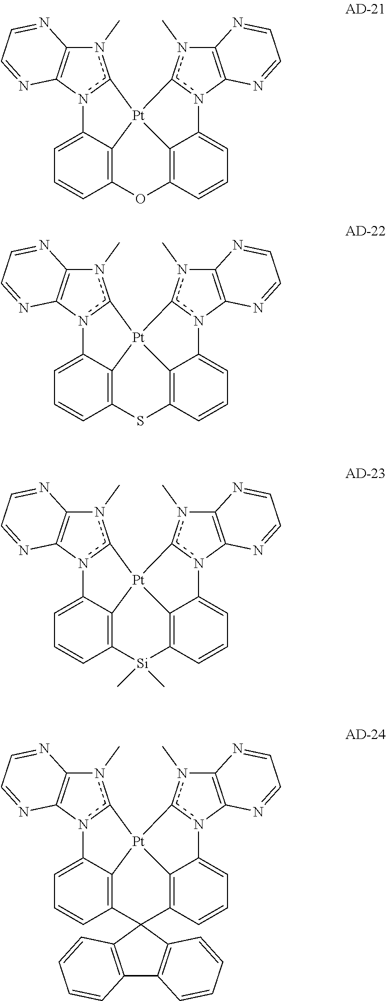

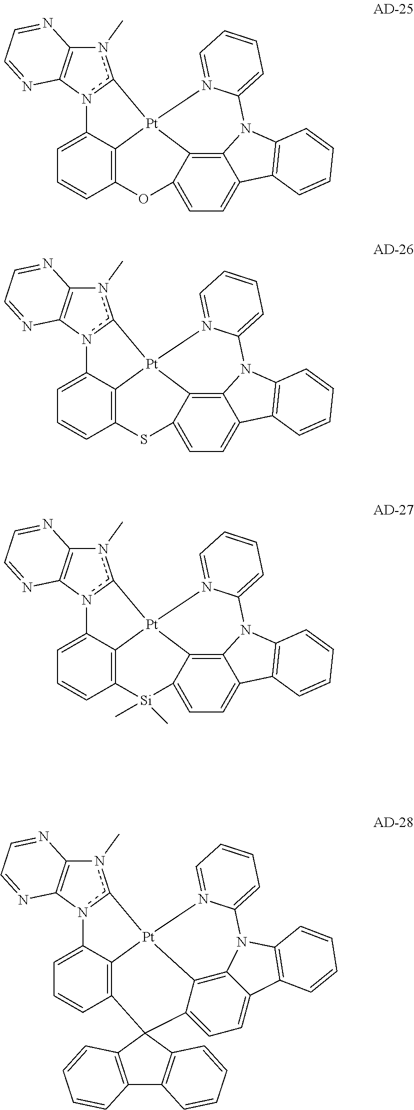

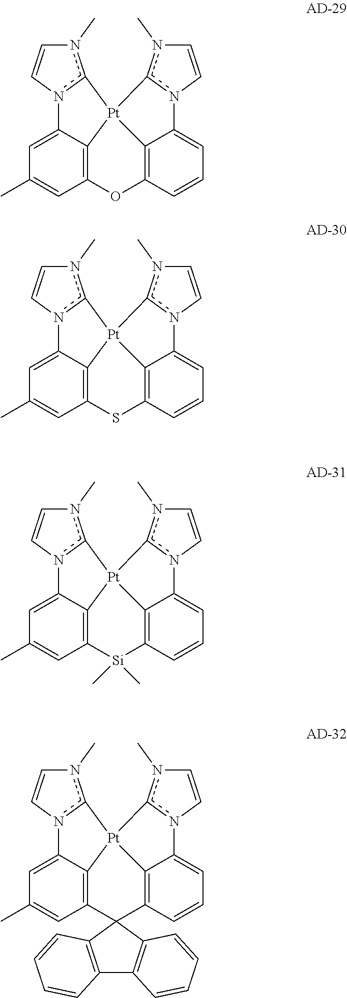

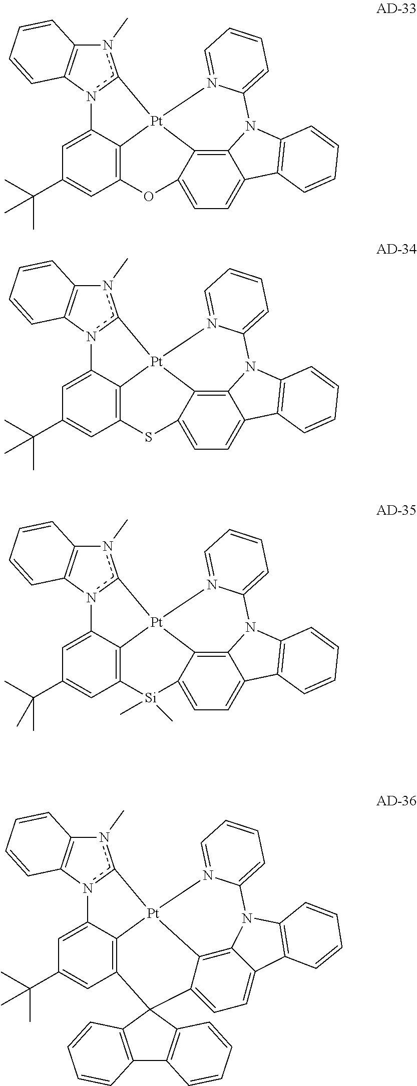

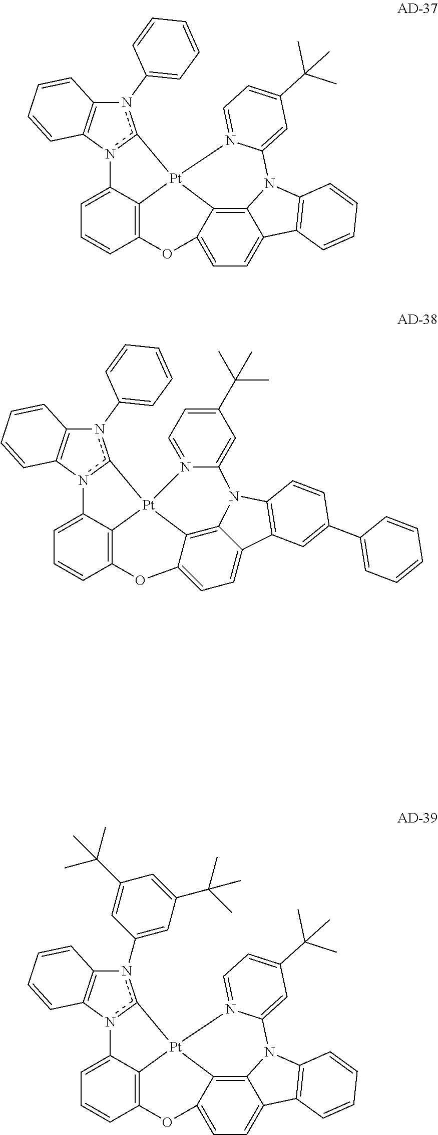

In an embodiment, the light emitting device ED may include multiple emission layers. The multiple emission layers may be provided as a stack. The light emitting device ED including multiple emission layers may emit white light. The light emitting device including multiple emission layers may be a light emitting device having a tandem structure. When the light emitting device ED includes multiple emission layers, at least one emission layer EML may include the first compound represented by Formula 1.

In the light emitting device ED according to an embodiment, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In each light emitting device ED according to embodiments illustrated in FIG. 3 to FIG. 6, the emission layer EML may further include a host of the related art and a dopant of the related art, in addition to the above-described host and dopant, and the emission layer EML may include a compound represented by Formula E-1. The compound represented by Formula E-1 may be used as a fluorescent host material.

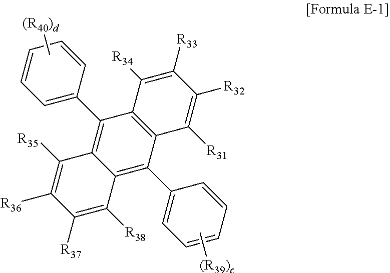

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 1 to 10 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. In Formula E-1, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be selected from Compound E1 to

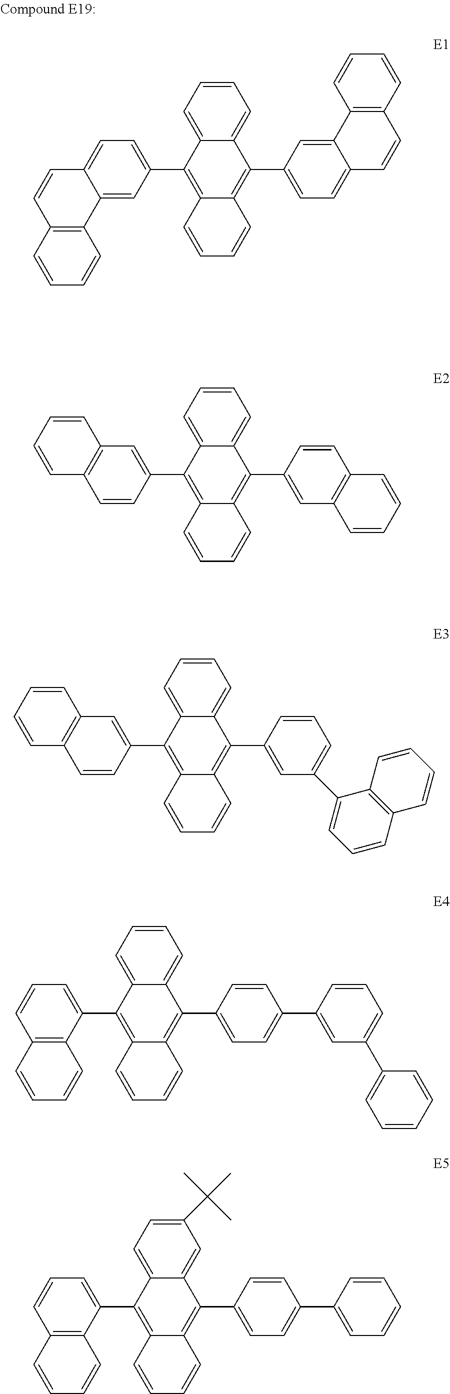

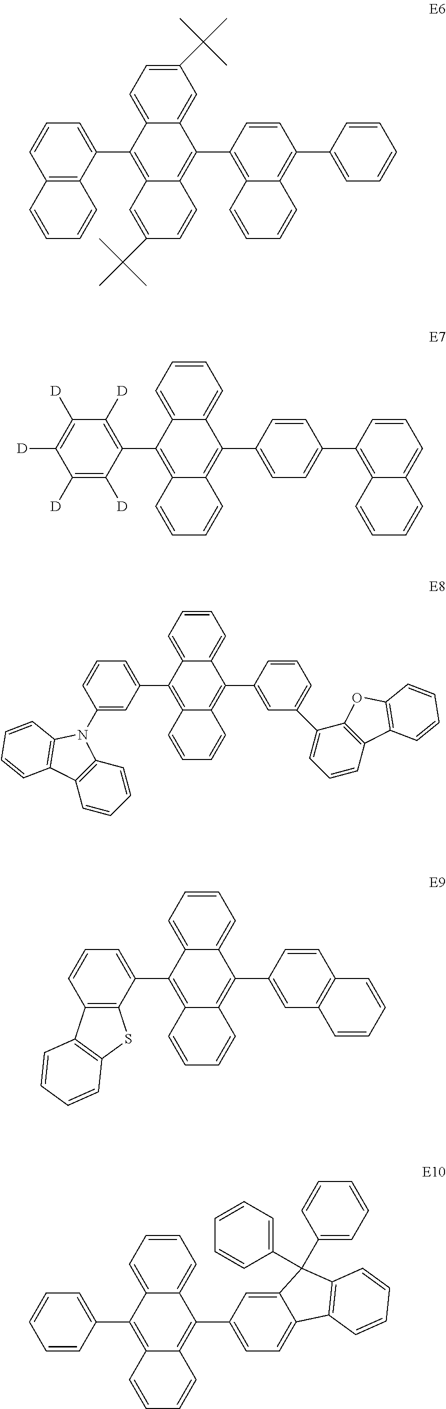

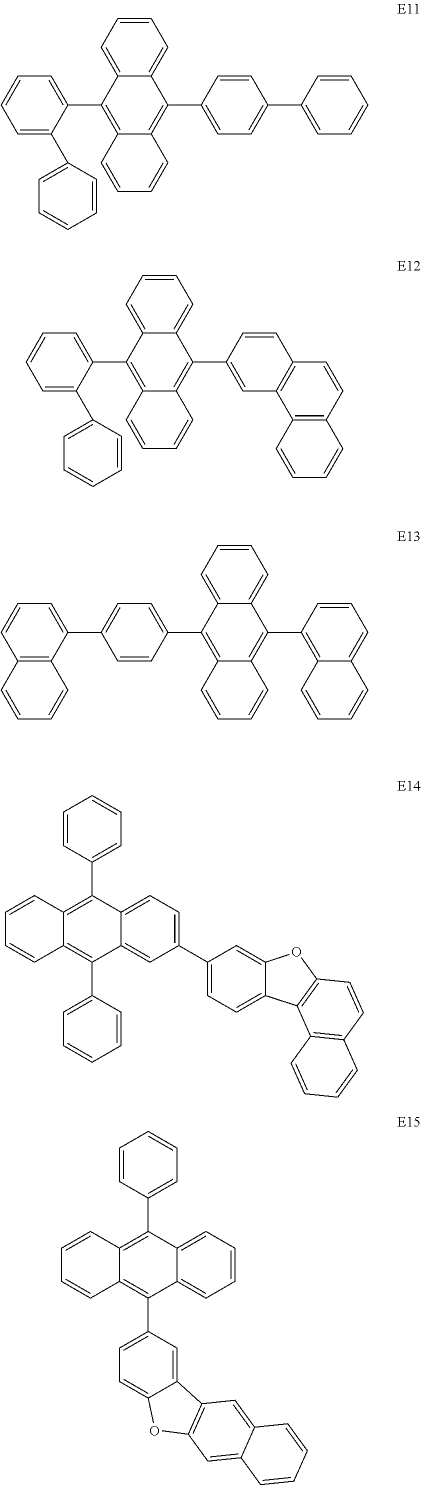

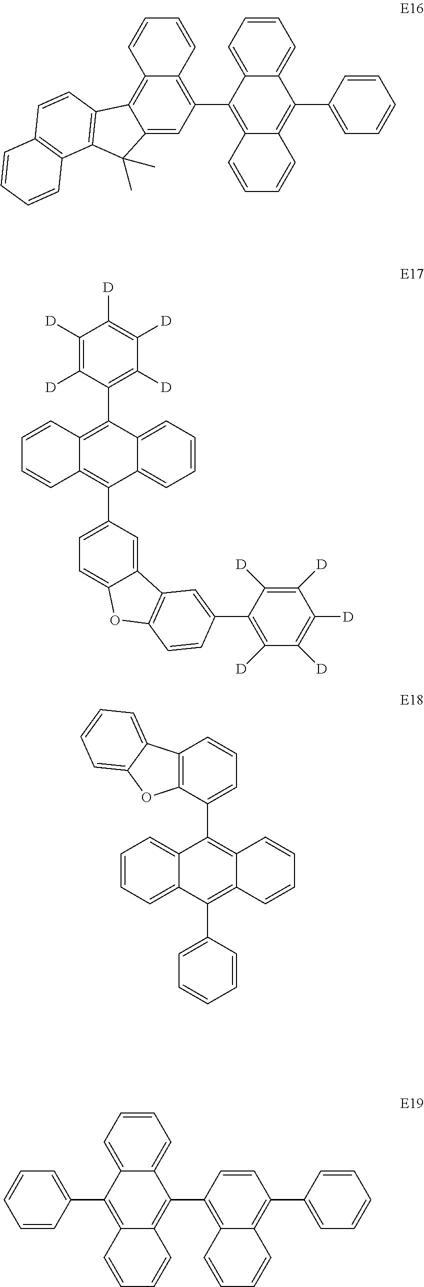

In an embodiment, the emission layer EML may include a compound represented by Formula E-2a or Formula E-2b. The compound represented by Formula E-2a or Formula E-2b may be used as a phosphorescent host material.

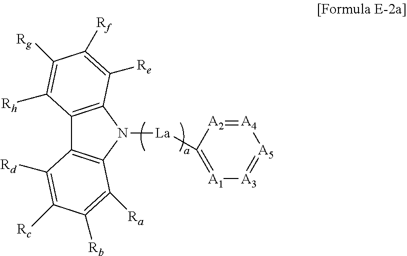

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or more, multiple Lₐ groups may each independently be a substituted or unsubstituted arylene group having 6 to 30 ring-forming carbon atoms, or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle containing N, O, S, etc. as a ring-forming atom.

In Formula E-2a, two or three of A₁ to A₅ may each be N, and the remainder of A₁ to A₅ may each independently be C(Rᵢ).

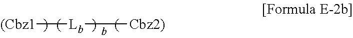

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or more, multiple L_{b} groups may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

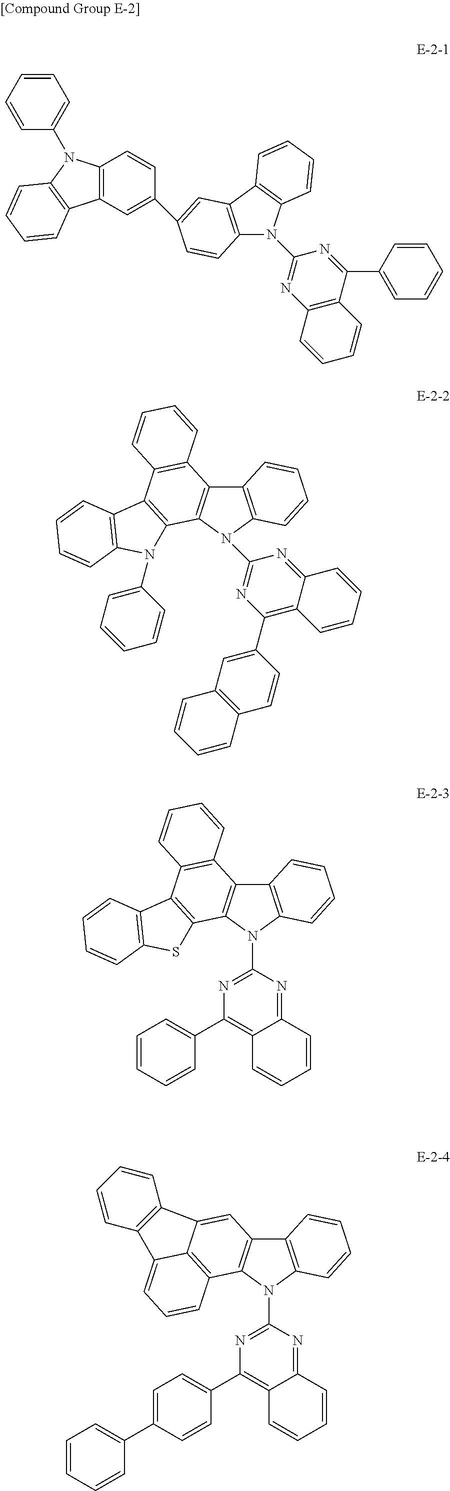 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1 ; c1ccc(-c2ccc(-c3nc(-n4c5ccccc5c5cc6c7c(cccc7c54)-c4ccccc4-6)nc4ccccc34)cc2)cc1]

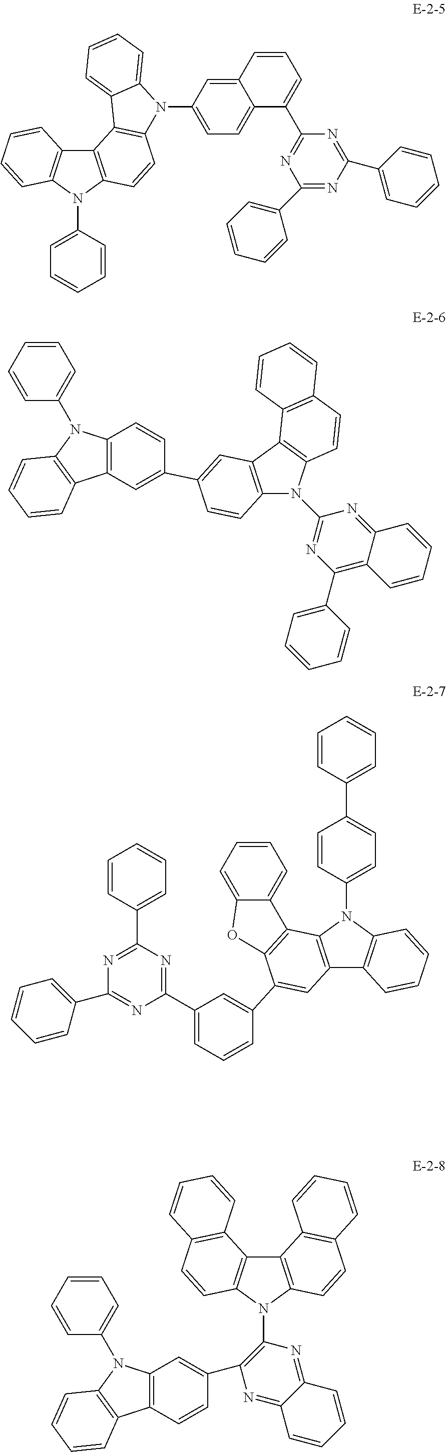 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

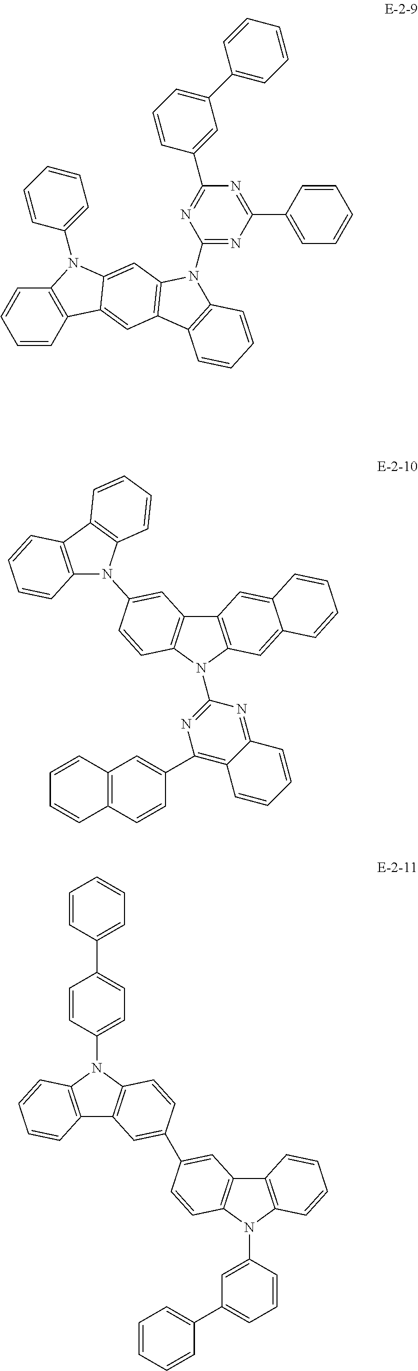 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

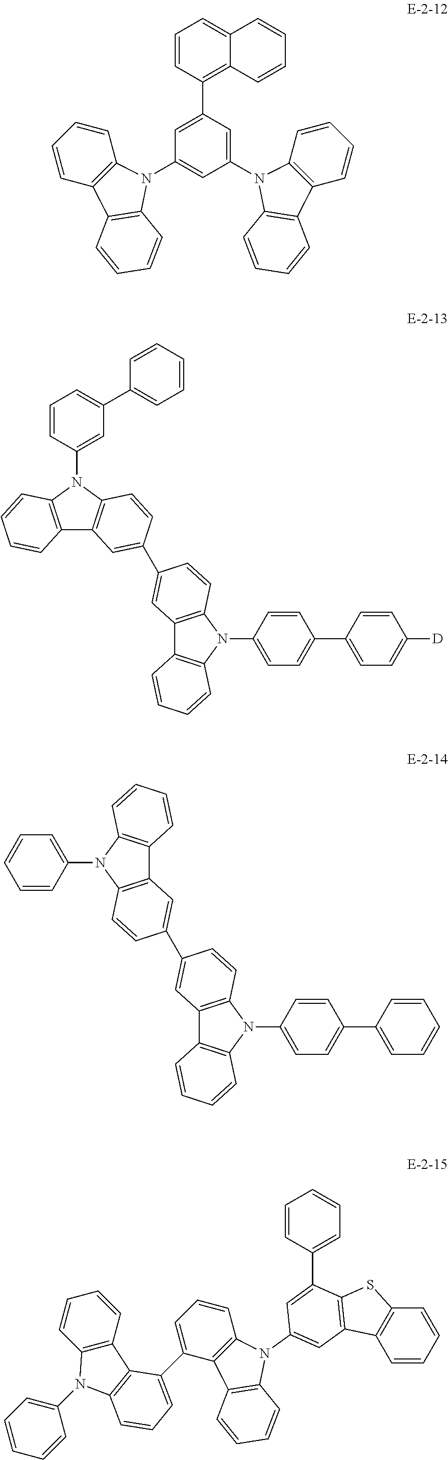 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

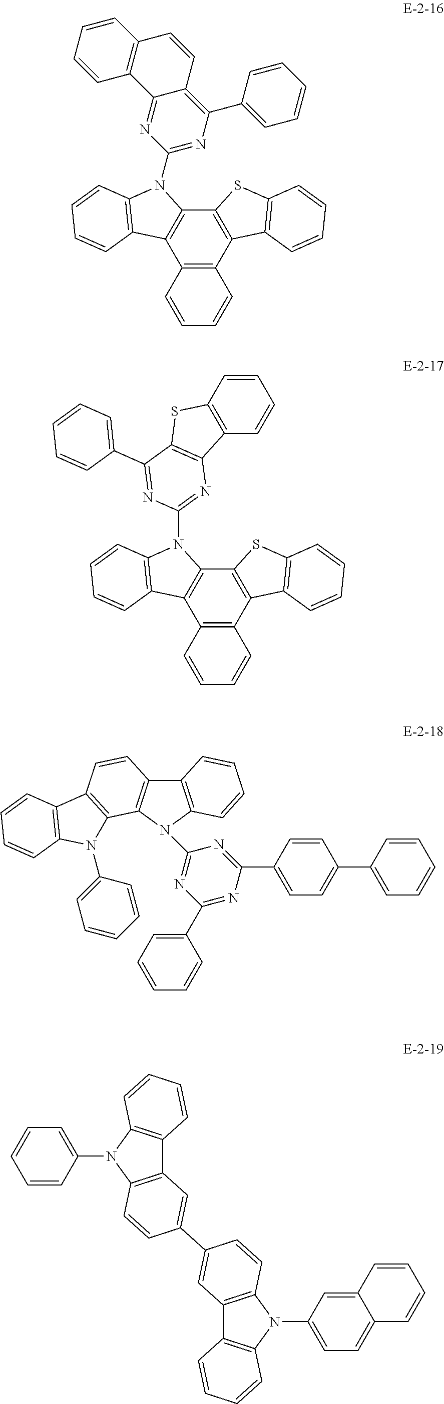 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

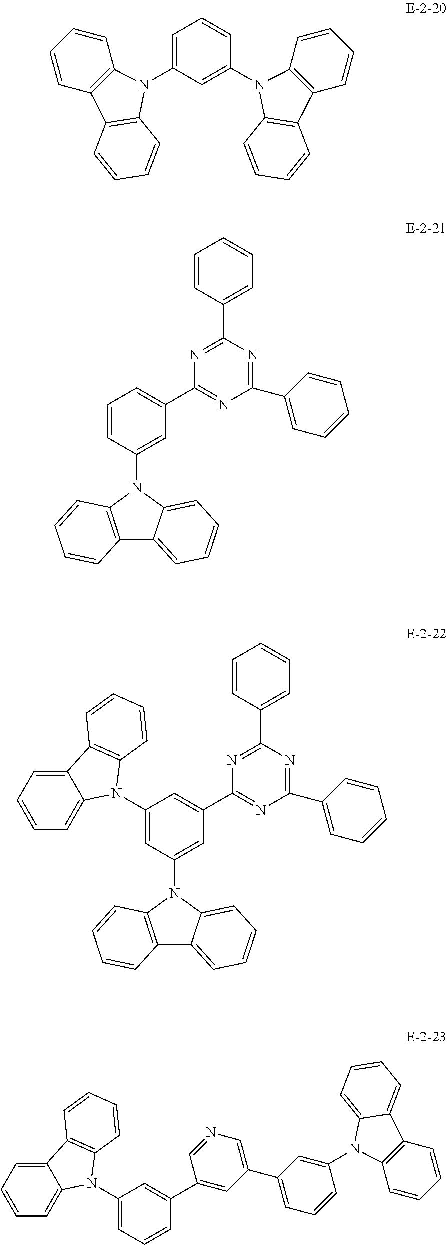 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

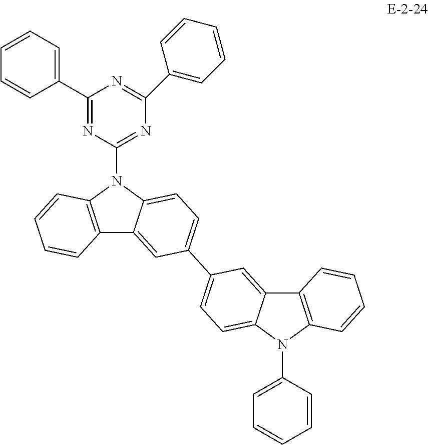 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto, and for example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenyl silyl)benzene (UGH2), hexaphenylcyclotrisiloxane (DPSiO₃), octaphenylcyclotetra siloxane (DPSiO₄), etc. may be used as a host material.

The emission layer EML may include a compound represented by Formula M-a. The compound represented by Formula M-a may be used as a phosphorescent dopant material.

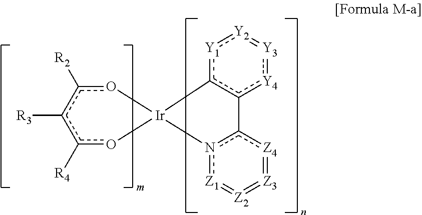

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be used as a phosphorescent dopant.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

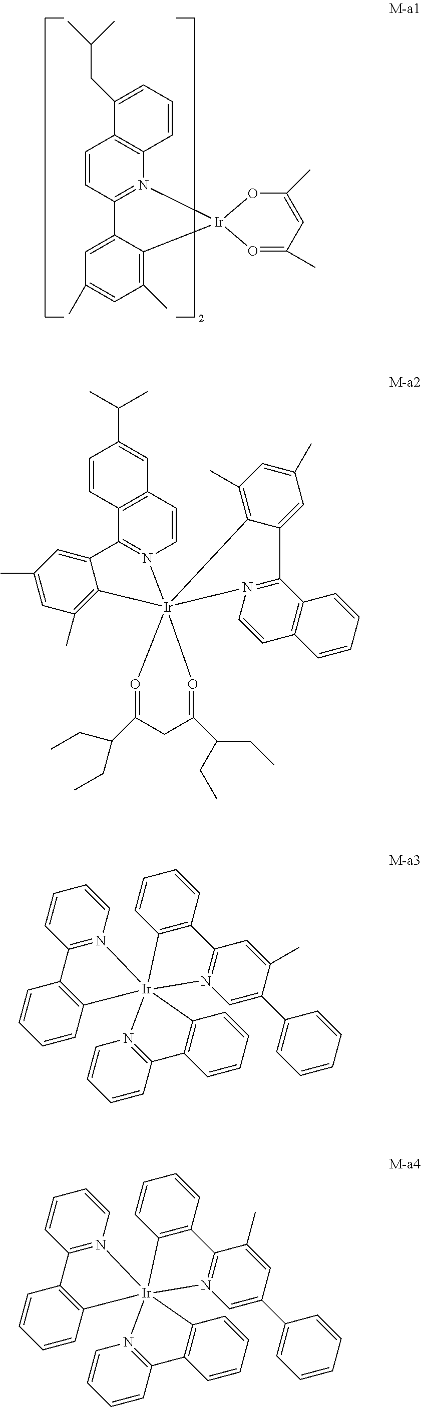

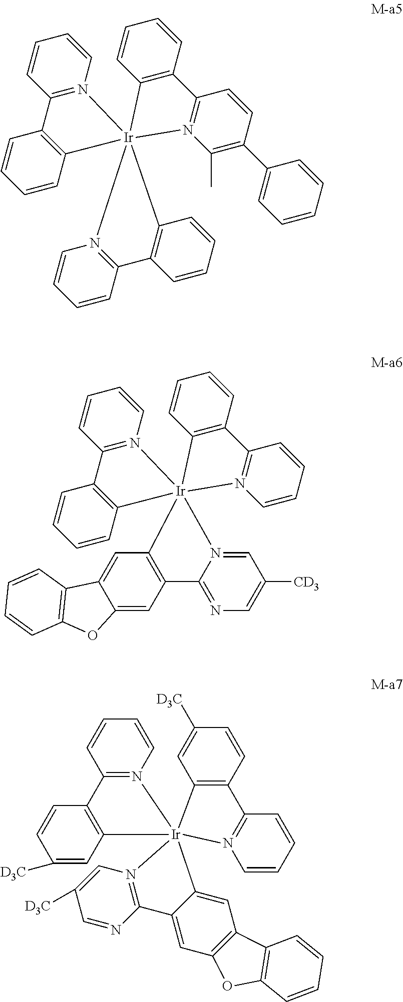

The emission layer EML may include a compound represented by Formula F-a or Formula F-b. The compound represented by Formula F-a or Formula F-b may be used as a fluorescent dopant material.

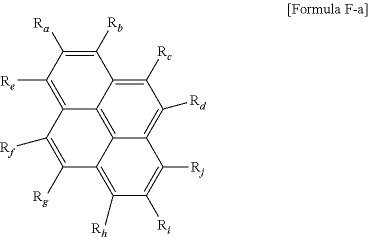

In Formula F-a, two of Rₐ to may each independently be substituted with a group represented by

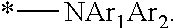

In Formula F-a, the remainder of Rₐ to Rⱼ which are not substituted with the group represented by

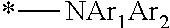

may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula F-a, the group represented by

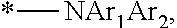

Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing 0 or S as a ring-forming atom.

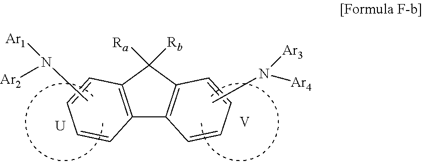

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. In Formula F-b, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. In Formula F-b, when the number of U or V is 1, a fused ring may be present at a portion indicated by U or V, and when the number of U or V is 0, a fused ring may not be present at a portion indicated by U or V. When the number of U is 0 and the number of V is 1, or when the number of U is 1 and the number of V is 0, a fused ring having a fluorene core of Formula F-b may be a cyclic compound having four rings. When the number of U and V is each 0, a fused ring having a fluorene core of Formula F-b may be a cyclic compound having three rings. When the number of U and V is each 1, a fused ring having a fluorene core of Formula F-b may be a cyclic compound having five rings.

In an embodiment, the emission layer EML may include, as a dopant material of the related art, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), etc.

The emission layer EML may include a phosphorescent dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), or platinum octaethyl porphyrin (PtOEP) may be used as a phosphorescence dopant. However, embodiments are not limited thereto.

In embodiments, the emission layer EML may include a quantum dot. The quantum dot may be a Group II-VI compound, a Group III-VI compound, a Group compound, a Group III-V compound, a Group III-II-V compound, a Group IV-VI compound, a Group IV element, a Group IV compound, or any combination thereof.

The Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof; or any combination thereof.

The Group III-VI compound may include: a binary compound such as In₂S₃ or In₂Se₃; a ternary compound such as InGaS₃ or InGaSe₃; or any combination thereof.

The Group compound may include: a ternary compound selected from the group consisting of AgInS, AgInS₂, CuInS, CuInS₂, AgGaS₂, CuGaS₂ CuGaO₂, AgGaO₂, AgAlO₂, and a mixture thereof; a quaternary compound such as AgInGaS₂ or CuInGaS₂; or any combination thereof.

The Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; or any combination thereof. In an embodiment, the Group III-V compound may further include a Group II metal. For example, InZnP, etc. may be selected as a Group V compound.

The Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof. The Group IV element may be Si, Ge, or a mixture thereof. The Group IV compound may include a binary compound selected from the group consisting of SiC, SiGe, or a mixture thereof.

A binary compound, a ternary compound, or a quaternary compound may be present in a particle at a uniform concentration distribution, or may be present in a particle at a partially different concentration distribution. In an embodiment, the quantum dot may have a core/shell structure in which one quantum dot surrounds another quantum dot. A quantum dot having a core/shell structure may have a concentration gradient in which the concentration of a material that is present in the shell decreases toward the core.

In embodiments, the quantum dot may have the above-described core/shell structure including a core containing nanocrystals and a shell surrounding the core. The shell of the quantum dot may serve as a protection layer to prevent the chemical deformation of the core to maintain semiconductor properties, and/or may serve as a charging layer to impart electrophoresis properties to the quantum dot. The shell may be a single layer or a multilayer. Examples of the shell of the quantum dot may include a metal oxide, a non-metal oxide, a semiconductor compound, or any combination thereof.

For example, the metal oxide or the non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; or any combination thereof. However, embodiments are not limited thereto.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. When the quantum dot has a FWHM of an emission wavelength spectrum in any of the above ranges, color purity or color reproducibility may be improved. Light emitted through a quantum dot may be emitted in all directions, so that a wide viewing angle may be improved.

The form of a quantum dot is not particularly limited, as long as it is any form that is used in the related art. For example, a quantum dot may have a spherical shape, a pyramidal shape, a multi-arm shape, or a cubic shape, or the quantum dot may be in the form of nanoparticles, nanotubes, nanowires, nanofibers, nanoparticles, etc.

A quantum dot may control the color of emitted light according to a particle size thereof. Accordingly, the quantum dot may have various light emission colors such as green, red, etc.

In the light emitting device ED according to embodiments illustrated in FIGS. 3 to 6, the electron transport region ETR is provided on the emission layer EML. The electron transport region ETR may include at least one of a hole blocking layer HBL, an electron transport layer ETL, or an electron injection layer EIL, but embodiments are not limited thereto.

The electron transport region ETR may be a layer formed of a single material, a layer formed of different materials, or a structure including multiple layers formed of different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. The electron transport region ETR may have a thickness, for example, in a range of about 1,000 Å to about 1,500 Å.

The electron transport region ETR may be formed by using various methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-1:

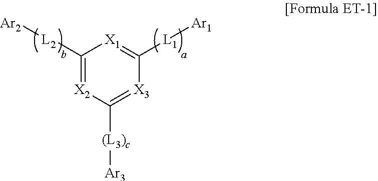

In Formula ET-1, at least one of X₁ to X₃ may each be N, and the remainder of X₁ to X₃ may each independently be C(Rₐ). In Formula ET-1, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula ET-1, when a to c are each 2 or more, multiple groups of each of L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-Bis[3,5-di(pyridin-3-yl)phenyl]benzene (BmPyPhB), or a mixture thereof.

In an embodiment, the electron transport region ETR may include at least one of Compound ET1 to Compound ET36:

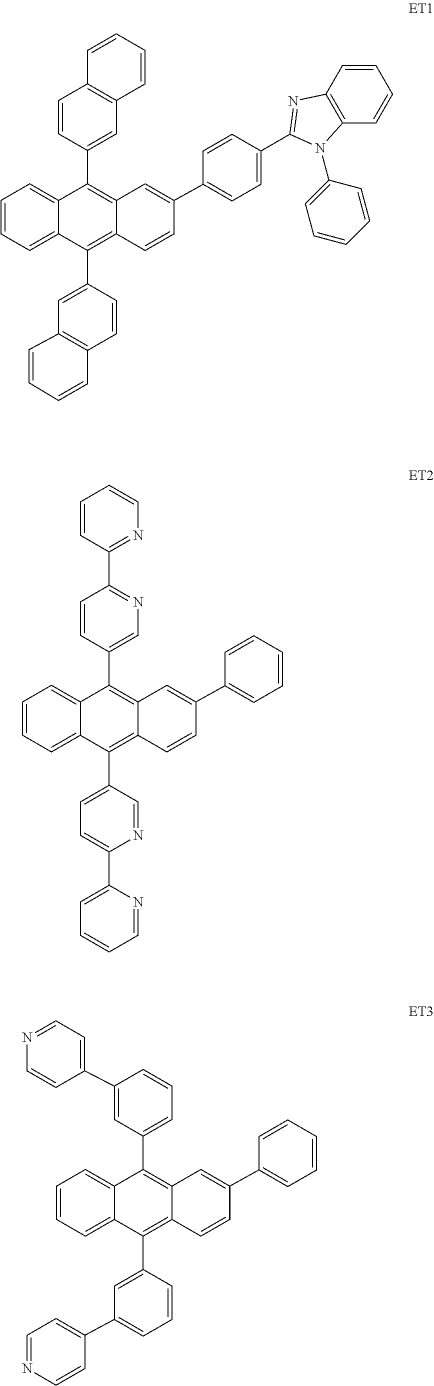 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

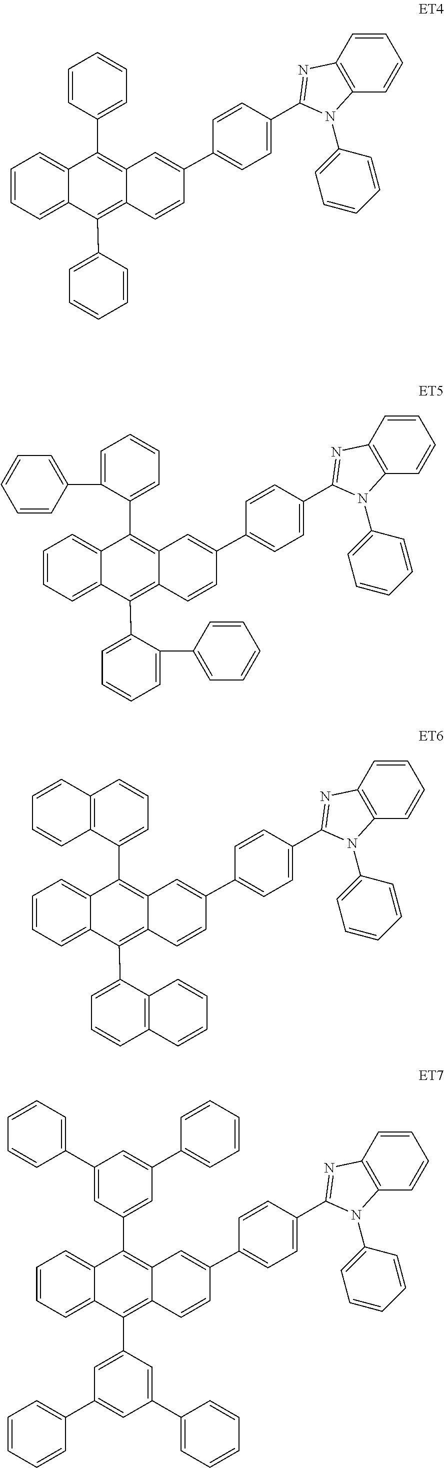 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

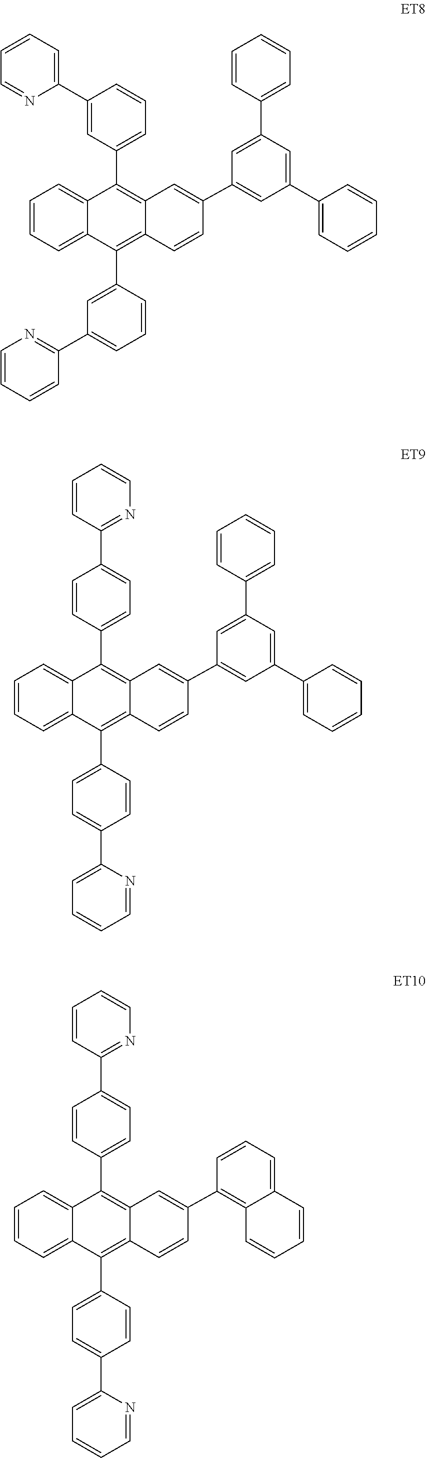 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

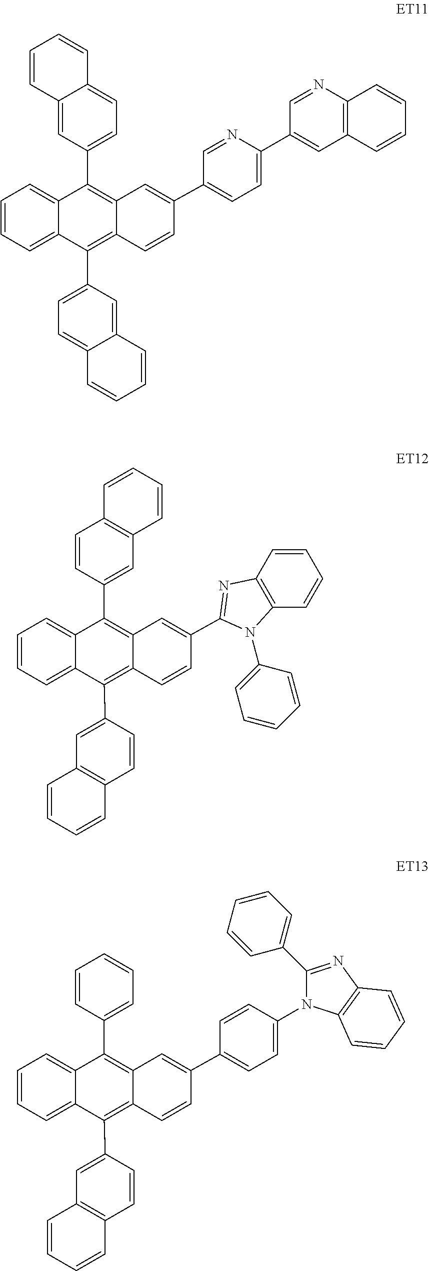 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

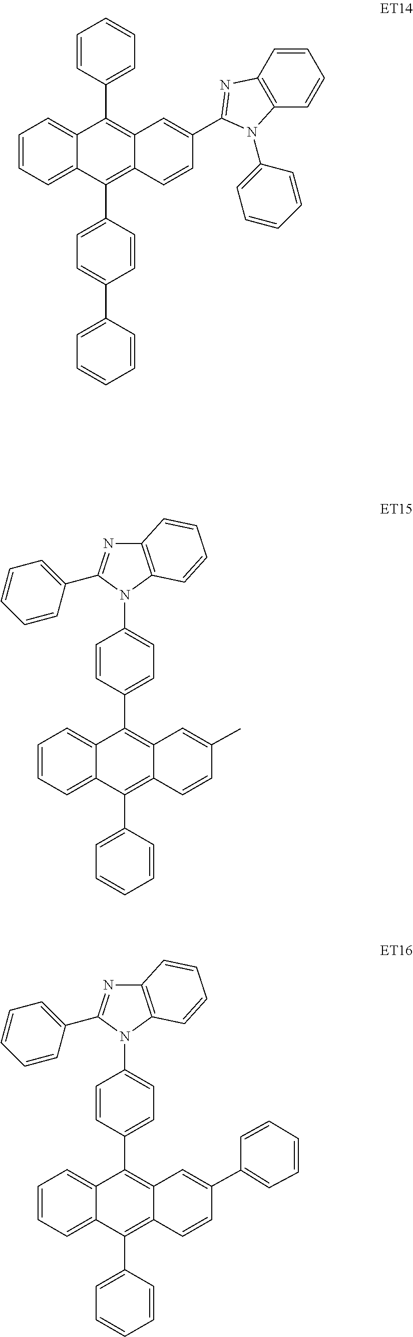 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

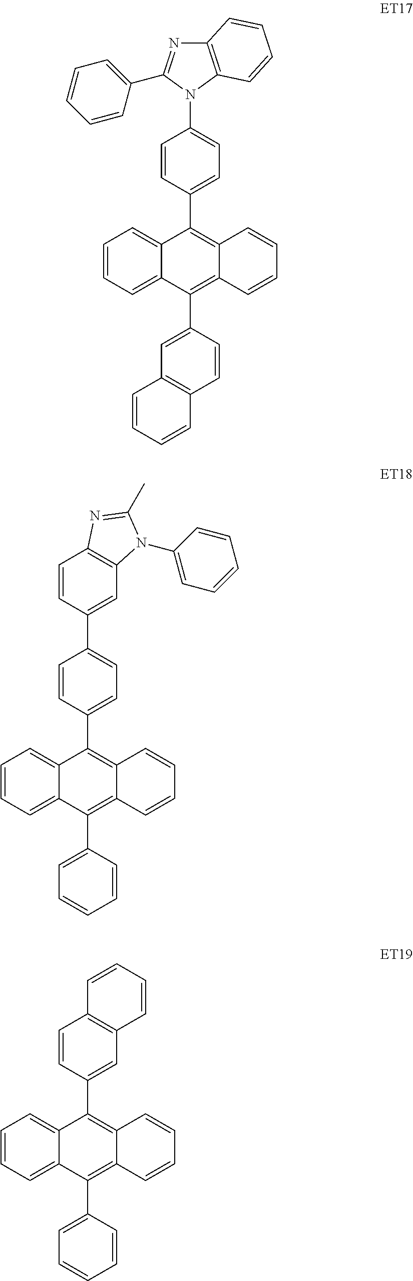

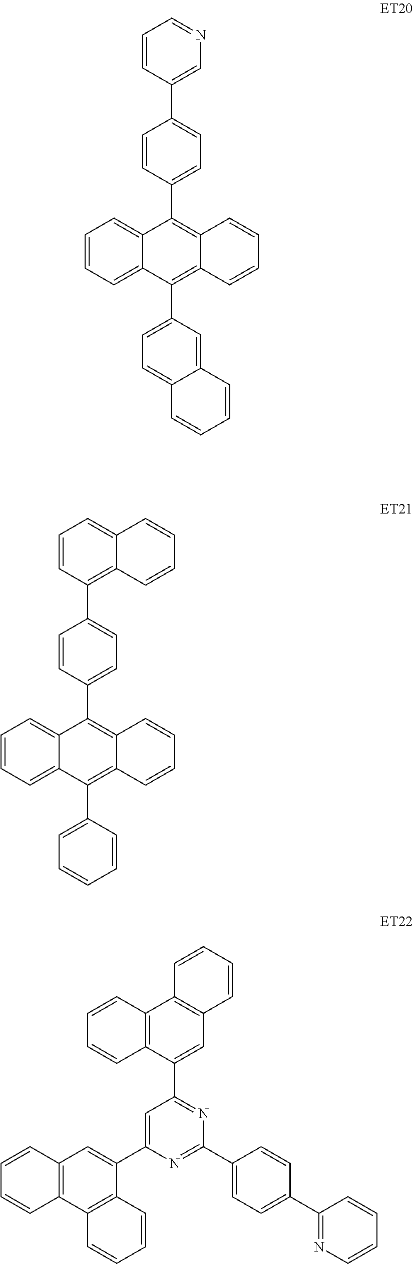

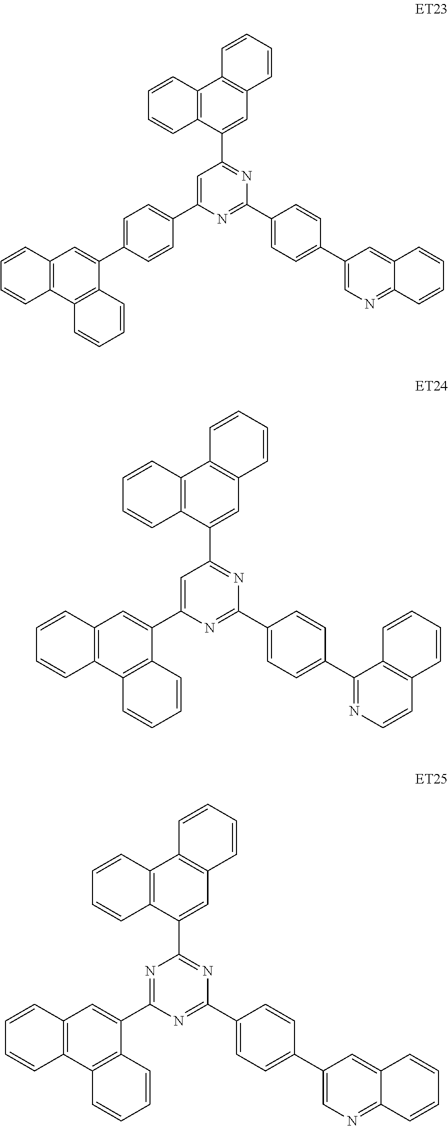 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

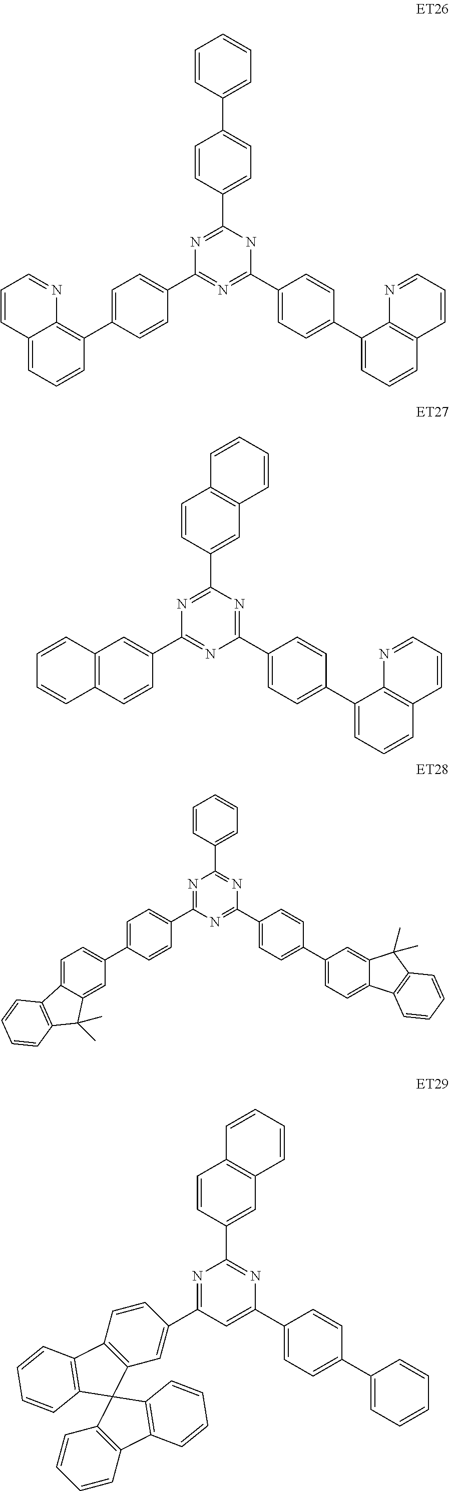

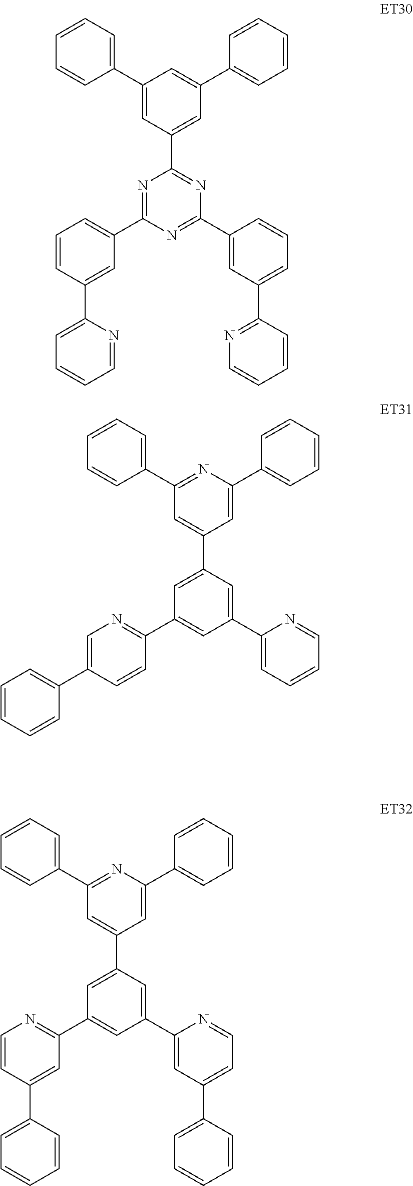

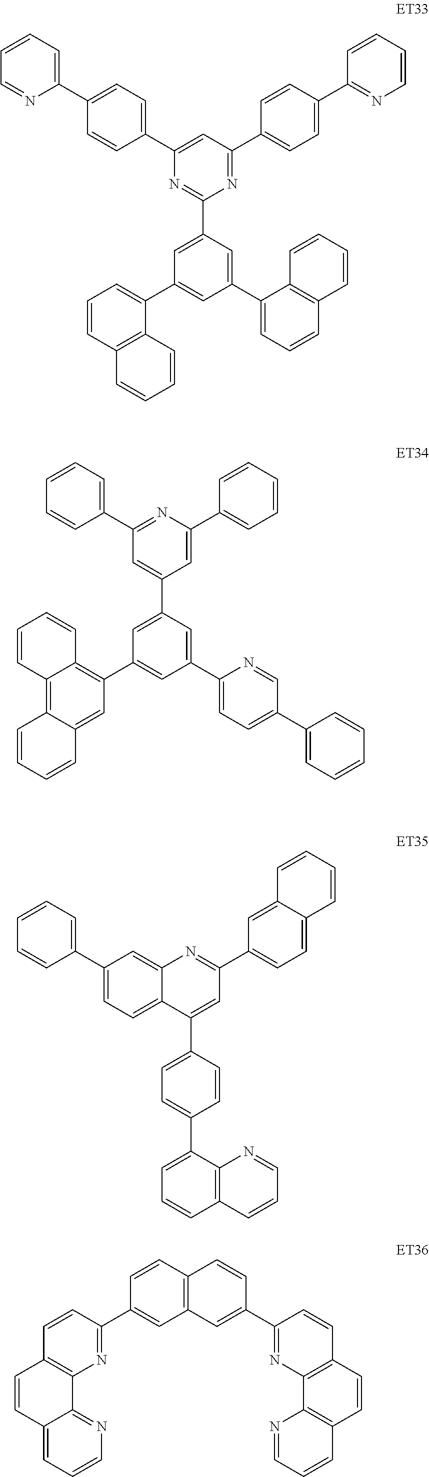 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

The electron transport regions ETR may include a metal halide such as LiF, NaCl, CsF, RbCl, RbI, CuI, or KI; a lanthanide metal such as Yb; or a co-deposited material of a metal halide and a lanthanide metal. For example, the electron transport region ETR may include KI:Yb, RbI:Yb, LiF:Yb, etc. as a co-deposited material. The electron transport region ETR may be formed of a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments are not limited thereto.

The electron transport region ETR may include the above-described compounds of the hole transport region in at least one of an electron injection layer EIL, an electron transport layer ETL, or a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode. The second electrode may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgAg). In another embodiment, the second electrode EL2 may have a multilayer structure including a reflective layer or a transflective layer formed of the above-described materials, and a transparent conductive layer formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, the resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL contains an inorganic material, the inorganic material may include an alkaline metal compound (for example, LiF), an alkaline earth metal compound (for example, MgF₂), SiON, SiNₓ, SiOy, etc.

For example, when the capping layer CPL contains an organic material, the organic material may include 2,2′-dimethyl-N,N′-di-[(1-naphthyl)-N,N′-diphenyl]-1,1′-biphenyl-4,4′-diamine (α-NPD), NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as a methacrylate. However, embodiments are not limited thereto, and the capping layer CPL may include at least one of Compounds P1 to P6:

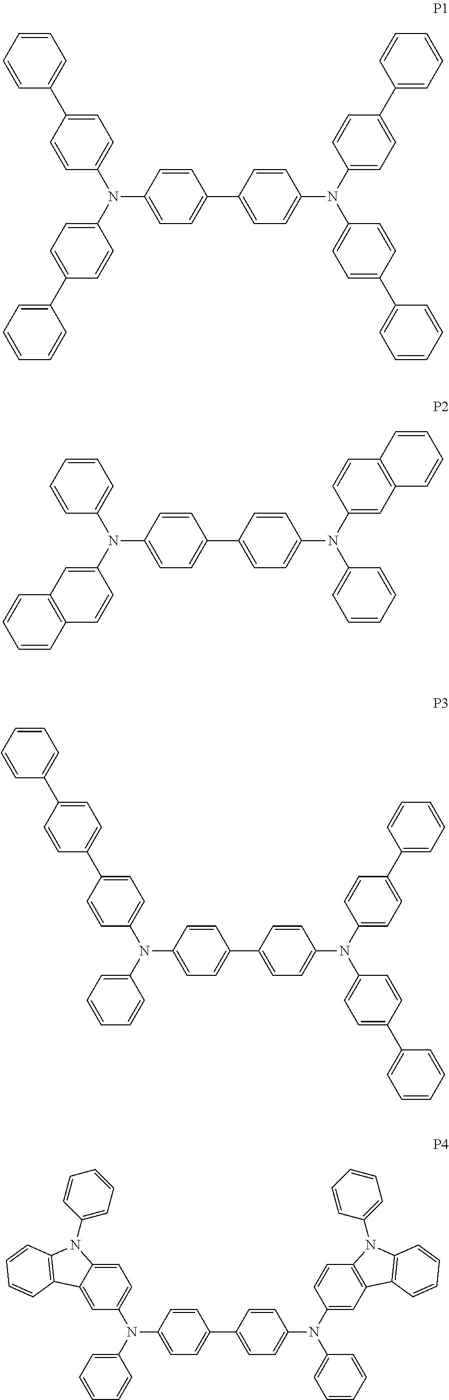 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

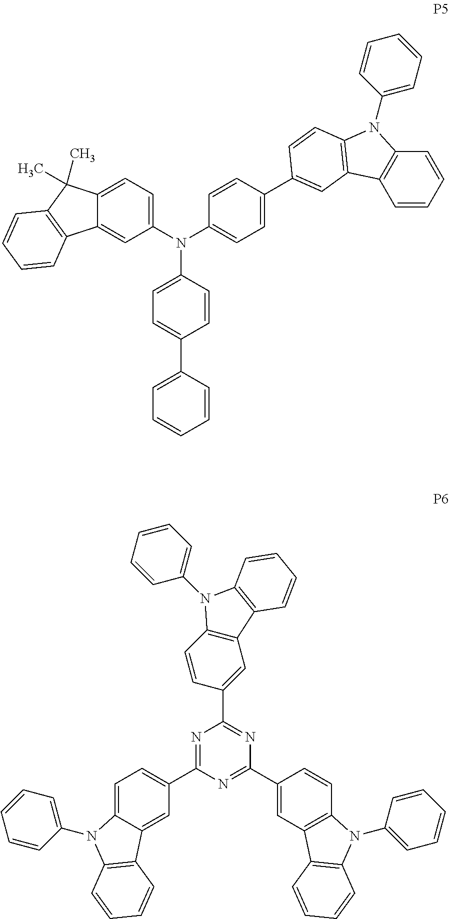 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21 ; c1ccc(-n2c3ccccc3c3cc(-c4nc(-c5ccc6c(c5)c5ccccc5n6-c5ccccc5)nc(-c5ccc6c(c5)c5ccccc5n6-c5ccccc5)n4)ccc32)cc1]

A refractive index of the capping layer CPL may be equal to or greater than about 1.6. For example, the refractive index of the capping layer CPL may be equal to or greater than about 1.6 with respect to light in a wavelength range of about 550 nm to about 660 nm.

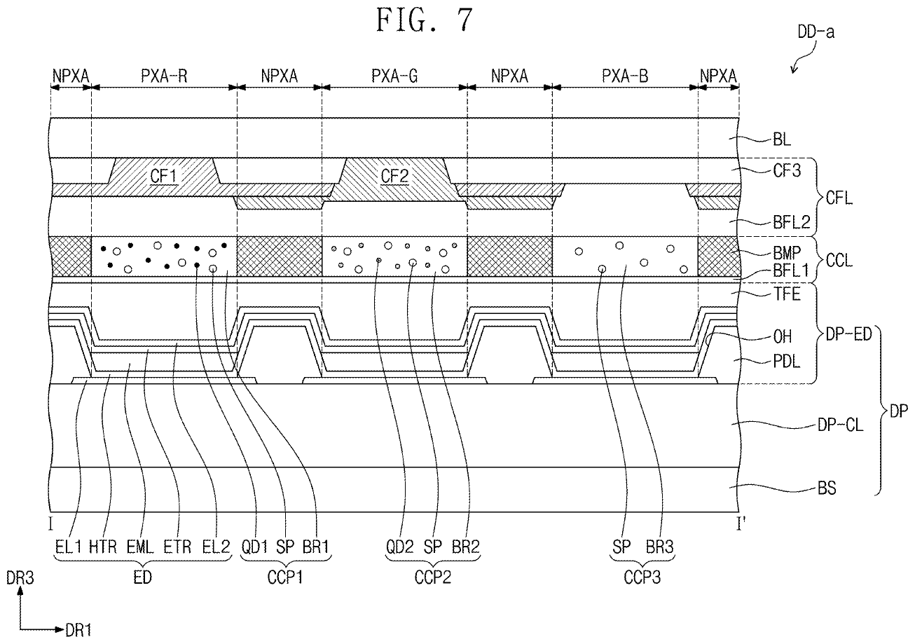

FIGS. 7 to 10 are each a schematic cross-sectional view of a display apparatus according to embodiments. Hereinafter, in describing the display apparatuses according to embodiments with reference to FIGS. 7 to 10, the features which have been described above with respect to FIGS. 1 to 6 will not be explained again, and the differing features will be described.

Referring to FIG. 7, a display apparatus DD-a according to an embodiment may include a display panel DP including a display apparatus layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and the display device layer DP-ED, and the display device layer DP-ED may include a light emitting device ED.

The light emitting device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 7 may be the same as a structure of a light emitting device according to one of FIGS. 3 to 6 as described herein.

Referring to FIG. 7, the emission layer EML may be disposed in an opening OH defined in a pixel defining film PDL. For example, the emission layer EML, which is separated by the pixel defining film PDL and provided corresponding to each of the light emitting regions PXA-R, PXA-G, and PXA-B, may emit light in a same wavelength range. In the display apparatus DD-a according to an embodiment, the emission layer EML may emit blue light. Although not shown in the drawings, in an embodiment, the emission layer EML may be provided as a common layer for all of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and may emit the resulting light. For example, the light control layer CCL may be a layer including a quantum dot or a layer including a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3, which are spaced apart from each other, but embodiments are not limited thereto. In FIG. 7, it is shown that the divided patterns BMP do not overlap the light control parts CCP1, CCP2, and CCP3, but at least a portion of the edges of the light control parts CCP1, CCP2, and CCP3 may overlap the divided patterns BMP.

The light control layer CCL may include a first light control part CCP1 containing a first quantum dot QD1 which converts first color light provided from the light emitting device ED into second color light, a second light control part CCP2 containing a second quantum dot QD2 which converts the first color light into third color light, and a third light control part CCP3 which transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting device ED. For example, the first quantum dot QD1 may be a red quantum dot, and the second quantum dot QD2 may be a green quantum dot. The quantum dots QD1 and QD2 may each be a quantum dot as described herein.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include any quantum dot but may include the scatterer SP.

The scatterer SP may be an inorganic particle. For example, the scatterer SP may include at least one of TiO₂, ZnO, Al₂O₃, SiO₂, or hollow silica. The scatterer SP may include any one of TiO₂, ZnO, Al₂O₃, SiO₂, and hollow silica, or the scatterer SP may be a mixture of at least two materials selected from TiO₂, ZnO, Al₂O₃, SiO₂, and hollow silica.

The first light control part CCP1, the second light control part CCP2, and the third light control part CCP3 may each include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3. The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may be disposed on the light control parts CCP1, CCP2, and CCP3 to block the light control parts CCP1, CCP2, and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may each independently further include an organic film. The barrier layers BFL1 and BFL2 may each independently be formed of a single layer or of multiple layers.

In the display apparatus DD-a according to an embodiment, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include a light shielding part (not shown) and color filters CF1, CF2, and CF3. The color filter layer CFL may include a first filter CF1 that transmits the second color light, a second filter CF2 that transmits the third color light, and a third filter CF3 that transmits the first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated but may be provided as one filter.

The light shielding part (not shown) may be a black matrix. The light shielding part (not shown) may include an organic light shielding material or an inorganic light shielding material containing a black pigment or dye. The light shielding part (not shown) may prevent light leakage, and may separate boundaries between adjacent filters CF1, CF2, and CF3. In an embodiment, the light shielding part (not shown) may be formed of a blue filter.

The first to third filters CF1, CF2, and CF3 may be disposed to respectively correspond to the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

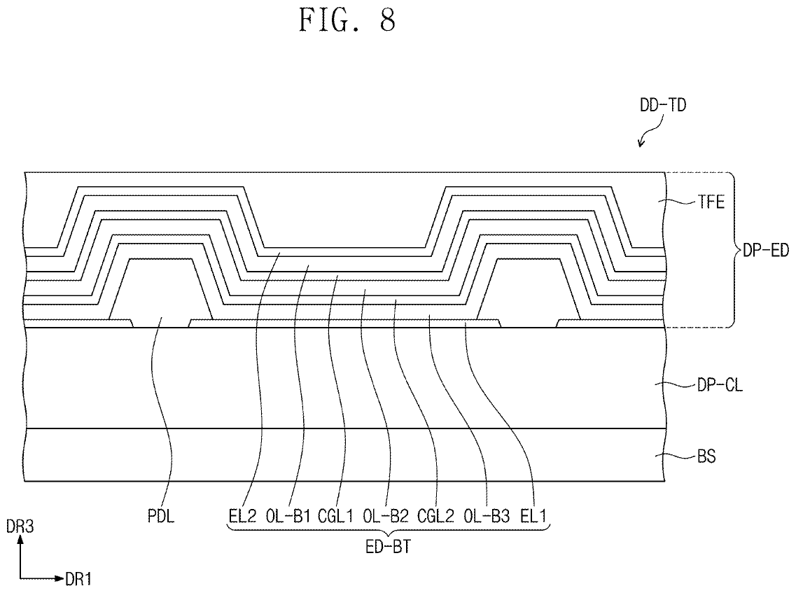

FIG. 8 is a schematic cross-sectional view illustrating a portion of the display apparatus DD-a according to an embodiment. In the display apparatus DD-TD according to an embodiment, the light emitting device ED-BT may include light emitting structures OL-B1, OL-B2, and OL-B3. The light emitting device ED-BT may include a first electrode EL1 and a second electrode EL2 which face each other, and the light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (FIG. 7) and a hole transport region HTR and an electron transport region ETR disposed with the emission layer EML (FIG. 7) therebetween.

For example, the light emitting device ED-BT included in the display apparatus DD-TD according to an embodiment may be a light emitting device having a tandem structure and including multiple emission layers.

In an embodiment illustrated in FIG. 8, light emitted from each of the light emitting structures OL-B1, OL-B2, and OL-B3 may all be blue light. However, embodiments are not limited thereto, and the light emitted from each of the light emitting structures OL-B1, OL-B2, and OL-B3 may have wavelength ranges that are different from each other. For example, the light emitting device ED-BT including the light emitting structures OL-B1, OL-B2, and OL-B3 which emit light having wavelength ranges that are different from each other may emit white light.

Charge generation layers CGL1 and CGL2 may be disposed between neighboring light emitting structures OL-B1, OL-B2, and OL-B3. Charge generation layers CGL1 and CGL2 may each independently include a p-type charge generation layer and/or an n-type charge generation layer.

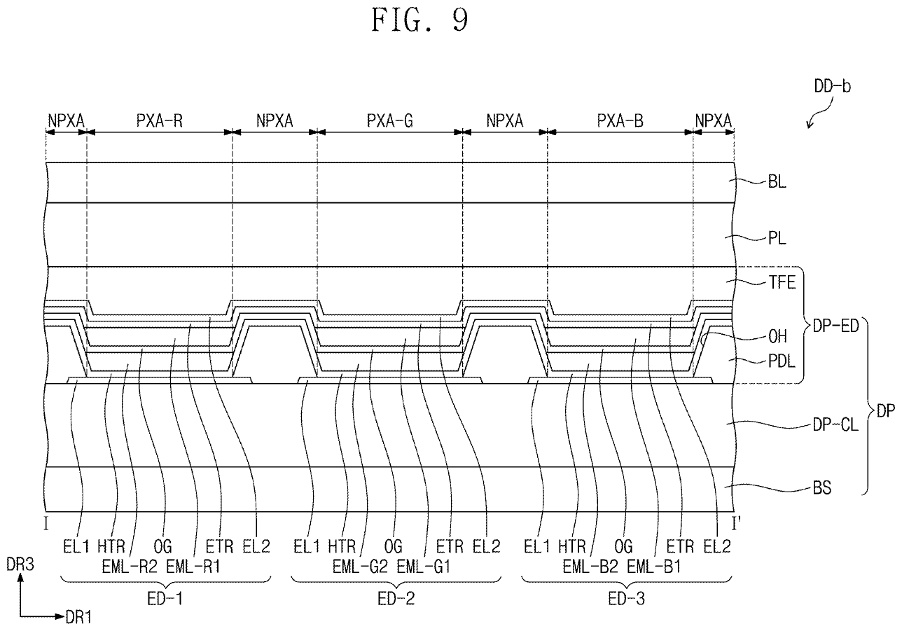

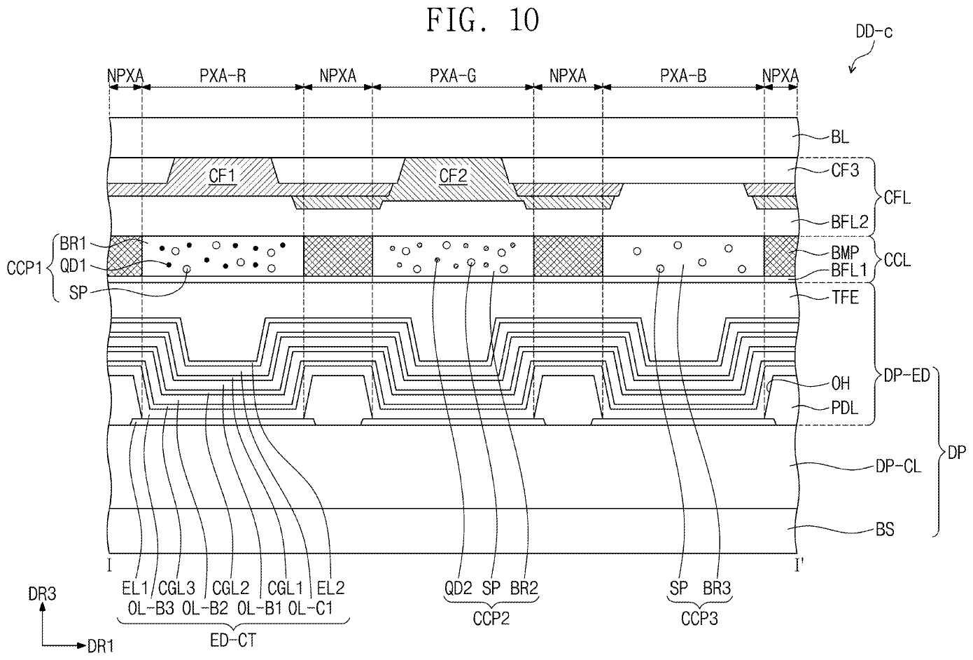

Referring to FIG. 9, the display apparatus DD-b according to an embodiment may include light emitting devices ED-1, ED-2, and ED-3 which may each include two emission layers that are stacked. In comparison to the display apparatus DD illustrated in FIG. 2, the embodiment illustrated in FIG. 9 is different at least in that the first to third light emitting devices ED-1, ED-2, and ED-3 each include two emission layers that are stacked in a thickness direction. In each of the first to third light emitting devices ED-1, ED-2, and ED-3, the two emission layers may emit light in a same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. The third light emitting device ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for all of the first to third light emitting devices ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the electron transport region ETR and the emission auxiliary part OG. The second red emission layer EML-R2, the second green emission layer EML-G2, and the second blue emission layer EML-B2 may each be disposed between the emission auxiliary part OG and the hole transport region HTR.

For example, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2 that are stacked in that order. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2 that are stacked in that order. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2 that are stacked in that order.

An optical auxiliary layer PL may be disposed on the display device layer DP-ED. The optical auxiliary layer PL may include a polarizing layer. The optical auxiliary layer PL may be disposed on the display panel DP and may control light reflected at the display panel DP from an external light. Although not shown in the drawings, in an embodiment, the optical auxiliary layer PL may be omitted from the display apparatus DD-b.

In contrast to FIGS. 8 and 9, FIG. 10 illustrates a display apparatus DD-c that is different at least in that it includes four light emitting structures OL-B1, OL-B2, OL-B3, and OL-C1. A light emitting device ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may each emit light in different wavelength regions.

The charge generation layers CGL1, CGL2, and CGL3 disposed between adjacent light emitting structures OL-B1, OL-B2, OL-B3, and OL-C1 may each independently include a p-type charge generation layer and/or an n-type charge generation layer.

In the display apparatus DD-c according to an embodiment, at least one of the light emitting structures OL-B1, OL-B2, OL-B3, and OL-C1 may include the fused polycyclic compound according to embodiments.

The fused polycyclic compound according to an embodiment may be included as a material for the light emitting device ED in a functional layer, in addition to the emission layer EML. The light emitting device ED according to an embodiment may include the above-described compound in at least one functional layer disposed between the first electrode EL1 and the second electrode EL2, or in a capping layer CPL disposed on the second electrode EL2.

The light emitting device ED according to an embodiment may include the fused polycyclic compound represented by Formula 1 according to an embodiment as a host material for the emission layer as described herein, thereby exhibiting excellent luminous efficiency and improved service life characteristics. The light emitting device ED according to embodiments may exhibit high efficiency and long service life characteristics in a blue wavelength region.

Hereinafter, a fused polycyclic compound according to an embodiment and a light emitting device according to an embodiment will be described in detail with reference to the Examples and the Comparative Examples. The Examples described below are only provided as illustrations to assist in understanding the disclosure, and the scope thereof is not limited thereto.

### EXAMPLES

1. Synthesis of Fused Polycyclic Compound

A synthesis method of the fused polycyclic compound according to an embodiment will be described in detail with reference to the synthesis methods of Compounds 1, 2, 3, 14, 15, 23, 24, 25, 27, 28, 30, and 32. The synthesis methods of the fused polycyclic compounds are provided only as examples, and the synthesis method of the fused polycyclic compound according to an embodiment is not limited to the Examples below.

(1) Synthesis of Compound 1

Compound 1 according to an example may be synthesized by, for example, the reaction below:

### 1-1. (Synthesis of Intermediate IM-1)

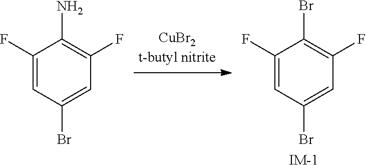

4-bromo-2,6-difluoroaniline (10 g), CuBr₂ (10.7 g), and t-butylnitrite (4.96 g) were dissolved in 480 mL of acetonitrile, and the reaction solution was stirred at about 100° C. using a reflux condenser. After 12 hours, the reaction solution was cooled to room temperature, and extracted with diethyl ether and water. The product thus obtained was purified by silica gel column chromatography to obtain Intermediate IM-1 (11.1 g, yield: 85%). (C₆H₂Br₂F₂: M+1 269.85)

### 1-2. (Synthesis of Intermediate IM-2)

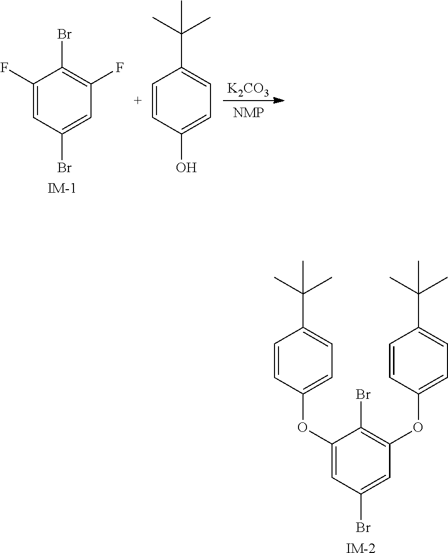

Intermediate IM-1 (10 g), 4-(tert-butyl)phenol (11.6 g), and K₂CO₃ (5.12 g) were dissolved in 500 mL of N-methyl-2-pyrrolidone (NMP), and the reaction solution was stirred at about 180° C. using a reflux condenser. After 12 hours, the reaction solution was cooled to room temperature, and extracted with diethyl ether and water. The product thus obtained was purified by silica gel column chromatography to obtain Intermediate IM-2 (15.5 g, yield: 78%). (C₂₆H₂₈Br₂O₂: M+1 532.32)

### 1-3. Synthesis of 7-bromo-2,12-di-tert-butyl-5,9-dioxa-13b-boranaphtho[3,2,1-de]anthracene (OBO-7Br)

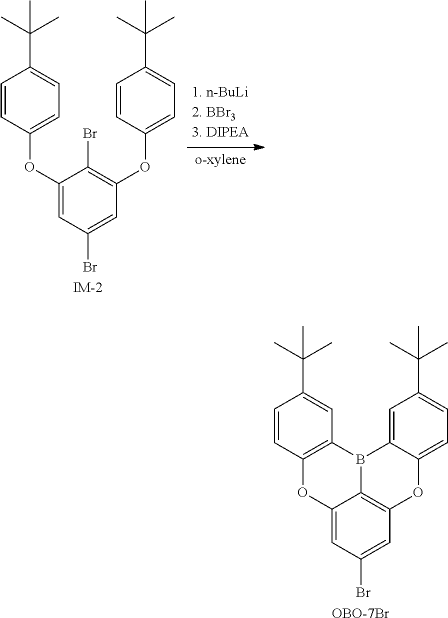

Intermediate IM-2 (10.0 g) was dissolved in 1.00 L of o-xylene, and 44.0 mL of normal butyl lithium (2.5 M solution in n-hexane) was slowly added thereto at about −78° C. After 1 hour and 30 minutes, 24.0 mL of BBr₃ was added thereto. The reaction solution was heated to room temperature and stirred for about 4 hours, and N,N-diisopropylethylamine (DIPEA) was added thereto and stirred for about 4 hours, and water was added thereto to terminate the reaction. The resulting product was extracted with diethyl ether and washed three times with water to obtain an organic layer. The obtained organic layer was dried over magnesium sulfate, and the solvent was removed under reduced pressure. The product thus obtained was purified by silica gel column chromatography to obtain Intermediate OBO-7Br (7.19 g, yield: 83%). (C₂₆H₂₆BBrO₂: M+1 461.21)

### 1-4. Synthesis of Compound 1

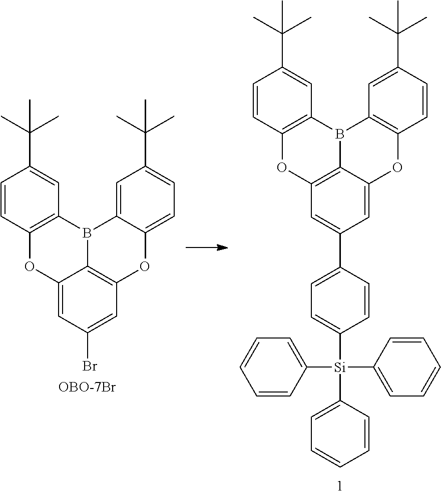 [SMILES: CC(C)(C)c1ccc2c(c1)B1c3cc(C(C)(C)C)ccc3Oc3cc(Br)cc(c31)O2 ; "OBO-7Br" ; CC(C)(C)c1ccc2c(c1)B1c3cc(C(C)(C)C)ccc3Oc3cc(-c4ccc([Si](c5ccccc5)(c5ccccc5)c5ccccc5)cc4)cc(c31)O2]

Intermediate OBO-7Br (10 g), (4-(triphenylsilyl)phenyl)boronic acid (9.07 g, 1.1 equiv.), tetrakis(triphenylphosphine)palladium(0) (Pd(PPh₃)₄, 5 mol %), and potassium carbonate (K₂CO₃, 4 equiv.) were dissolved in 500 mL of a mixed solution of toluene/H₂O, and the reaction solution was stirred at about 100° C. using a reflux condenser. After 12 hours, the reaction solution was cooled to room temperature, and extracted with diethyl ether and water. The product thus obtained was purified by silica gel column chromatography to obtain Compound 1 (14.1 g, yield: 91%). (C₅₀H₄₅BO₂Si: M+1 716.80)

(2) Synthesis of Compound 2

Compound 2 according to an example may be synthesized by, for example, the reaction below:

### 2-1. (Synthesis of Intermediate IM-3)

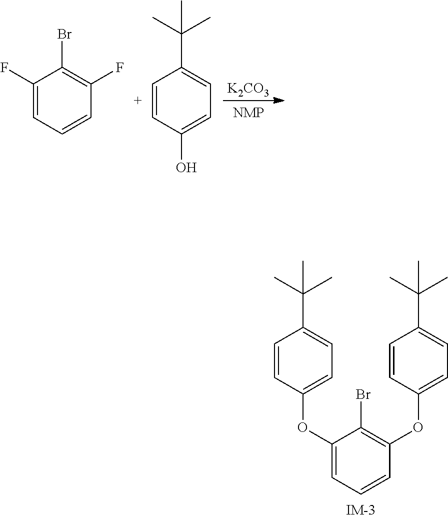

Intermediate IM-3 (yield: 72%) was synthesized in the same manner and molar ratio as in Synthesis of Intermediate IM-2 above except for using 2-bromo-1,3-difluorobenzene instead of Intermediate IM-1. (C₂₆H₂₉BrO₂: M+1 453.42)

### 2-2. (Synthesis of Intermediate IM-4)

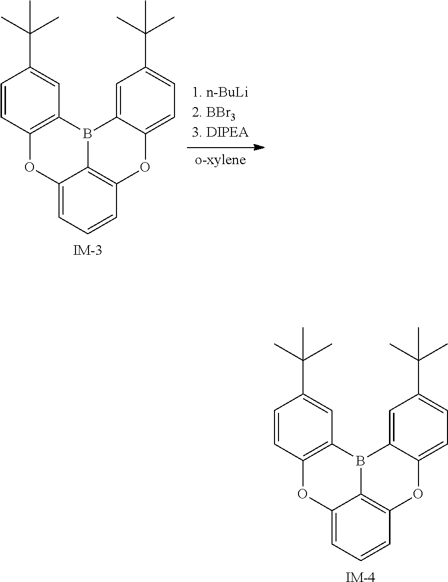

Intermediate IM-4 (yield: 82%) was synthesized in the same manner and molar ratio as in Synthesis of Intermediate OBO-7Br above except for using Intermediate IM-3 instead of Intermediate IM-2. (C₂₆H₂₇BO₂: M+1 382.31)

### 2-3. Synthesis of 6-bromo-2,12-di-tert-butyl-5,9-dioxa-13b-boranaphtho[3,2,1-de]anthracene (Intermediate OBO-6Br)

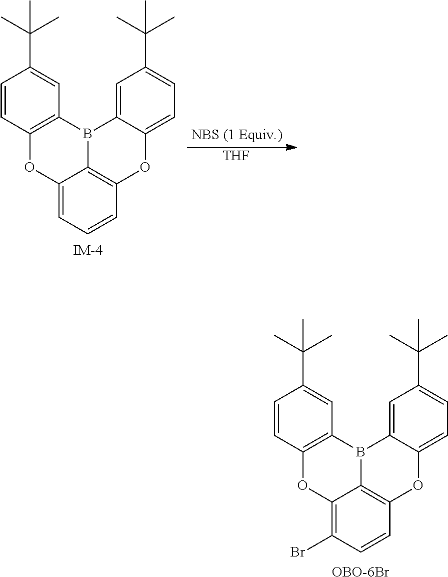

Intermediate IM-4 (10 g) and NBS (4.66 g) were dissolved in 480 mL of tetrahydrofuran (THF), and the reaction solution was stirred at room temperature. After 6 hours, the reaction solution was extracted with diethyl ether and water. The product thus obtained was purified by silica gel column chromatography to obtain Intermediate OBO-6Br (9.65 g, yield: 80%). (C₂₆H₂₆BBrO₂: M+1 461.21)

### 2-4. Synthesis of Compound 2

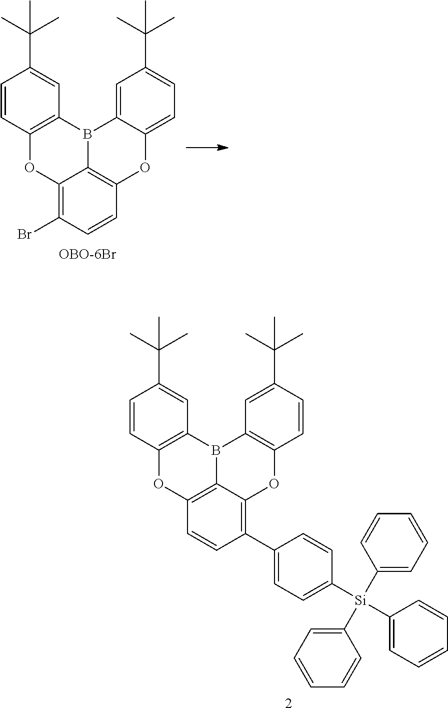

Compound 2 (yield: 88%) was synthesized in the same manner and molar ratio as in Synthesis of Compound 1 above except for using Intermediate OBO-6Br instead of Intermediate OBO-7Br. (C₅₀H₄₅BO₂Si: M+1 716.80)

(3) Synthesis of Compound 3

Compound 3 according to an example may be synthesized by, for example, the reaction below:

### 3-1. Synthesis of 6,8-dibromo-2,12-di-tert-butyl-5,9-dioxa-13b-boranaphtho[3,2,1-de]anthracene (Intermediate OBO-diBr)

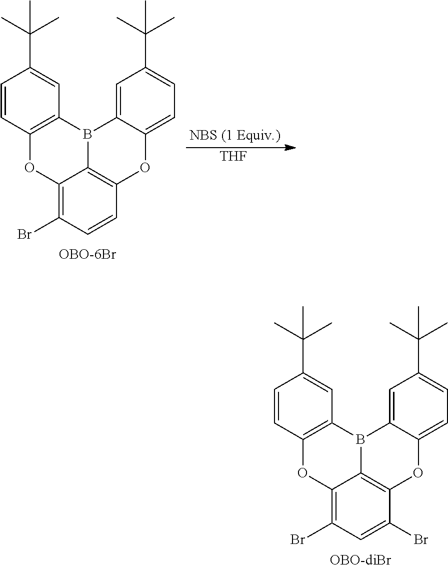

Intermediate OBO-diBr (yield: 86%) was synthesized in the same manner and molar ratio as in Synthesis of Intermediate OBO-6Br above except for using Intermediate OBO-6Br instead of Intermediate IM-4. (C26H₂₅BBr₂O₂: M+1 540.10)

### 3-2. Synthesis of Compound 3

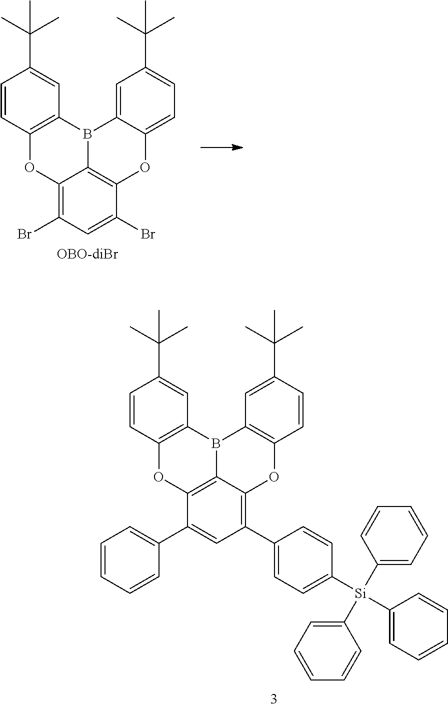

Compound 3 (yield: 79%) was synthesized in the same manner and molar ratio as in Synthesis of Compound 1 above except for using Intermediate OBO-diBr instead of Intermediate OBO-6Br and using (4-(triphenylsilyl)phenyl)boronic acid (1.05 equiv.) and phenylboronic acid (1.05 equiv.) instead of (4-(triphenylsilyl)phenyl)boronic acid (1.1 equiv.). (C₅₆H₄₉BO₂Si: M+1 792.70)

(4) Synthesis of Compound 14

Compound 14 (yield: 60%) was synthesized in the same manner and molar ratio as in Synthesis of Compound 3 above except for using 6,8-dibromo-3,11-bis(3,5-di-tert-butylphenyl)-5,9-dioxa-13b-boranaphtho[3,2,1-de]anthracene instead of Intermediate OBO-diBr and using (3-(tert-butyl)-[1,1′-biphenyl]-2-yl)boronic acid instead of phenylboronic acid. (C₈₆H₈₅BO₂Si: M+1 1189.52)

(5) Synthesis of Compound 15

Compound 15 (yield: 42%) was synthesized in the same manner and molar ratio as in Synthesis of Compound 14 above except for using [1,1′:3′,1″-terphenyl]-2′-ylboronic acid instead of (3-(tert-butyl)-[1,1′-biphenyl]-2-yl)boronic acid. (C₈₈H₈₁BO₂Si: M+1 1209.51)

(6) Synthesis of Compound 23

Compound 23 (yield: 67%) was synthesized in the same manner and molar ratio as in Synthesis of Compound 3 above except for using [1,1′:3′,1″-terphenyl]-2′-ylboronic acid and (3-(triphenylsilyl)phenyl)boronic acid instead of (4-(triphenylsilyl)phenyl)boronic acid, phenylboronic acid. (C₆₈H₅₇BO₂Si: M+1 945.10)

(7) Synthesis of Compound 24

Compound 24 (yield: 55%) was synthesized in the same manner and molar ratio as in Synthesis of Compound 23 above except for using (3-(triphenylsilyl)phenyl)boronic acid instead of [1,1′:3′,1″-terphenyl]-2′-ylboronic acid. (C₇₄H₆₃BO₂Si₂: M+1 1051.30)

(8) Synthesis of Compound 25

Compound 25 (yield: 78%) was synthesized in the same manner and molar ratio as in Synthesis of Compound 1 above except for using 7-bromo-3,11-bis(3,5-di-tert-butylphenyl)-5,9-dioxa-13b-boranaphtho[3,2,1-de]anthracene instead of Intermediate OBO-6Br. (C₇₀H₆₉BO₂Si: M+1 981.22)

(9) Synthesis of Compound 27

Compound 27 (yield: 72%) was synthesized in the same manner and molar ratio as in Synthesis of Compound 3 above except for using (3-(triphenylsilyl)phenyl)boronic acid instead of (4-(triphenylsilyl)phenyl)boronic acid, phenylboronic acid. (C₇₆H₇₃BO₂Si: M+1 1057.31)

(10) Synthesis of Compound 28

Compound 28 (yield: 30%) was synthesized in the same manner and molar ratio as in Synthesis of Compound 3 above except for using (3-(triphenylsilyl)phenyl)boronic acid and pyridin-2-ylboronic acid instead of (4-(triphenylsilyl)phenyl)boronic acid and phenylboronic acid. (C₇₅H₇₂BNO₂Si: M+1 1058.30)

(11) Synthesis of Compound 30

Compound 30 (yield: 47%) was synthesized in the same manner and molar ratio as in Synthesis of Compound 28 above except for using (3-(tert-butyl)-[1,1′-biphenyl]-2-yl)boronic acid instead of pyridin-2-ylboronic acid. (C₈₆H₈₅BO₂Si: M+1 1189.52)

(12) Synthesis of Compound 32

Compound 32 (yield: 61%) was synthesized in the same manner and molar ratio as in Synthesis of Compound 30 above except for using (3-(triphenylsilyl)phenyl)boronic acid instead of (3-(tert-butyl)-[1,1′-biphenyl]-2-yl)boronic acid. (C₉₄H₈₇BO₂Si₂: M+1 1315.71)

2. Manufacture and Evaluation of Light Emitting Device Including Fused Polycyclic Compound

(Manufacture of Light Emitting Device)

Examples of light emitting devices that include the fused polycyclic compound of an Example in an emission layer were manufactured as follows. Compounds 1, 2, 3, 14, 15, 23, 24, 25, 27, 28, 30, and 32 that are Example Compounds as described above were used as a host material for the emission layer to manufacture the light emitting devices of Examples 1-1 to 1-3, Examples 2-1 to 2-3, Examples 3-1 to 3-3, and Examples 4-1 and 4-3. Examples 1-1 to 1-3 correspond to the light emitting devices manufactured by using Compounds 1 to 3, respectively, as a host material for the emission layer. Examples 2-1 to 2-3 correspond to the light emitting devices manufactured by using Compounds 23 to 25, respectively, as a host material for the emission layer. Examples 3-1 to 3-3 correspond to the light emitting devices manufactured by using Compounds 14, 15, and 28, respectively, as a host material for the emission layer. Examples 4-1 to 4-3 correspond to the light emitting devices manufactured by using Compounds 27, 30, and 32, respectively, as a host material for the emission layer.

Comparative Examples 1-1 to 1-3 correspond to light emitting devices which were manufactured by using Comparative Example Compounds C1 to C3, respectively, as a host material for the emission layer. Comparative Examples 2-1 to 2-3 correspond to the light emitting devices which were manufactured by using Comparative Example Compounds C1 to C3, respectively, as a host material for the emission layer. Comparative Example 3-1 corresponds to the light emitting device which was manufactured by using Comparative Compound C1 as a host material for the emission layer. Comparative Example 4-1 corresponds to the light emitting device which was manufactured by using Comparative Compound C2 as a host material for the emission layer.

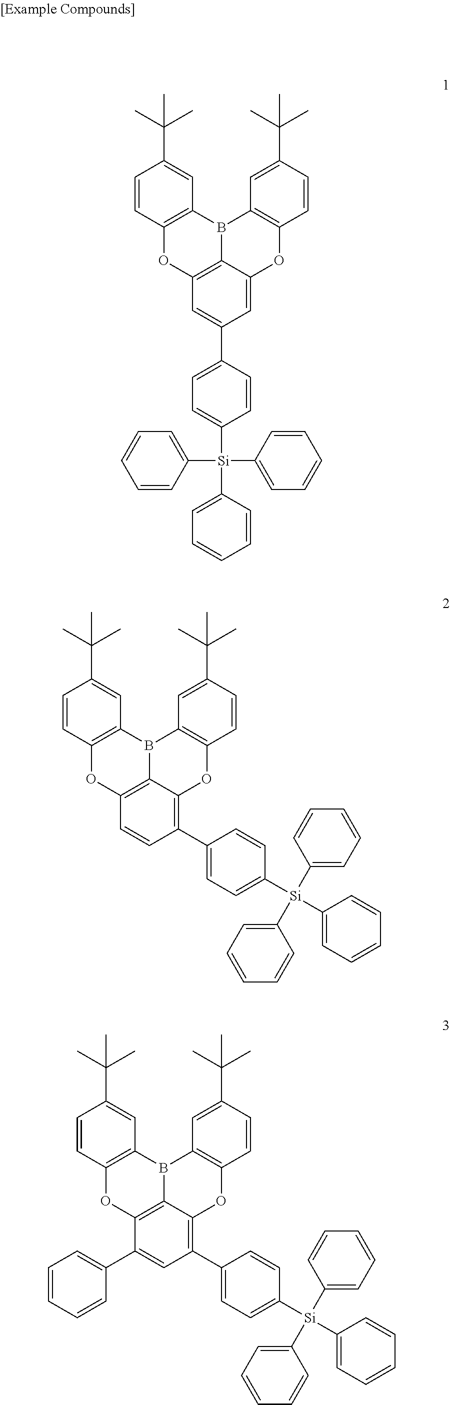 [SMILES: CC(C)(C)c1ccc2c(c1)B1c3cc(C(C)(C)C)ccc3Oc3cc(-c4ccc([Si](c5ccccc5)(c5ccccc5)c5ccccc5)cc4)cc(c31)O2 ; CC(C)(C)c1ccc2c(c1)B1c3cc(C(C)(C)C)ccc3Oc3c(-c4ccc([Si](c5ccccc5)(c5ccccc5)c5ccccc5)cc4)ccc(c31)O2 ; CC(C)(C)c1ccc2c(c1)B1c3cc(C(C)(C)C)ccc3Oc3c(-c4ccc([Si](c5ccccc5)(c5ccccc5)c5ccccc5)cc4)cc(-c4ccccc4)c(c31)O2]

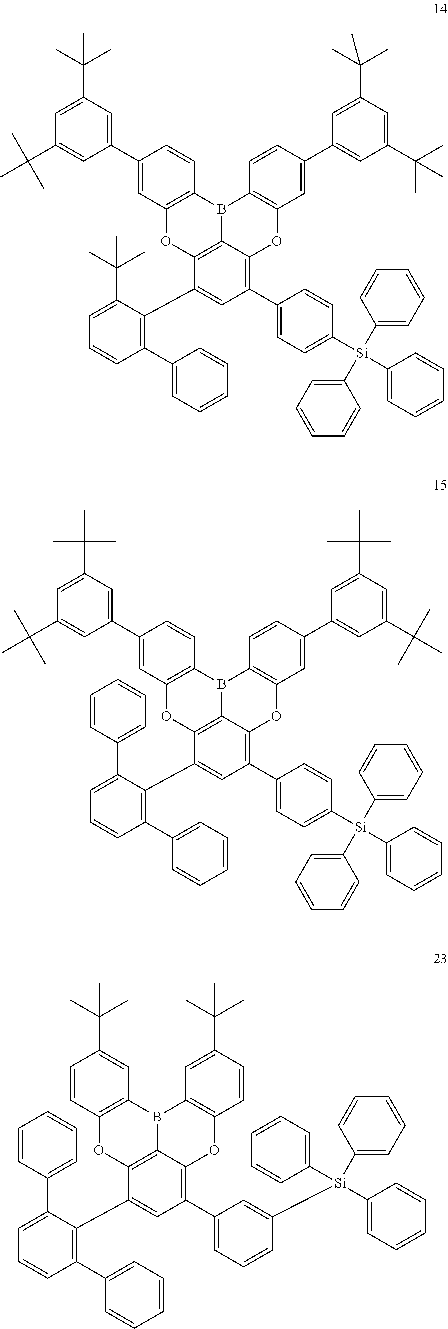

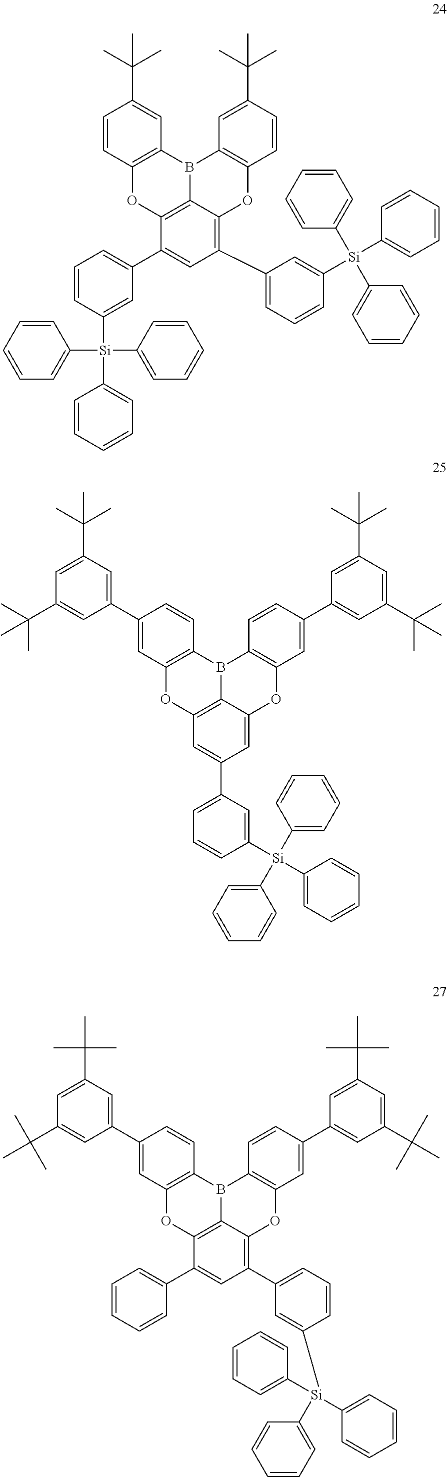

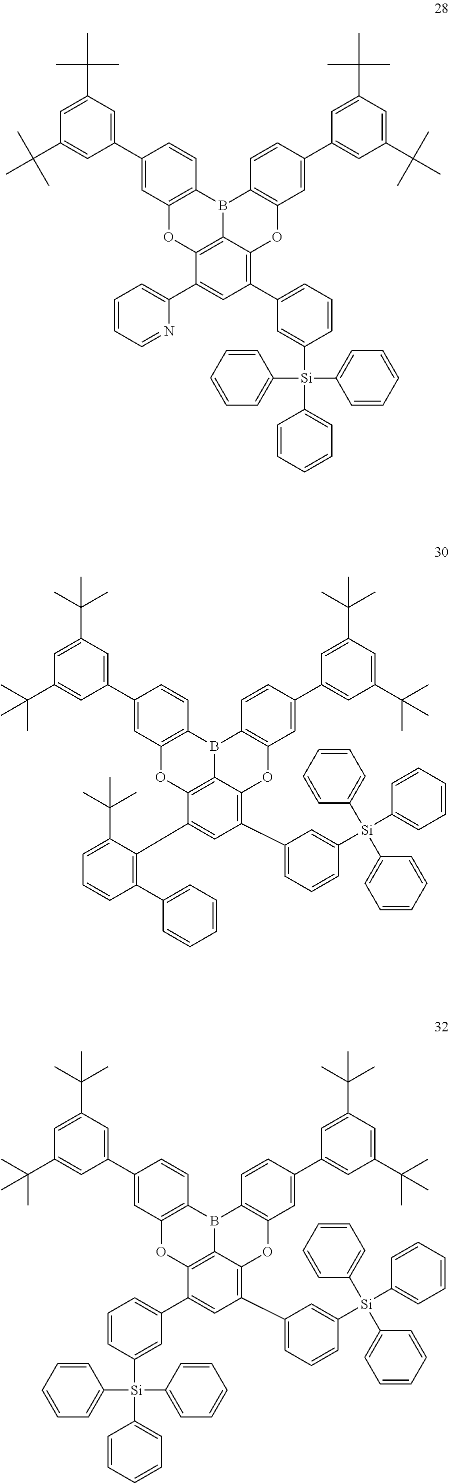

Comparative Example Compounds C1 to C3 below were used to manufacture devices of Comparative Examples.

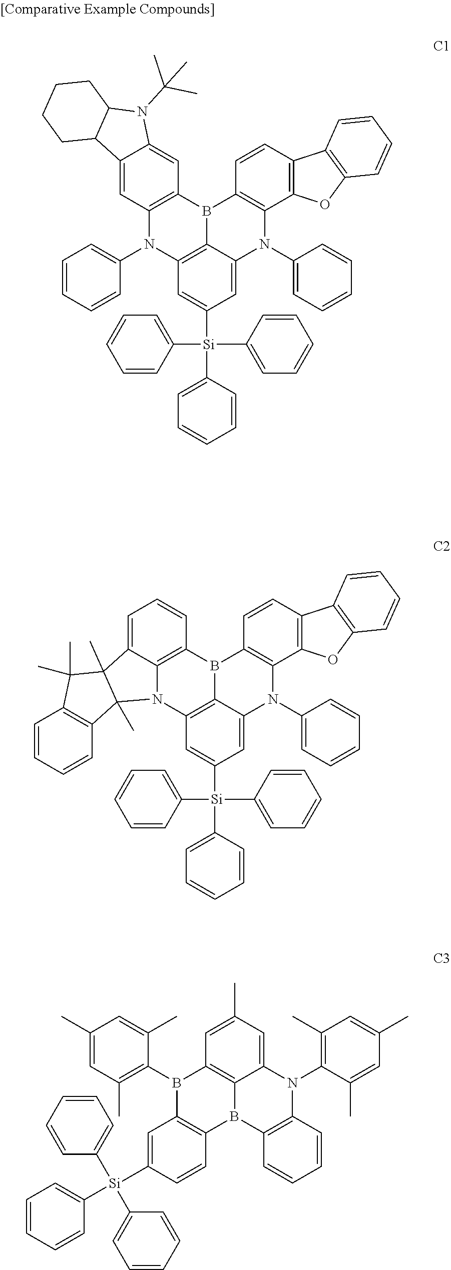 [SMILES: CC(C)(C)N1c2cc3c(cc2C2CCCCC21)N(c1ccccc1)c1cc([Si](c2ccccc2)(c2ccccc2)c2ccccc2)cc2c1B3c1ccc3c(oc4ccccc43)c1N2c1ccccc1 ; CC1(C)c2ccccc2C2(C)N3c4cc([Si](c5ccccc5)(c5ccccc5)c5ccccc5)cc5c4B(c4cccc(c43)C12C)c1ccc2c(oc3ccccc32)c1N5c1ccccc1 ; Cc1cc(C)c(B2c3cc([Si](c4ccccc4)(c4ccccc4)c4ccccc4)ccc3B3c4ccccc4N(c4c(C)cc(C)cc4C)c4cc(C)cc2c43)c(C)c1]

### Example 1-1

An ITO glass substrate of about 15 Ω/cm² (about 1,200 Å) of Corning Co. was cut to a size of about 50 mm×50 mm×0.7 mm, washed with isopropyl alcohol and pure water, and cleansed by ultrasonic waves for about 5 minutes, and irradiated with ultraviolet rays for about 30 minutes and treated with ozone.

2-TNATA was deposited in vacuum to form a 600 Å-thick hole injection layer, and NPB was deposited in vacuum to form a 300 Å-thick hole transport layer. On the hole transport layer, HT-08 was deposited in vacuum to form a 50 Å-thick electron blocking layer. Compound AD-39 was doped at a ratio of 15% to a host in which HT-08 and Example Compound 1 were mixed in a weight ratio of 7:3 to thereby form a 400 Å-thick emission layer.

SiCzTrz was deposited in vacuum to form a 50 Å-thick hole blocking layer. On the upper portion of the emission layer, SiCzTrz and LiQ were mixed in a weight ratio of 5:5 and co-deposited in vacuum to form a 300 Å-thick electron transport layer, and on the upper portion of the electron transport layer, Yb was deposited in vacuum to form a 15 Å-thick electron injection layer. Mg:Ag were deposited in vacuum in a weight ratio of 90:10 to form a 120 Å-thick second electrode, and P6 was deposited in vacuum to form a 700 Å-thick capping layer, thereby manufacturing a light emitting device.

### Example 1-2

Compared with Example 1-1 above, the light emitting device was manufactured in the same manner as Example 1-1 except for using Example Compound 2 instead of Example Compound 1 when the emission layer was formed.

### Example 1-3

Compared with Example 1-1 above, the light emitting device was manufactured in the same manner as Example 1-1 except for using Example Compound 3 instead of Example Compound 1 when the emission layer was formed.

### Comparative Example 1-1

Compared with Example 1-1 above, the light emitting device was manufactured in the same manner as Example 1-1 except for using Comparative Example Compound C1 instead of Example Compound 1 when the emission layer was formed.

### Comparative Example 1-2

Compared with Example 1-1 above, the light emitting device was manufactured in the same manner as Example 1-1 except for using Comparative Example Compound C2 instead of Example Compound 1 when the emission layer was formed.

### Comparative Example 1-3

Compared with Example 1-1 above, the light emitting device was manufactured in the same manner as Example 1-1 except for using Comparative Example Compound C3 instead of Example Compound 1 when the emission layer was formed.

### Example 2-1

An ITO glass substrate of about 15 Ω/cm² (about 1,200 Å) of Corning Co. was cut to a size of about 50 mm×50 mm×0.7 mm, washed with isopropyl alcohol and pure water, and cleansed by ultrasonic waves for about 5 minutes, and irradiated with ultraviolet rays for about 30 minutes and treated with ozone.

2-TNATA was deposited in vacuum to form a 600 Å-thick hole injection layer, and NPB was deposited in vacuum to form a 300 Å-thick hole transport layer. On the hole transport layer, HT-08 was deposited in vacuum to form a 50 Å-thick electron blocking layer. Compound AD-39 was doped at a ratio of 15% to Example Compound 23 to thereby form a 400 Å-thick emission layer.

SiCzTrz was deposited in vacuum to form a 50 Å-thick hole blocking layer. On the upper portion of the emission layer, SiCzTrz and LiQ were mixed in a weight ratio of 5:5 and co-deposited in vacuum to form a 300 Å-thick electron transport layer, and on the upper portion of the electron transport layer, Yb was deposited in vacuum to form a 15 Å-thick electron injection layer. Mg:Ag were deposited in vacuum in a weight ratio of 90:10 to form a 120 Å-thick second electrode, and P6 was deposited in vacuum to form a 700 Å-thick capping layer, thereby manufacturing a light emitting device.

### Example 2-2

Compared with Example 2-1 above, the light emitting device was manufactured in the same manner as Example 2-1 except for using Example Compound 24 instead of Example Compound 23 when the emission layer was formed.

### Example 2-3

Compared with Example 2-1 above, the light emitting device was manufactured in the same manner as Example 2-1 except for using Example Compound 25 instead of Example Compound 23 when the emission layer was formed.

### Comparative Example 2-1

Compared with Example 2-1 above, the light emitting device was manufactured in the same manner as Example 2-1 except for using Comparative Example Compound C1 instead of Example Compound 23 when the emission layer was formed.

### Comparative Example 2-2

Compared with Example 2-1 above, the light emitting device was manufactured in the same manner as Example 2-1 except for using Comparative Example Compound C2 instead of Example Compound 23 when the emission layer was formed.

### Comparative Example 2-3

Compared with Example 2-1 above, the light emitting device was manufactured in the same manner as Example 2-1 except for using Comparative Example Compound C3 instead of Example Compound 23 when the emission layer was formed.

### Example 3-1

An ITO glass substrate of about 15 Ω/cm² (about 1,200 Å) of Corning Co. was cut to a size of about 50 mm×50 mm×0.7 mm, washed with isopropyl alcohol and pure water, and cleansed by ultrasonic waves for about 5 minutes, and irradiated with ultraviolet rays for about 30 minutes and treated with ozone.

2-TNATA was deposited in vacuum to form a 600 Å-thick hole injection layer, and NPB was deposited in vacuum to form a 300 Å-thick hole transport layer. On the hole transport layer, HT-08 was deposited in vacuum to form a 50 Å-thick electron blocking layer. Compound BD-1 was doped at a ratio of 1% to a host in which HT-08 and Example Compound 14 were mixed in a weight ratio of 7:3 to thereby form a 400 Å-thick emission layer.

SiCzTrz was deposited in vacuum to form a 50 Å-thick hole blocking layer. On the upper portion of the emission layer, SiCzTrz and 8-quinolinolato lithium (LiQ) were mixed in a weight ratio of 5:5 and co-deposited in vacuum to form a 300 Å-thick electron transport layer, and on the upper portion of the electron transport layer, Yb was deposited in vacuum to form a 15 Å-thick electron injection layer. Mg:Ag were deposited in vacuum in a weight ratio of 90:10 to form a 120 Å-thick second electrode, and P6 was deposited in vacuum to form a 700 Å-thick capping layer, thereby manufacturing a light emitting device.

### Example 3-2

Compared with Example 3-1 above, the light emitting device was manufactured in the same manner as Example 3-1 except for using Example Compound 15 instead of Example Compound 14 when the emission layer was formed.

### Example 3-3

Compared with Example 3-1 above, the light emitting device was manufactured in the same manner as Example 3-1 except for using Example Compound 28 instead of Example Compound 14 when the emission layer was formed.

### Comparative Example 3-1

Compared with Example 3-1 above, the light emitting device was manufactured in the same manner as Example 3-1 except for using Comparative Example Compound C1 instead of Example Compound 14 when the emission layer was formed.

### Example 4-1

An ITO glass substrate of about 15 Ω/cm² (about 1,200 Å) of Corning Co. was cut to a size of about 50 mm×50 mm×0.7 mm, washed with isopropyl alcohol and pure water, and cleansed by ultrasonic waves for about 5 minutes, and irradiated with ultraviolet rays for about 30 minutes and treated with ozone.

2-TNATA was deposited in vacuum to form a 600 Å-thick hole injection layer, and NPB was deposited in vacuum to form a 300 Å-thick hole transport layer. On the hole transport layer, HT-08 was deposited in vacuum to form a 50 Å-thick electron blocking layer. Compound BD-1 was doped at a ratio of 1% to Example Compound 27 to thereby form a 400 Å-thick emission layer.

SiCzTrz was deposited in vacuum to form a 50 Å-thick hole blocking layer. On the upper portion of the emission layer, SiCzTrz and LiQ were mixed in a weight ratio of 5:5 and co-deposited in vacuum to form a 300 Å-thick electron transport layer, and on the upper portion of the electron transport layer, Yb was deposited in vacuum to form a 15 Å-thick electron injection layer. Mg:Ag were deposited in vacuum in a weight ratio of 90:10 to form a 120 Å-thick second electrode, and P6 was deposited in vacuum to form a 700 Å-thick capping layer, thereby manufacturing a light emitting device.

### Example 4-2

Compared with Example 4-1 above, the light emitting device was manufactured in the same manner as Example 4-1 except for using Example Compound 30 instead of Example Compound 27 when the emission layer was formed.

### Example 4-3

Compared with Example 4-1 above, the light emitting device was manufactured in the same manner as Example 4-1 except for using Example Compound 32 instead of Example Compound 27 when the emission layer was formed.

### Comparative Example 4-1

Compared with Example 4-1 above, the light emitting device was manufactured in the same manner as Example 4-1 except for using Comparative Example Compound C2 instead of Example Compound 27 when the emission layer was formed.

(Compounds Used to Manufacture Light Emitting Devices)

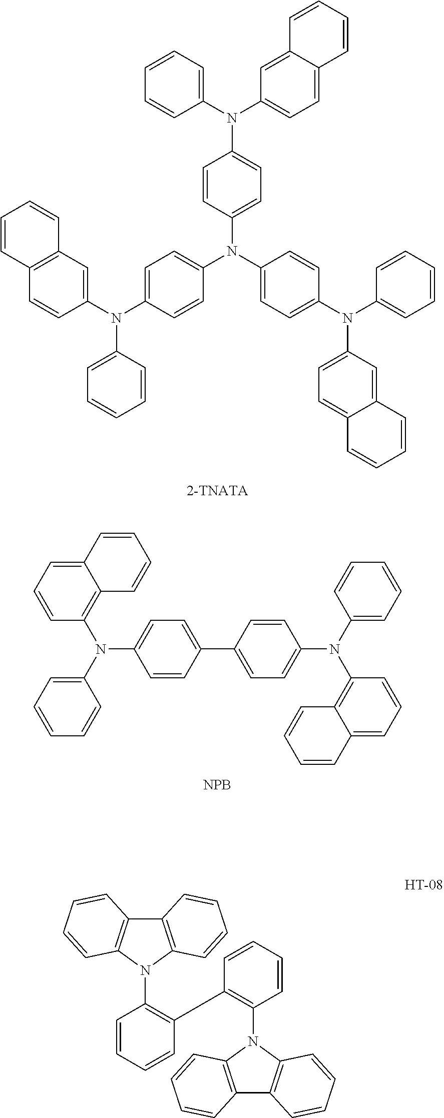 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1 ; "NPB" ; c1ccc(-n2c3ccccc3c3ccccc32)c(-c2ccccc2-n2c3ccccc3c3ccccc32)c1]

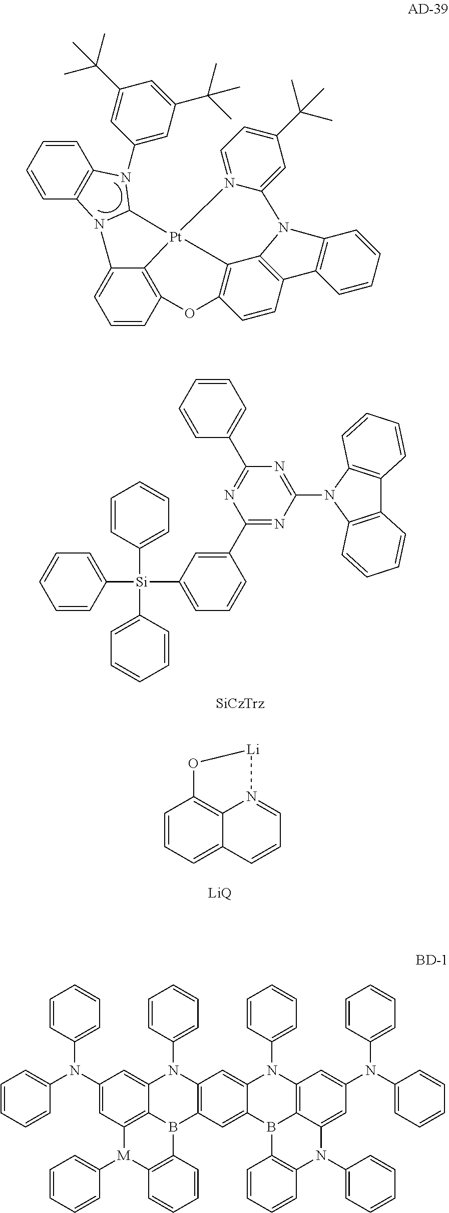

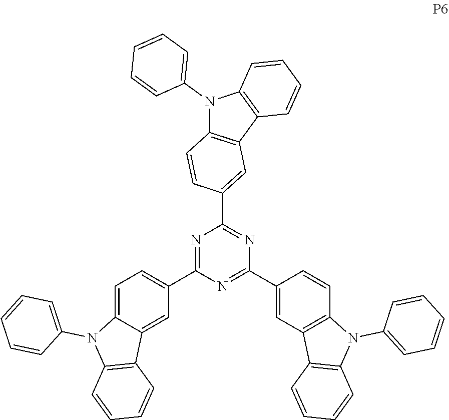 [SMILES: c1ccc(-n2c3ccccc3c3cc(-c4nc(-c5ccc6c(c5)c5ccccc5n6-c5ccccc5)nc(-c5ccc6c(c5)c5ccccc5n6-c5ccccc5)n4)ccc32)cc1]

(Evaluation of Light Emitting Device Characteristics)

Evaluation results of the light emitting devices of Examples 1-1 to 1-3, Examples 2-1 to 2-3, Examples 3-1 to 3-3, Examples 4-1 to 4-3, Comparative Examples 1-1 to 1-3, Comparative Examples 2-1 to 2-3, Comparative Example 3-1, and Comparative Example 4-1 are listed in Table 1. Luminous efficiencies and device service lives of the manufactured light emitting devices are listed in Table 1. In the characteristic evaluation results of Examples and Comparative Examples listed in Table 1, driving voltages and current densities were measured by using V7000 OLED IVL Test System (Polaronix). The luminous efficiency and device service life were measured at a current density of 100 mA/cm² and the results are listed below.

TABLE 1

| | | | Driving | Current | | | Device |
|---|---|---|---|---|---|---|---|
| | | | voltage | density | Efficiency | | Service life |
| | Host | Dopant | (V) | (mA/cm²) | (cd/A) | CIE_y | (LT₉₀, hr) |
| Example 1-1 | Compound | AD-39 | 4.58 | 6.52 | 22.3 | 0.066 | 107.1 |
| | 1/HT-08 | | | | | | |
| Example 1-2 | Compound | AD-39 | 4.60 | 6.62 | 21.1 | 0.063 | 100.0 |
| | 2/HT-08 | | | | | | |
| Example 1-3 | Compound | AD-39 | 4.61 | 6.63 | 21.8 | 0.059 | 110.9 |
| | 3/HT-08 | | | | | | |
| Comparative | Comparative | AD-39 | 4.70 | 7.93 | 15.3 | 0.063 | 54.9 |
| Example 1-1 | Example | | | | | | |
| | Compound | | | | | | |
| | C1/HT-08 | | | | | | |
| Comparative | Comparative | AD-39 | 4.82 | 8.10 | 17.1 | 0.064 | 66.1 |
| Example 1-2 | Example | | | | | | |
| | Compound | | | | | | |
| | C2/HT-08 | | | | | | |
| Comparative | Comparative | AD-39 | 4.81 | 8.11 | 16.5 | 0.064 | 73.6 |
| Example 1-3 | Example | | | | | | |
| | Compound | | | | | | |
| | C3/HT-08 | | | | | | |
| Example 2-1 | Compound 23 | AD-39 | 4.21 | 6.11 | 21.9 | 0.059 | 97.2 |
| Example 2-2 | Compound 24 | AD-39 | 4.17 | 6.21 | 21.8 | 0.058 | 105.3 |
| Example 2-3 | Compound 25 | AD-39 | 4.20 | 6.20 | 22.8 | 0.064 | 96.6 |
| Comparative | Comparative | AD-39 | 4.50 | 7.69 | 19.2 | 0.064 | 54.2 |
| Example 2-1 | Example | | | | | | |
| | Compound C1 | | | | | | |
| Comparative | Comparative | AD-39 | 4.49 | 8.06 | 18.6 | 0.062 | 60.1 |
| Example 2-2 | Example | | | | | | |
| | Compound C2 | | | | | | |
| Comparative | Comparative | AD-39 | 4.67 | 7.70 | 17.1 | 0.066 | 70.9 |
| Example 2-3 | Example | | | | | | |
| | Compound C3 | | | | | | |
| Example 3-1 | Compound | BD-1 | 4.25 | 5.38 | 21.5 | 0.053 | 136.8 |
| | 14/HT-08 | | | | | | |
| Example 3-2 | Compound | BD-1 | 4.20 | 5.32 | 21.8 | 0.053 | 144.3 |
| | 15/HT-08 | | | | | | |
| Example 3-3 | Compound | BD-1 | 4.21 | 5.33 | 20.3 | 0.050 | 143.8 |
| | 28/HT-08 | | | | | | |
| Comparative | Comparative | BD-1 | 4.43 | 6.28 | 19.5 | 0.056 | 79.4 |
| Example 3-1 | Example | | | | | | |
| | Compound | | | | | | |
| | C1/HT-08 | | | | | | |
| Example 4-1 | Compound 27 | BD-1 | 4.21 | 5.34 | 22.3 | 0.054 | 144.8 |
| Example 4-2 | Compound 30 | BD-1 | 4.21 | 5.34 | 22.2 | 0.054 | 143.3 |
| Example 4-3 | Compound 32 | BD-1 | 4.25 | 5.38 | 21.6 | 0.053 | 139.1 |
| Comparative | Comparative | BD-1 | 4.44 | 6.33 | 20.1 | 0.058 | 62.8 |
| Example 4-1 | Example | | | | | | |
| | Compound C2 | | | | | | |

Referring to the results of Table 1, it may be seen that Examples of the light emitting device using the fused polycyclic compound according to an example as a host material for the emission layer exhibit low driving voltage values and relatively higher luminous efficiencies and device service lives as compared with Comparative Examples. The fused polycyclic compound represented by Formula 1 according to an example has a structure in which three aromatic rings are fused by one boron atom and two heterocycles, and has a structure in which a substituent represented by Formula 2 is necessarily bonded to a carbon atom constituting the aromatic rings. The substituent represented by Formula 2 has a structure in which substituents represented by Rₐ to R_{c} are bonded to a silicon atom, and a linker, which is linked to the fused ring core in Formula 1, is included. The fused polycyclic compound represented by Formula 1 has a high glass transition temperature, and thus may have high heat resistance against joule heating generated between multiple organic layers or between an organic layer and an electrode when the fused polycyclic compound is used in at least one of the organic layers disposed between the first electrode and the second electrode of the light emitting device.

Steric hindrance between the fused ring core composed of three aromatic rings and the substituent represented by Formula 2 is increased, so that a conformational torsion of a ground state and an excited state of the molecule may be reduced so that the rigidity of the entire molecule may increase. Accordingly, the fused polycyclic compound according to an example may have an improvement in thermal characteristics and may have high triplet energy (T1) value at the same time. Thus, when the fused polycyclic compound according to embodiments is used as a host for the emission layer and a phosphorescent or delayed fluorescent dopant is used as a dopant for the emission layer of the light emitting device of an example, the light emitting device may exhibit improved luminous efficiency, low driving voltage, and increased device service life characteristics. The fused polycyclic compound according to embodiments includes at least one substituent represented by Formula 2, thereby having a structurally more twisted shape due to an appropriate steric hindrance effect in the molecule, and thus the distance between molecules in the emission layer may be increased, thereby the thin film uniformity may be improved and a charge balance in the emission layer may be maintained appropriately so that high luminous efficiency characteristics may be expected when the fused polycyclic compound is applied to the light emitting device.

It may be confirmed that Comparative Example Compounds C1 to C3 have a structure which includes a planar skeleton structure containing a boron atom at the center thereof, and in which a silyl group is substituted at the planar skeleton, but have a structure in which the silyl group is linked to the fused ring core via a direct linkage rather than via a linker, and thus have higher driving voltage and reduced luminous efficiency, and exhibit deteriorated service life characteristics as compared with Examples.

The light emitting device according to an embodiment may exhibit improved device characteristics with high efficiency and a long service life.

The fused polycyclic compound of an embodiment may be included in the emission layer of the light emitting device to contribute to high efficiency and a long service life of the light emitting device.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting device comprising:
a first electrode;
a second electrode facing the first electrode; and
an emission layer disposed between the first electrode and the second electrode, wherein
the emission layer comprises a first compound represented by Formula 1: 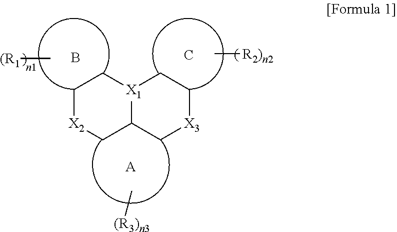
wherein in Formula 1,
A, B, and C are each independently a monocyclic aromatic hydrocarbon ring having 6 to 30 ring-forming carbon atoms, or a monocyclic aromatic heterocycle having 2 to 30 ring-forming carbon atoms,
X₁ is B, P, P═O, P═S, Al, Ga, As, Si(R₄), or Ge(R₅),
X₂ and X₃ are each independently O, S, Se, or N(R₆),
R₁ to R₃ are each independently a hydrogen atom, a deuterium atom, a halogen atom, a substituted or unsubstituted alkyl group having 1 to 20 carbon group, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, a group represented by Formula 2, or are bonded to an adjacent group to form a ring,
at least one of R₁ to R₃ is each independently a group represented by Formula 2,
R₄ to R₆ are each independently a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or are bonded to an adjacent group to form a ring,
n1 and n2 are each independently an integer from 1 to 4, and
n3 is an integer from 1 to 3, 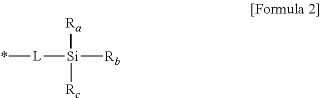
wherein in Formula 2,
Rₐ to R_{c} are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
L is a substituted or unsubstituted arylene group having 6 to 30 ring-forming carbon atoms, or a substituted or unsubstituted heteroarylene group having 2 to 30 ring-forming carbon atoms, and [symbol] represents a bonding site to Formula 1.

2. The light emitting device of claim 1, wherein the first compound represented by Formula 1 is represented by Formula 3: 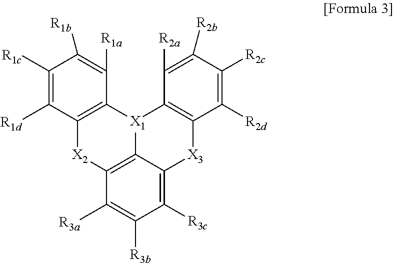
wherein in Formula 3,
R₁ₐ to R_{1d}, R₂ₐ to R_{2d}, and R₃ₐ to R_{3c} are each independently a hydrogen atom, a deuterium atom, a halogen atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, a group represented by Formula 2, or are bonded to an adjacent group to form a ring,
at least one of R₁ₐ to R_{1d}, R₂ₐ to R_{2d}, and R₃ₐ to R_{3c} is each independently a group represented by Formula 2, and
X₁ to X₃ are each the same as defined in Formula 1.

3. The light emitting device of claim 2, wherein the first compound represented by Formula 3 is represented by one of Formula 4-1 to Formula 4-4: 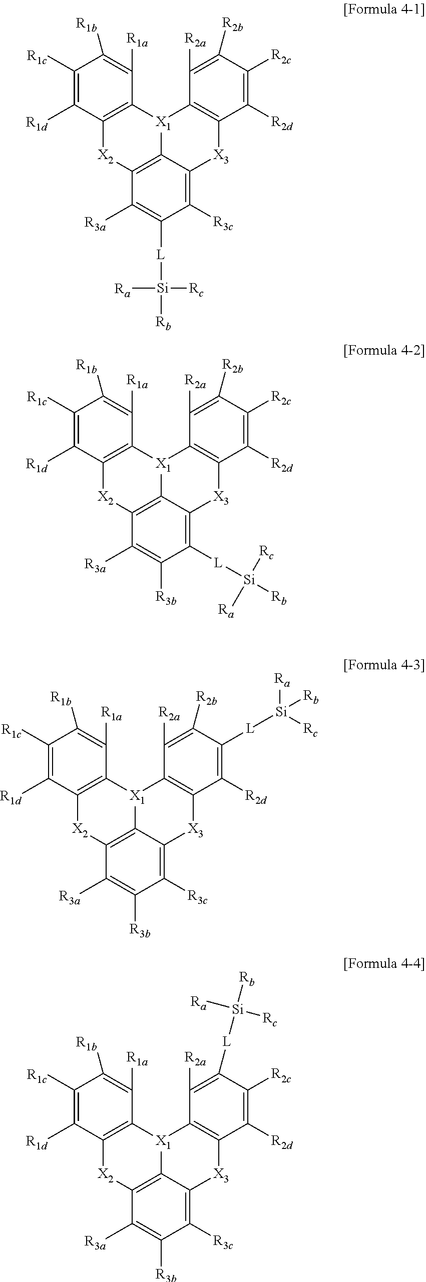
wherein in Formula 4-1 to Formula 4-4,
X₁ to X₃, L, Rₐ to R_{c}, R₁ₐ to R_{1d}, R₂ₐ to R_{2d}, and R₃ₐ to R_{3c} are each the same as defined in Formula 1, Formula 2, and Formula 3.

4. The light emitting device of claim 2, wherein the first compound represented by Formula 3 is represented by one of Formula 5-1 to Formula 5-4: 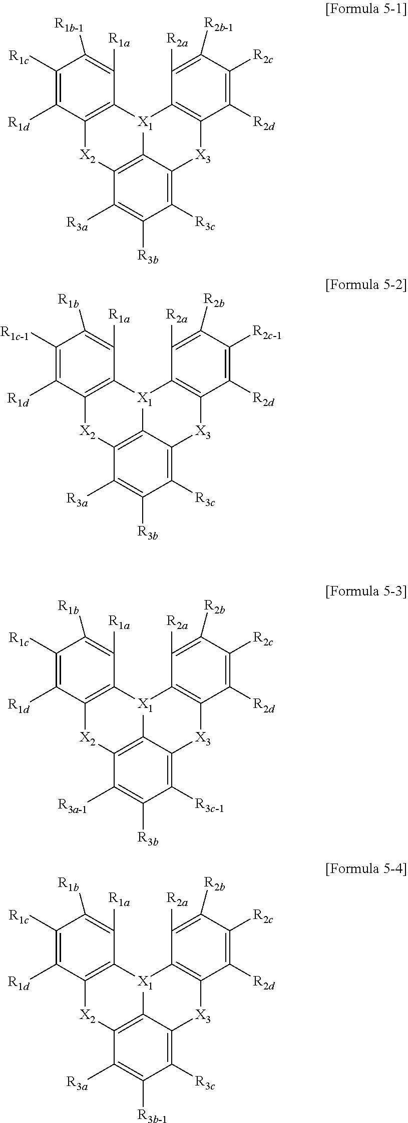
wherein in Formula 5-1 to Formula 5-4,
R_{2b-1}, R_{2b-1}, R_{1c-1}, R_{2c-1}, and R₃ₐ₋₁ to R_{3c-1} are each independently a substituted or unsubstituted alkyl group having 1 to 10 carbon atoms, a substituted or unsubstituted aryl group having 6 to 30 ring-forming carbon atoms, a substituted or unsubstituted heteroaryl group having 2 to 30 ring-forming carbon atoms, or a group represented by Formula 2, and
X₁ to X₃, R₁ₐ to R_{1d}, R₂ₐ to R_{2d}, and R₃ₐ to R_{3c} are each the same as defined in Formula 1 and Formula 3.

5. The light emitting device of claim 2, wherein the first compound represented by Formula 3 is represented by one of Formula 6-1 to Formula 6-4: 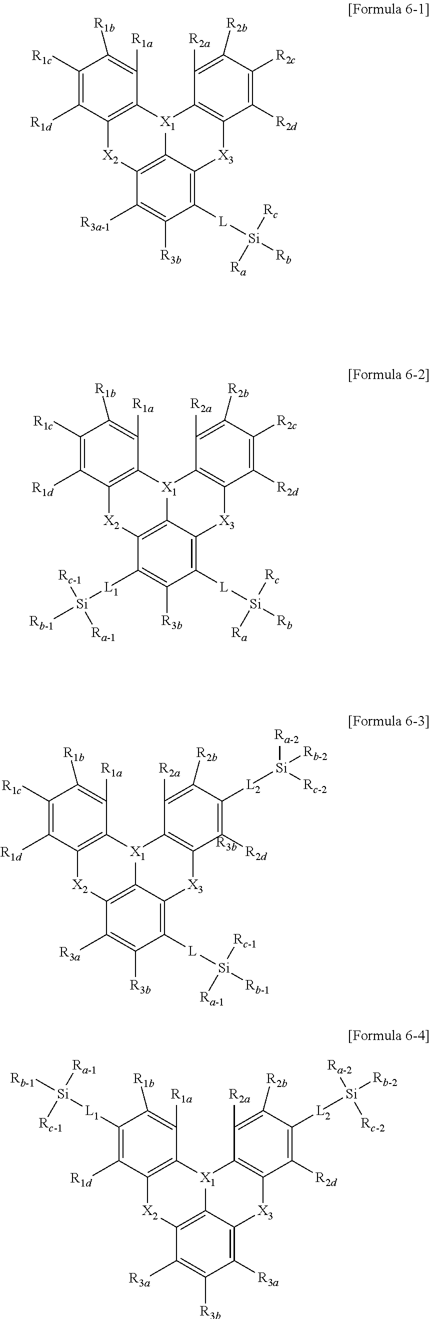
wherein in Formula 6-1 to Formula 6-4,
R₃ₐ₋₁ is a substituted or unsubstituted aryl group having 6 to 30 ring-forming carbon atoms, or a substituted or unsubstituted heteroaryl group having 2 to 30 ring-forming carbon atoms,
Rₐ₋₁ to R_{c-1} and Rₐ₋₂ to R_{c-2} are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
L₁ and L₂ are each independently a substituted or unsubstituted arylene group having 6 to 30 ring-forming carbon atoms, or a substituted or unsubstituted heteroarylene group having 2 to 30 ring-forming carbon atoms, and
X₁ to X₃, L, Rₐ to R_{c}, R₁ₐ to R_{1d}, R₂ₐ to R_{2d}, and R₃ₐ to R_{3c} are each the same as defined in Formula 1, Formula 2, and Formula 3.

6. The light emitting device of claim 5, wherein in Formula 6-1, R₃ₐ₋₁ is a group represented by one of Formula 7-1 to Formula 7-4: 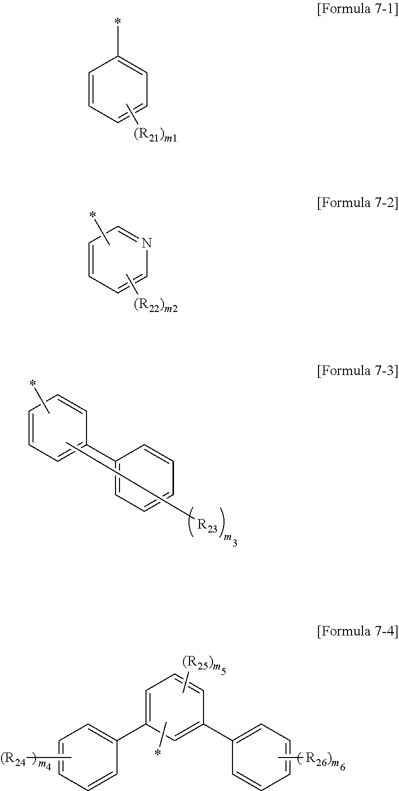
wherein in Formula 7-1 to Formula 7-4,
R₂₁ to R₂₆ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m₁, m₄, and m₆ are each independently an integer from 0 to 5,
m₃ is an integer from 0 to 9,
m₂ is an integer from 0 to 4, and
m₅ is an integer from 0 to 3.

7. The light emitting device of claim 2, wherein the first compound represented by Formula 3 is represented by one of Formula 8-1 to Formula 8-3: 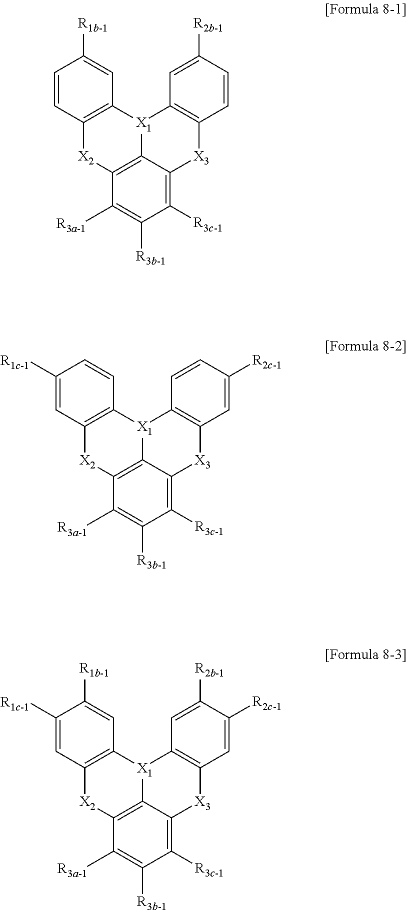
wherein in Formula 8-1 to Formula 8-3,
R_{1b-1}, R_{2b-1}, R_{1c-1}, R_{2c-1}, and R₃ₐ₋₁ to R_{3c-1} are each independently a hydrogen atom, a substituted or unsubstituted t-butyl group, a substituted or unsubstituted phenyl group, a substituted or unsubstituted biphenyl group, a substituted or unsubstituted terphenyl group, a substituted or unsubstituted pyridine group, a substituted or unsubstituted carbazole group, or a group represented by Formula 2,
at least one of R_{1b-1}, R_{2b-1}, R_{1c-1}, R_{2c-1}, and R₃ₐ₋₁ to R_{3c-1} is each independently a group represented by Formula 2, and
X₁ to X₃ are each the same as defined in Formula 1.

8. The light emitting device of claim 2, wherein the first compound represented by Formula 3 is represented by one of Formula 9-1 to Formula 9-6: 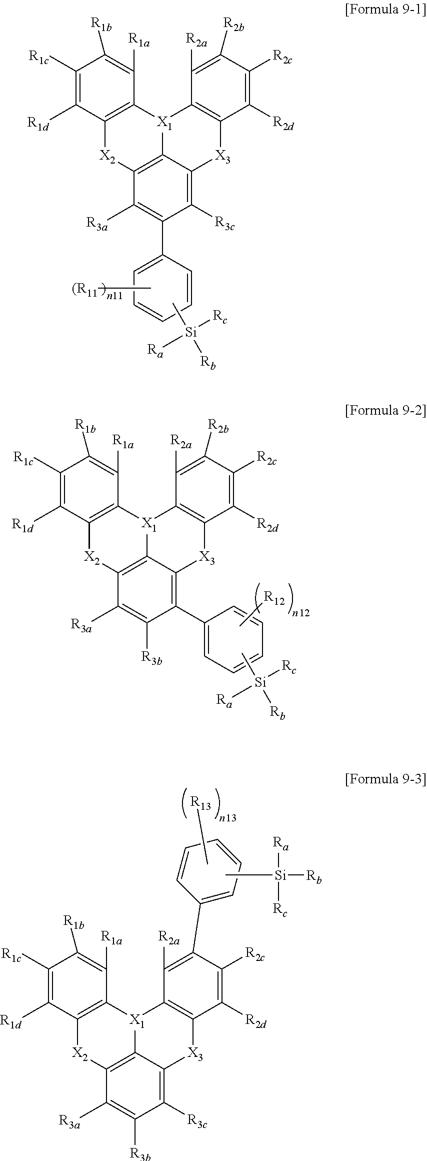 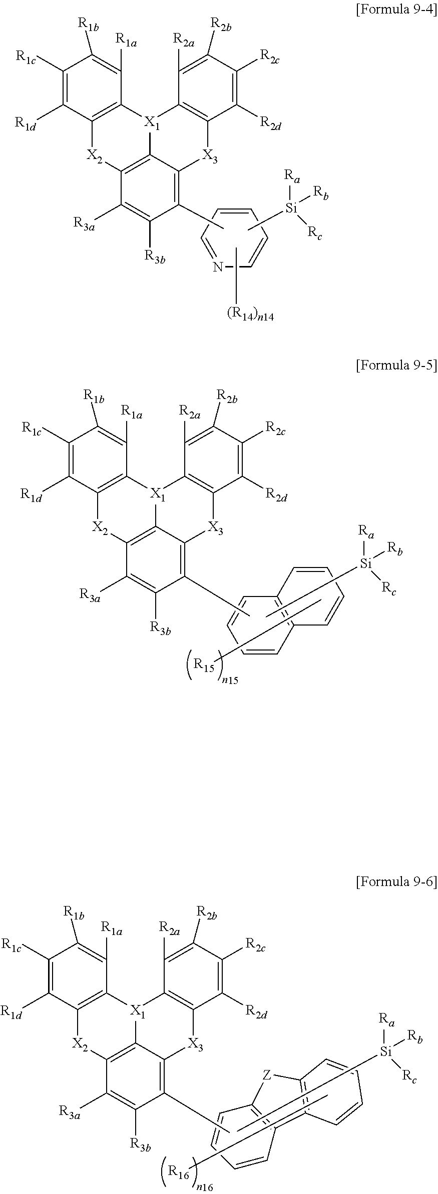
wherein in Formula 9-1 to Formula 9-6,
Z is N(R₁₇), O, or S,
R₁₁ to R₁₇ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n11 to n13 are each independently an integer from 0 to 4,
n14 is an integer from 0 to 3,
n15 and n16 are each independently an integer from 0 to 6, and
X₁ to X₃, Rₐ to R_{c}, R₁ₐ to R_{1d}, R₂ₐ to R_{2d}, and R₃ₐ to R_{3c} are each the same as defined in Formula 1, Formula 2, and Formula 3.

9. The light emitting device of claim 1, wherein the first compound represented by Formula 1 is represented by one of Formula 10-1 to Formula 10-6: 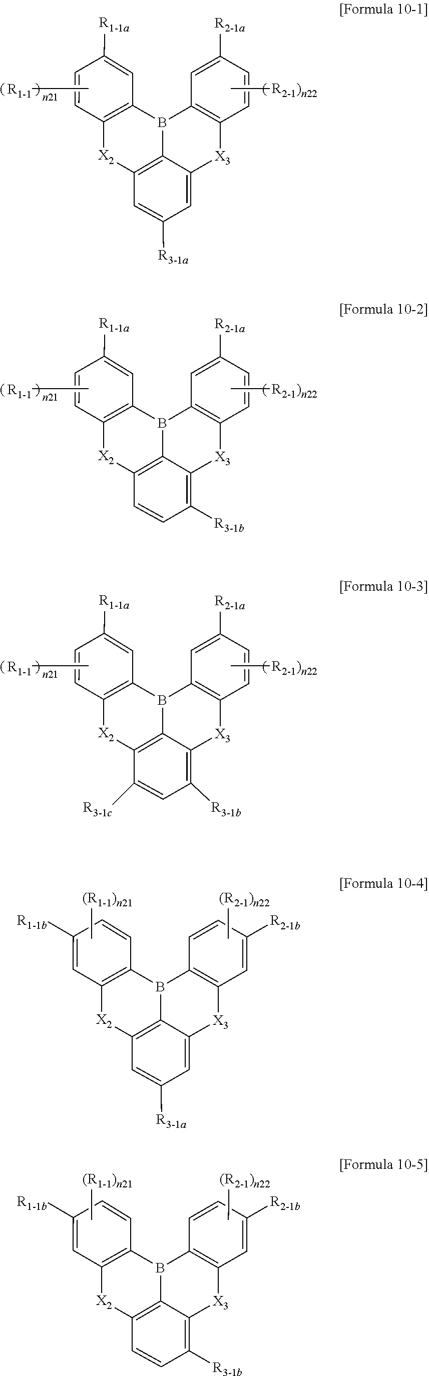 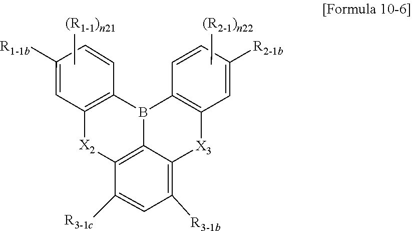
wherein in Formula 10-1 to Formula 10-6,
R₁₋₁ and R₂₋₁ are each independently a hydrogen atom, a deuterium atom, a halogen atom, a substituted or unsubstituted alkyl group having 1 to 20 carbon group, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, a group represented by Formula 2, or are bonded to an adjacent group to form a ring,
R₁₋₁ₐ, R_{1-1b}, R₂₋₁ₐ, and R_{2-1b} are each independently a substituted or unsubstituted t-butyl group, an aryl group having 6 to 30 ring-forming carbon atoms which is substituted with a t-butyl group, or a substituted or unsubstituted carbazole group,
R₃₋₁ₐ to R_{3-1c} are each independently a group represented by Formula 2,
n21 and n22 are each independently an integer from 0 to 3, and
X₂ and X₃ are each the same as defined in Formula 1.

10. The light emitting device of claim 1, wherein the emission layer further comprises a second compound represented by Formula H-1: 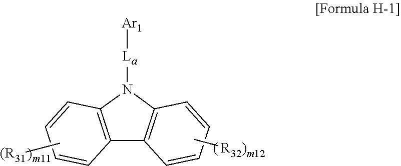
wherein in Formula H-1,
Lₐ is a direct linkage, a substituted or unsubstituted arylene group having 6 to 30 ring-forming carbon atoms, or a substituted or unsubstituted heteroarylene group having 2 to 30 ring-forming carbon atoms,
Ar₁ is a substituted or unsubstituted aryl group having 6 to 30 ring-forming carbon atoms, or a substituted or unsubstituted heteroaryl group having 2 to 30 ring-forming carbon atoms,
R₃₁ and R₃₂ are each independently a hydrogen atom, a deuterium atom, a halogen atom, a substituted or unsubstituted alkyl group having 1 to 20 carbon group, a substituted or unsubstituted aryl group having 6 to 30 ring-forming carbon atoms, or a substituted or unsubstituted heteroaryl group having 2 to 30 ring-forming carbon atoms, and
m11 and m12 are each independently an integer from 0 to 4.

11. The light emitting device of claim 1, wherein the emission layer further comprises a third compound represented by Formula D-1: 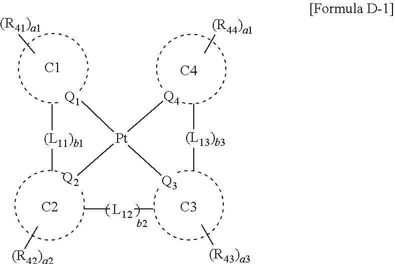
wherein in Formula D-1,
Q₁ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
R₄₁ to R₄₆ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or are bonded to an adjacent group to form a ring,
a1 to a4 are each independently an integer from 0 to 4,
L₁₁ to L₁₃ are each independently a direct linkage, 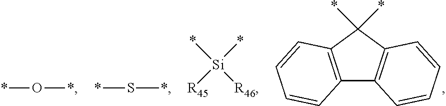
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and
b1 to b3 are each independently 0 or 1.

12. The light emitting device of claim 1, wherein the emission layer further comprises a fourth compound represented by Formula D-2: 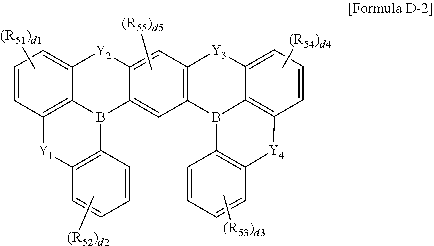
wherein in Formula D-2,
Y₁ to Y₄ are each independently N(R₅₆), O or S,
R₅₁ to R₅₆ are each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or are bonded to an adjacent group to form a ring,
d1 and d4 are each independently an integer from 0 to 3,
d2 and d3 are each independently an integer from 0 to 4, and
d5 is an integer from 0 to 2.

13. The light emitting device of claim 1, wherein the first compound represented by Formula 1 includes at least one compound selected from Compound Group 1:

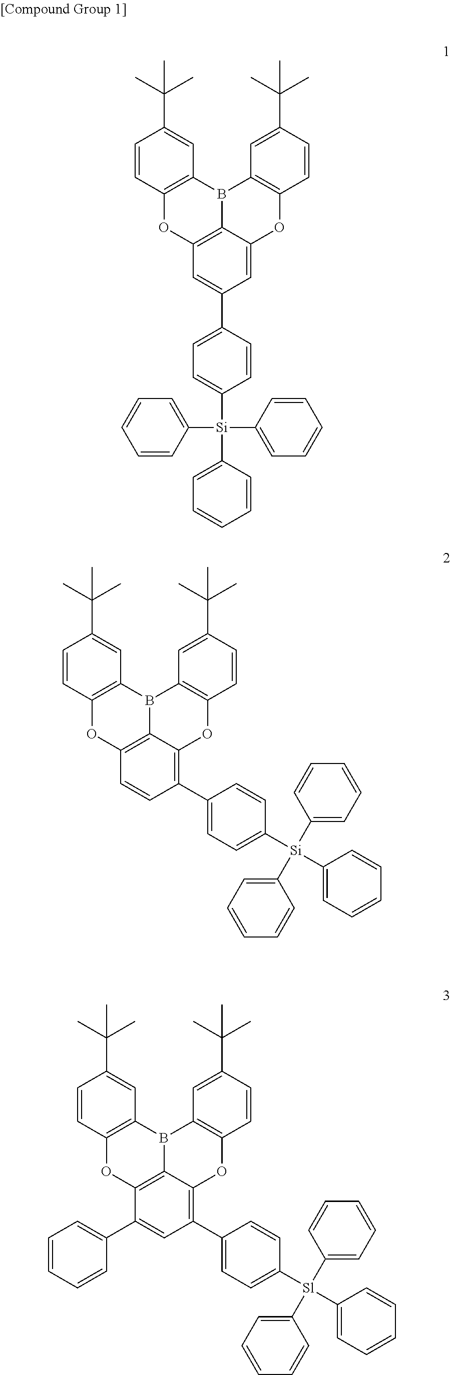

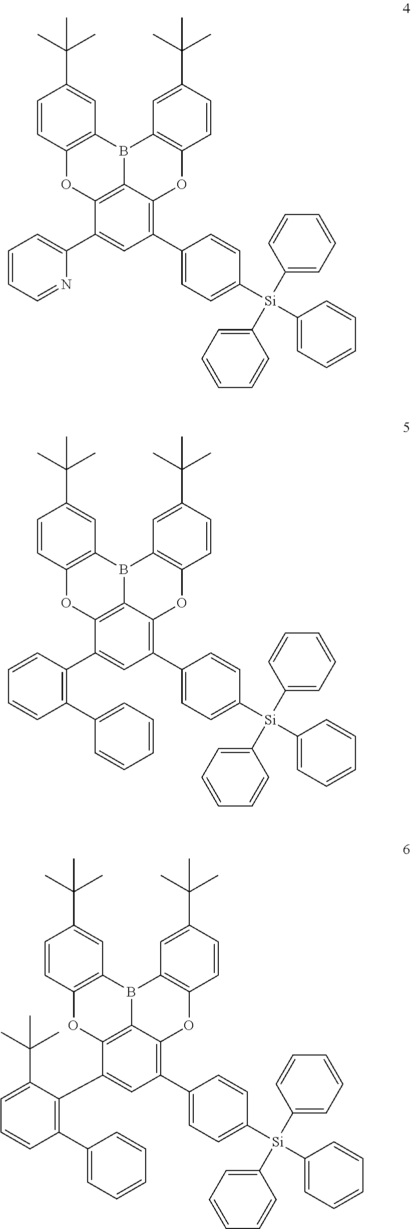 [SMILES: CC(C)(C)c1ccc2c(c1)B1c3cc(C(C)(C)C)ccc3Oc3c(-c4ccccn4)cc(-c4ccc([Si](c5ccccc5)(c5ccccc5)c5ccccc5)cc4)c(c31)O2 ; CC(C)(C)c1ccc2c(c1)B1c3cc(C(C)(C)C)ccc3Oc3c(-c4ccccc4-c4ccccc4)cc(-c4ccc([Si](c5ccccc5)(c5ccccc5)c5ccccc5)cc4)c(c31)O2 ; CC(C)(C)c1ccc2c(c1)B1c3cc(C(C)(C)C)ccc3Oc3c(-c4c(-c5ccccc5)cccc4C(C)(C)C)cc(-c4ccc([Si](c5ccccc5)(c5ccccc5)c5ccccc5)cc4)c(c31)O2]

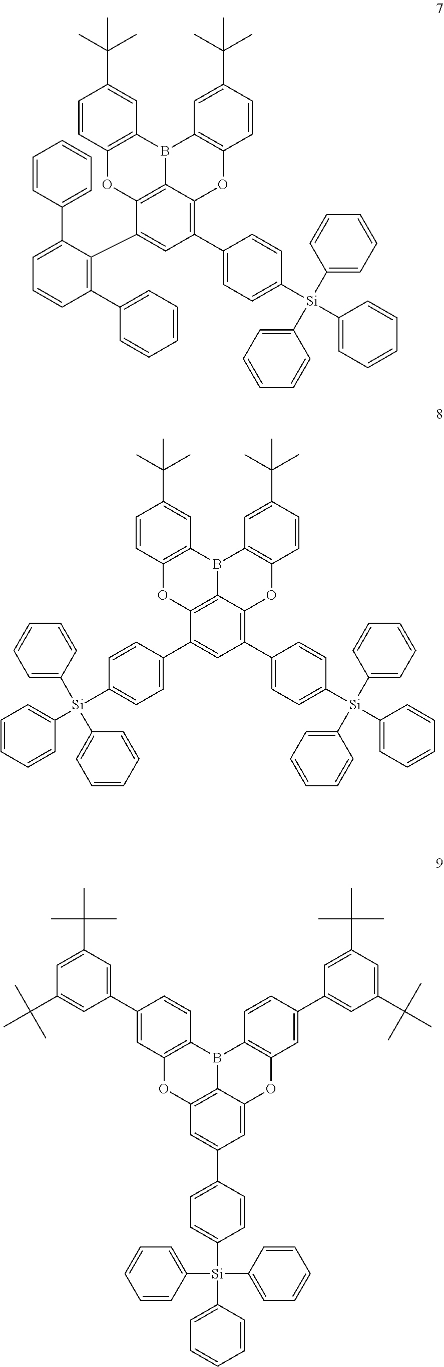 [SMILES: CC(C)(C)c1ccc2c(c1)B1c3cc(C(C)(C)C)ccc3Oc3c(-c4c(-c5ccccc5)cccc4-c4ccccc4)cc(-c4ccc([Si](c5ccccc5)(c5ccccc5)c5ccccc5)cc4)c(c31)O2 ; CC(C)(C)c1ccc2c(c1)B1c3cc(C(C)(C)C)ccc3Oc3c(-c4ccc([Si](c5ccccc5)(c5ccccc5)c5ccccc5)cc4)cc(-c4ccc([Si](c5ccccc5)(c5ccccc5)c5ccccc5)cc4)c(c31)O2 ; CC(C)(C)c1cc(-c2ccc3c(c2)Oc2cc(-c4ccc([Si](c5ccccc5)(c5ccccc5)c5ccccc5)cc4)cc4c2B3c2ccc(-c3cc(C(C)(C)C)cc(C(C)(C)C)c3)cc2O4)cc(C(C)(C)C)c1]

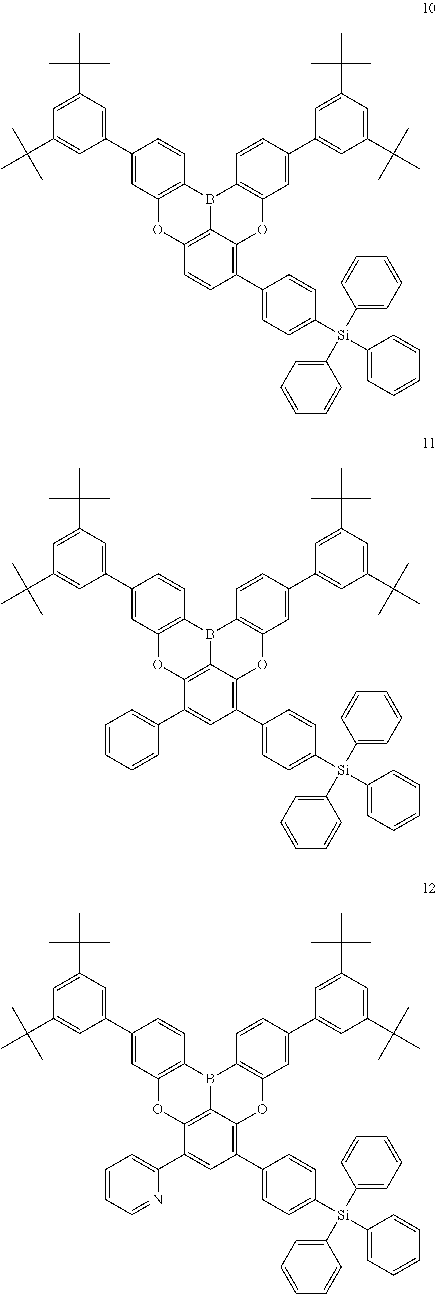

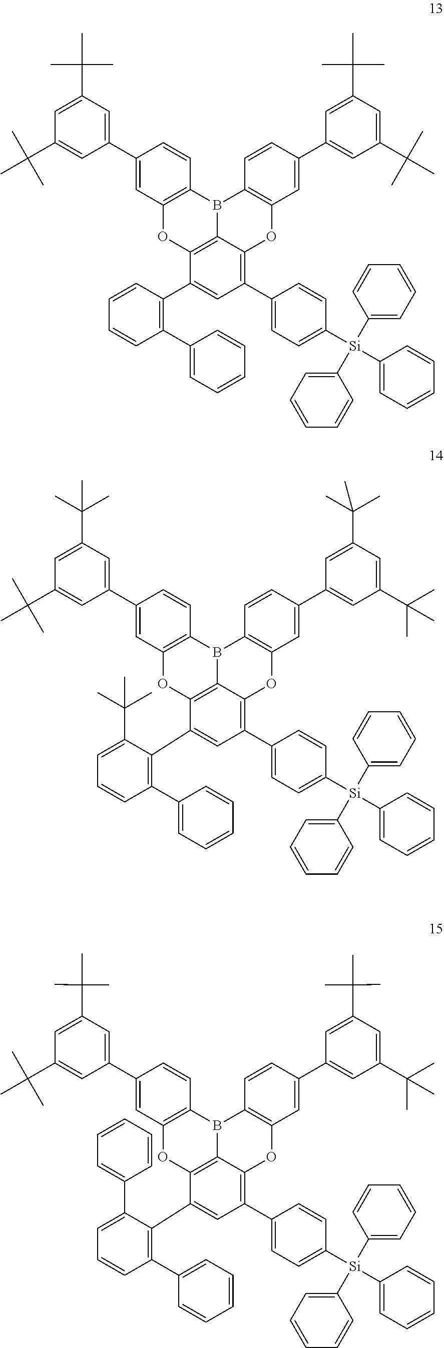

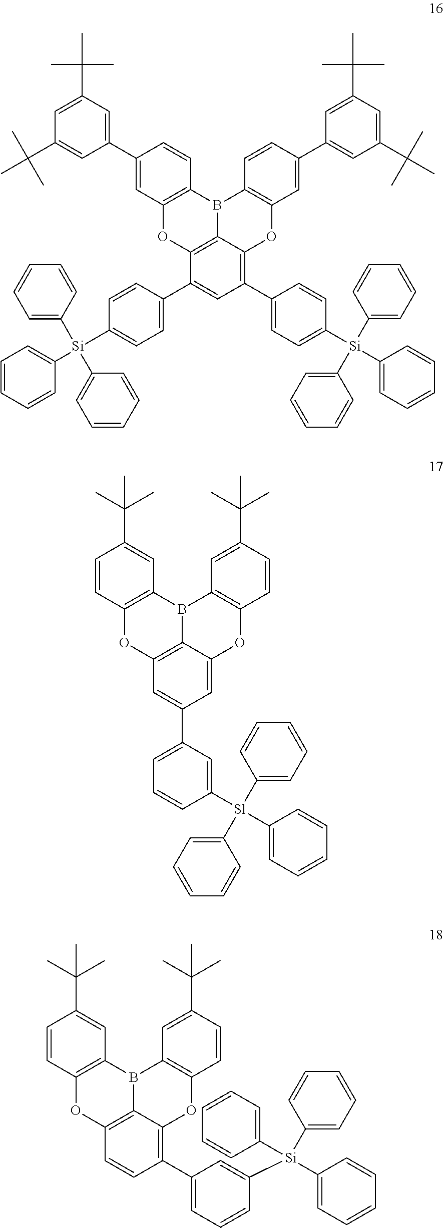

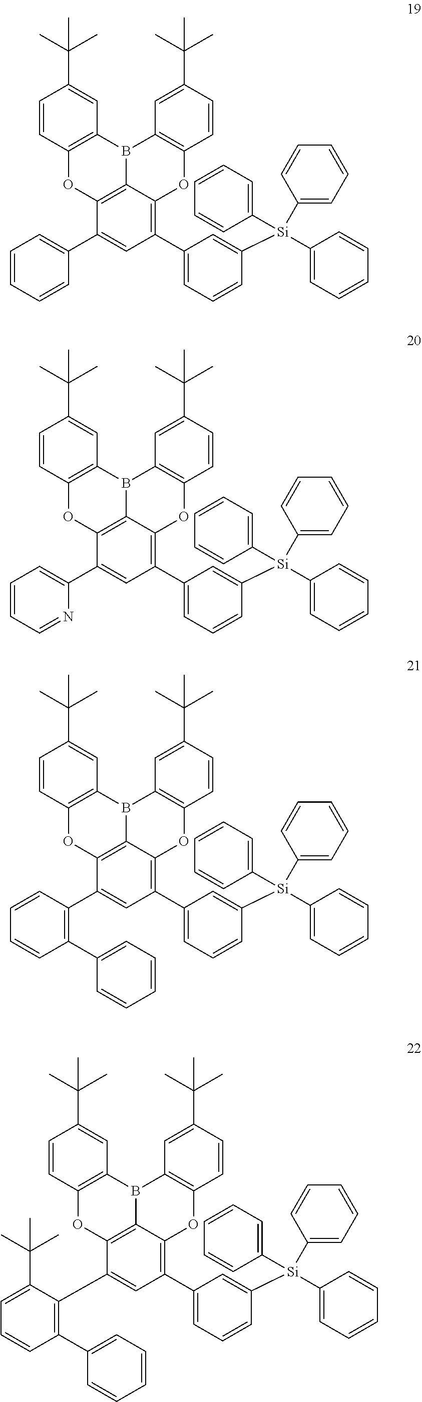 [SMILES: CC(C)(C)c1ccc2c(c1)B1c3cc(C(C)(C)C)ccc3Oc3c(-c4cccc([Si](c5ccccc5)(c5ccccc5)c5ccccc5)c4)cc(-c4ccccc4)c(c31)O2 ; CC(C)(C)c1ccc2c(c1)B1c3cc(C(C)(C)C)ccc3Oc3c(-c4ccccn4)cc(-c4cccc([Si](c5ccccc5)(c5ccccc5)c5ccccc5)c4)c(c31)O2 ; CC(C)(C)c1ccc2c(c1)B1c3cc(C(C)(C)C)ccc3Oc3c(-c4ccccc4-c4ccccc4)cc(-c4cccc([Si](c5ccccc5)(c5ccccc5)c5ccccc5)c4)c(c31)O2 ; CC(C)(C)c1ccc2c(c1)B1c3cc(C(C)(C)C)ccc3Oc3c(-c4c(-c5ccccc5)cccc4C(C)(C)C)cc(-c4cccc([Si](c5ccccc5)(c5ccccc5)c5ccccc5)c4)c(c31)O2]

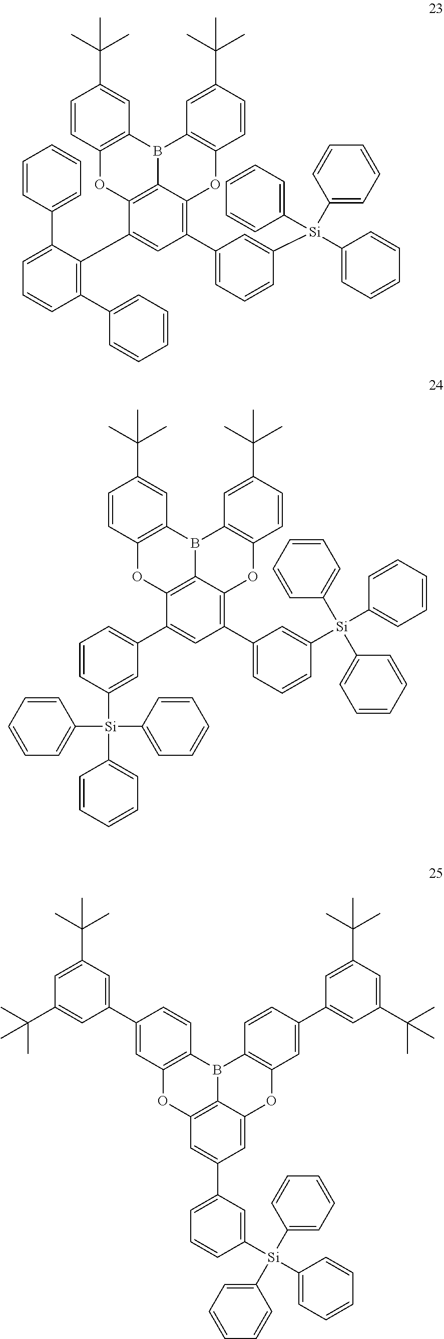 [SMILES: CC(C)(C)c1ccc2c(c1)B1c3cc(C(C)(C)C)ccc3Oc3c(-c4c(-c5ccccc5)cccc4-c4ccccc4)cc(-c4cccc([Si](c5ccccc5)(c5ccccc5)c5ccccc5)c4)c(c31)O2 ; CC(C)(C)c1ccc2c(c1)B1c3cc(C(C)(C)C)ccc3Oc3c(-c4cccc([Si](c5ccccc5)(c5ccccc5)c5ccccc5)c4)cc(-c4cccc([Si](c5ccccc5)(c5ccccc5)c5ccccc5)c4)c(c31)O2 ; CC(C)(C)c1cc(-c2ccc3c(c2)Oc2cc(-c4cccc([Si](c5ccccc5)(c5ccccc5)c5ccccc5)c4)cc4c2B3c2ccc(-c3cc(C(C)(C)C)cc(C(C)(C)C)c3)cc2O4)cc(C(C)(C)C)c1]

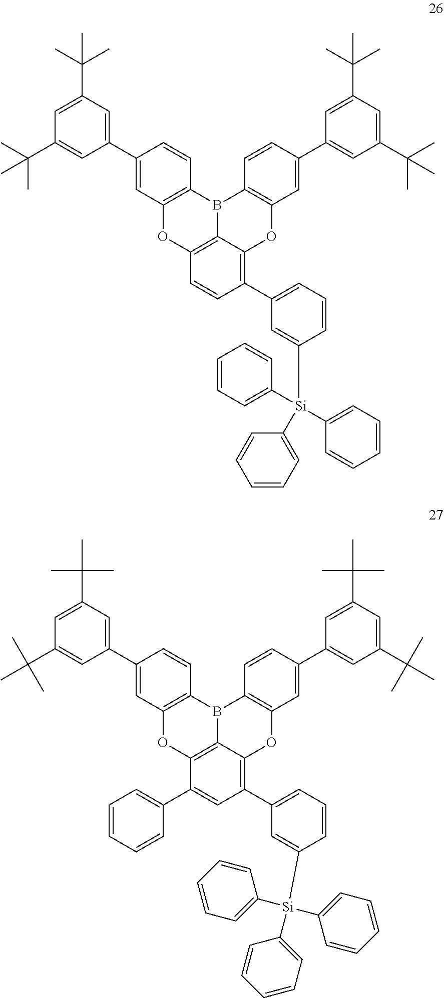

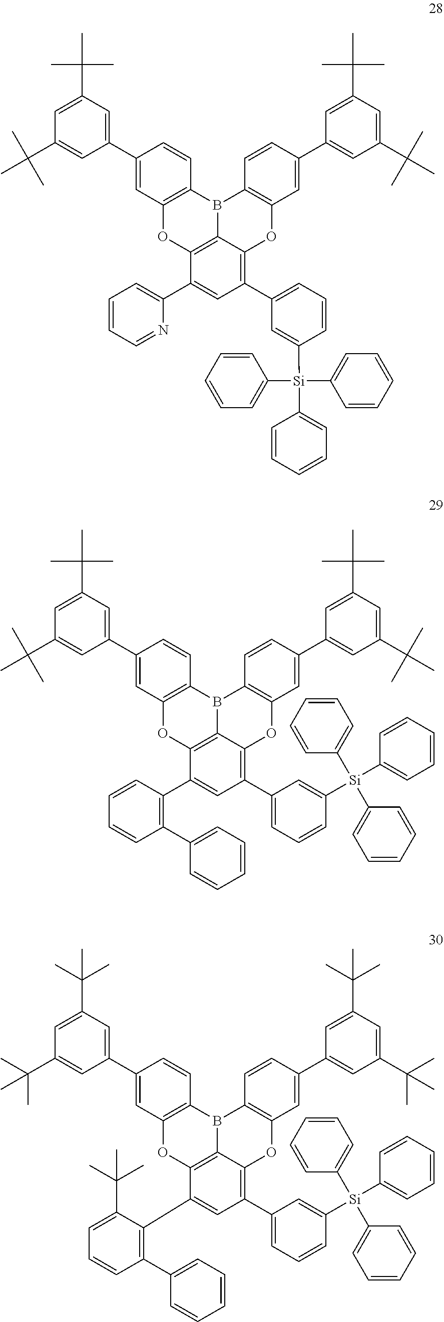

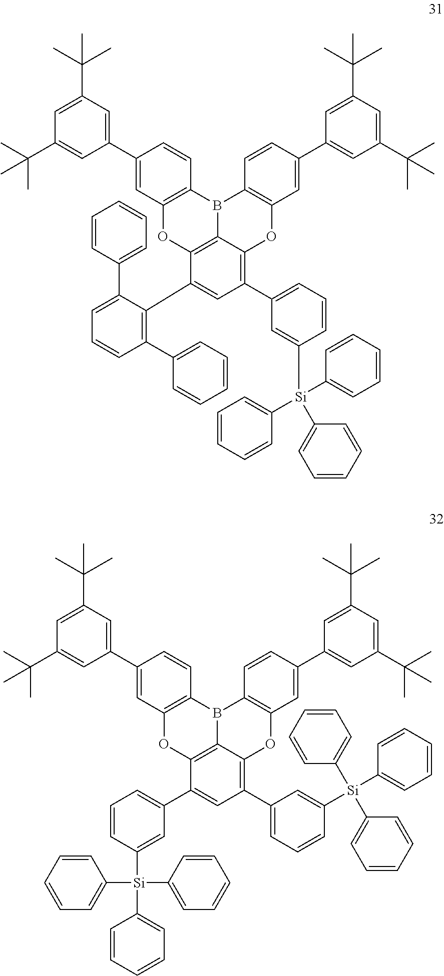

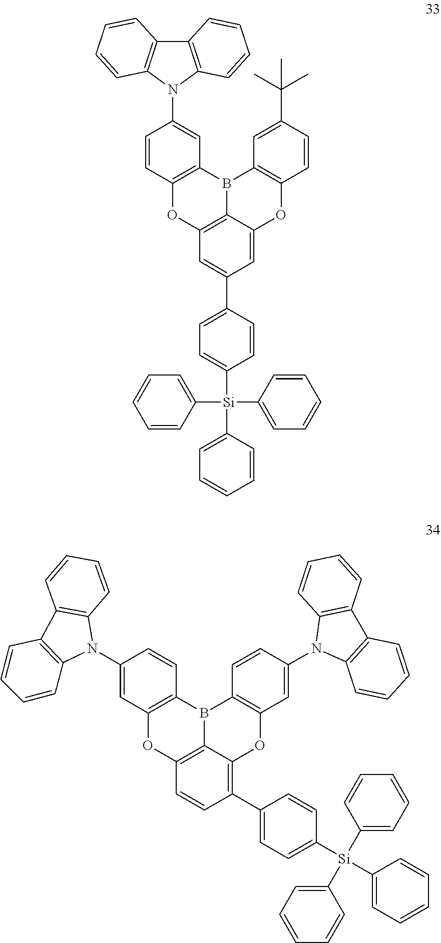 [SMILES: CC(C)(C)c1ccc2c(c1)B1c3cc(-n4c5ccccc5c5ccccc54)ccc3Oc3cc(-c4ccc([Si](c5ccccc5)(c5ccccc5)c5ccccc5)cc4)cc(c31)O2 ; c1ccc([Si](c2ccccc2)(c2ccccc2)c2ccc(-c3ccc4c5c3Oc3cc(-n6c7ccccc7c7ccccc76)ccc3B5c3ccc(-n5c6ccccc6c6ccccc65)cc3O4)cc2)cc1]

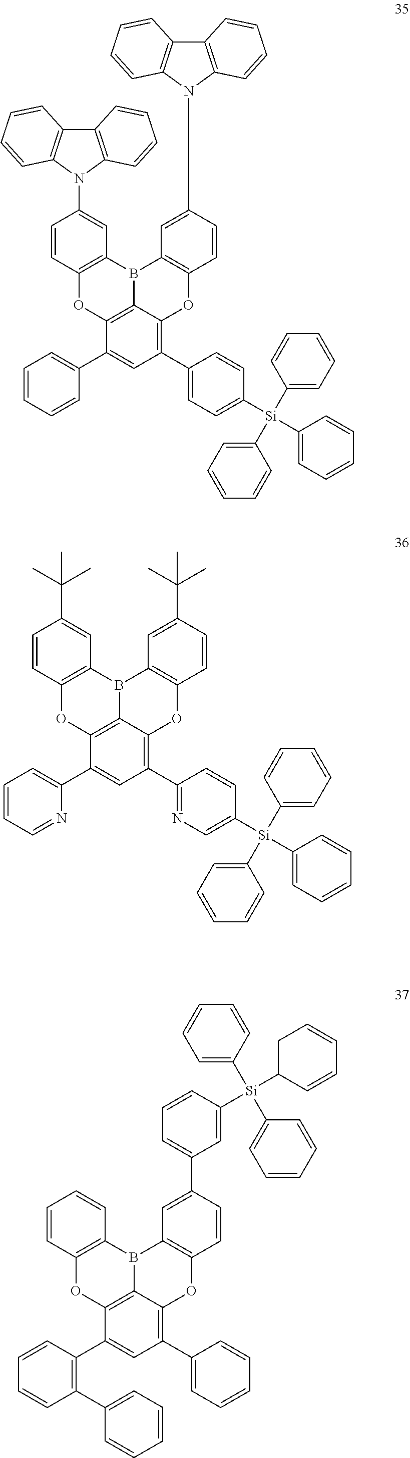 [SMILES: c1ccc(-c2cc(-c3ccc([Si](c4ccccc4)(c4ccccc4)c4ccccc4)cc3)c3c4c2Oc2ccc(-n5c6ccccc6c6ccccc65)cc2B4c2cc(-n4c5ccccc5c5ccccc54)ccc2O3)cc1 ; CC(C)(C)c1ccc2c(c1)B1c3cc(C(C)(C)C)ccc3Oc3c(-c4ccc([Si](c5ccccc5)(c5ccccc5)c5ccccc5)cn4)cc(-c4ccccn4)c(c31)O2 ; C1=CCC([Si](c2ccccc2)(c2ccccc2)c2cccc(-c3ccc4c(c3)B3c5ccccc5Oc5c(-c6ccccc6-c6ccccc6)cc(-c6ccccc6)c(c53)O4)c2)C=C1]

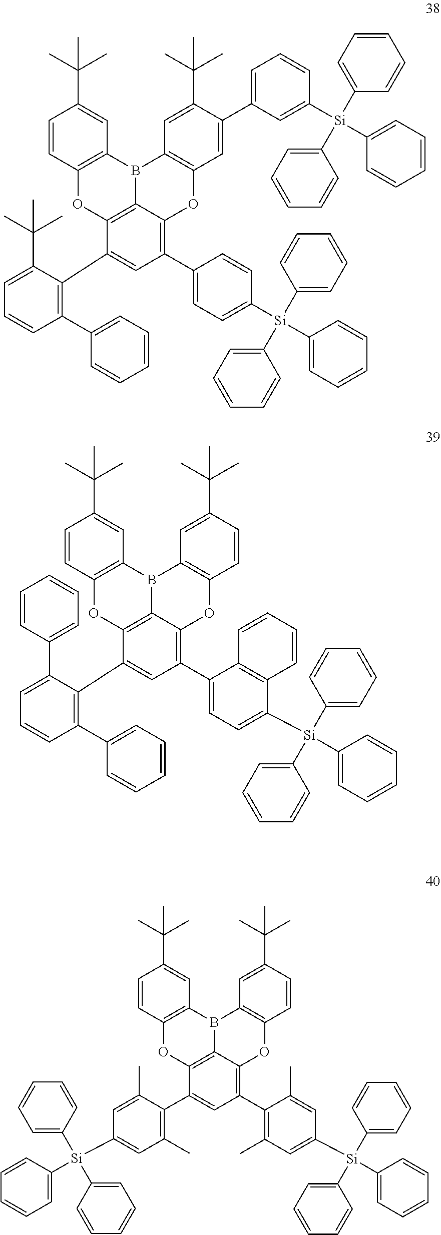

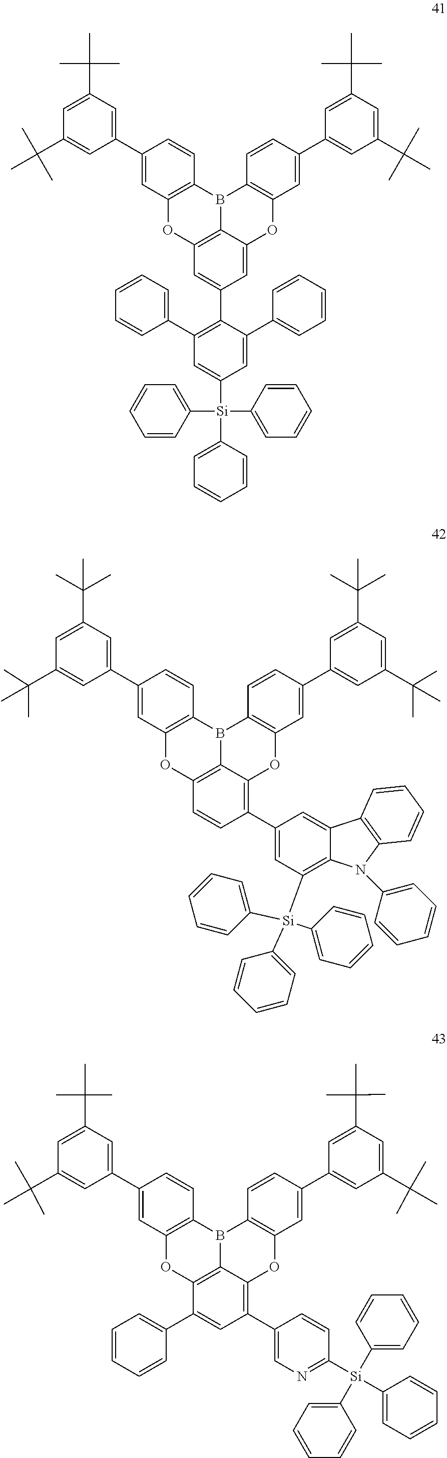

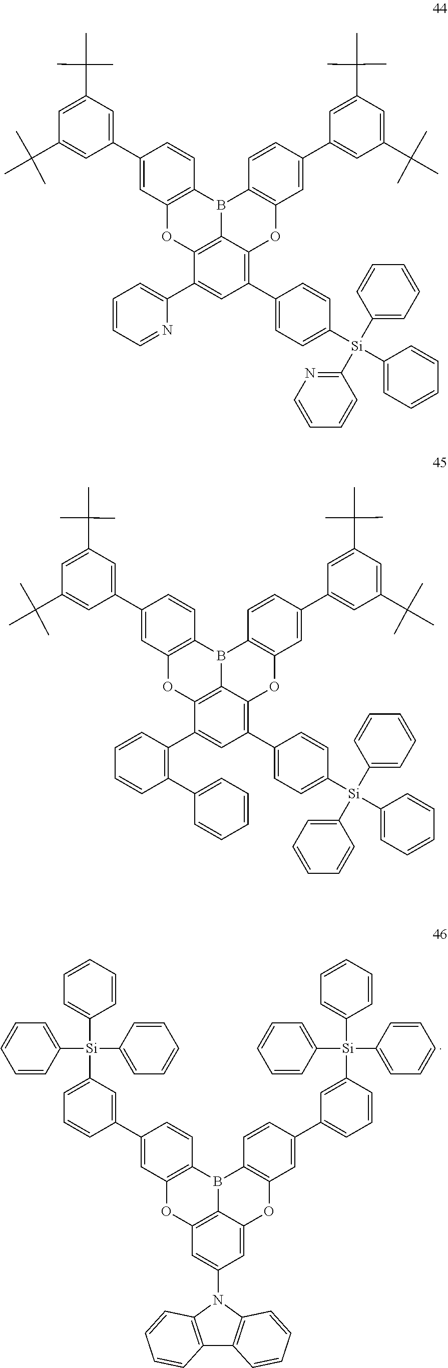 [SMILES: CC(C)(C)c1cc(-c2ccc3c(c2)Oc2c(-c4ccc([Si](c5ccccc5)(c5ccccc5)c5ccccn5)cc4)cc(-c4ccccn4)c4c2B3c2ccc(-c3cc(C(C)(C)C)cc(C(C)(C)C)c3)cc2O4)cc(C(C)(C)C)c1 ; CC(C)(C)c1cc(-c2ccc3c(c2)Oc2c(-c4ccc([Si](c5ccccc5)(c5ccccc5)c5ccccc5)cc4)cc(-c4ccccc4-c4ccccc4)c4c2B3c2ccc(-c3cc(C(C)(C)C)cc(C(C)(C)C)c3)cc2O4)cc(C(C)(C)C)c1 ; c1ccc([Si](c2ccccc2)(c2ccccc2)c2cccc(-c3ccc4c(c3)Oc3cc(-n5c6ccccc6c6ccccc65)cc5c3B4c3ccc(-c4cccc([Si](c6ccccc6)(c6ccccc6)c6ccccc6)c4)cc3O5)c2)cc1]

14. A fused polycyclic compound represented by Formula 1: 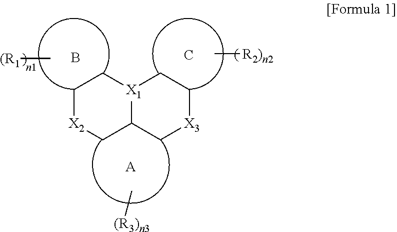
wherein in Formula 1,
A, B, and C are each independently a monocyclic aromatic hydrocarbon ring having 6 to 30 ring-forming carbon atoms, or a monocyclic aromatic heterocycle having 2 to 30 ring-forming carbon atoms,
X₁ is B, P, P═O, P═S, Al, Ga, As, Si(R₄) or Ge(R₅),
X₂ and X₃ are each independently O, S, Se, or N(R₆),
R₁ to R₃ are each independently a hydrogen atom, a deuterium atom, a halogen atom, a substituted or unsubstituted alkyl group having 1 to 20 carbon group, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, a group represented by Formula 2, or are bonded to an adjacent group to form a ring,
at least one of R₁ to R₃ is each independently a group represented by Formula 2,
R₄ to R₆ are each independently a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or are bonded to an adjacent group to form a ring,
n1 and n2 are each independently an integer from 1 to 4, and
n3 is an integer from 1 to 3, 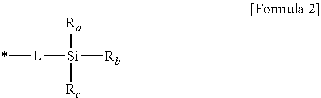
wherein in Formula 2,
Rₐ to R_{c} are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
L is a substituted or unsubstituted arylene group having 6 to 30 ring-forming carbon atoms, or a substituted or unsubstituted heteroarylene group having 2 to 30 ring-forming carbon atoms, and [symbol] represents a bonding site to Formula 1.

15. The fused polycyclic compound of claim 14, wherein the fused polycyclic compound represented by Formula 1 is represented by Formula 3: 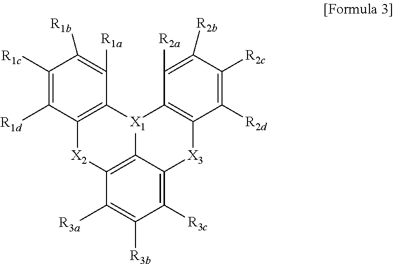
wherein in Formula 3,
R₁ₐ to R_{1d}, R₂ₐ to R_{2d}, and R₃ₐ to R_{3c} are each independently a hydrogen atom, a deuterium atom, a halogen atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, a group represented by Formula 2, or are bonded to an adjacent group to form a ring,
at least one of R₁ₐ to R_{1d}, R₂ₐ to R_{2d}, and R₃ₐ to R_{3c} is each independently a group represented by Formula 2, and
X₁ to X₃ are each the same as defined in Formula 1.

16. The fused polycyclic compound of claim 15, wherein the fused polycyclic compound represented by Formula 3 is represented by one of Formula 4-1 to Formula 4-4: 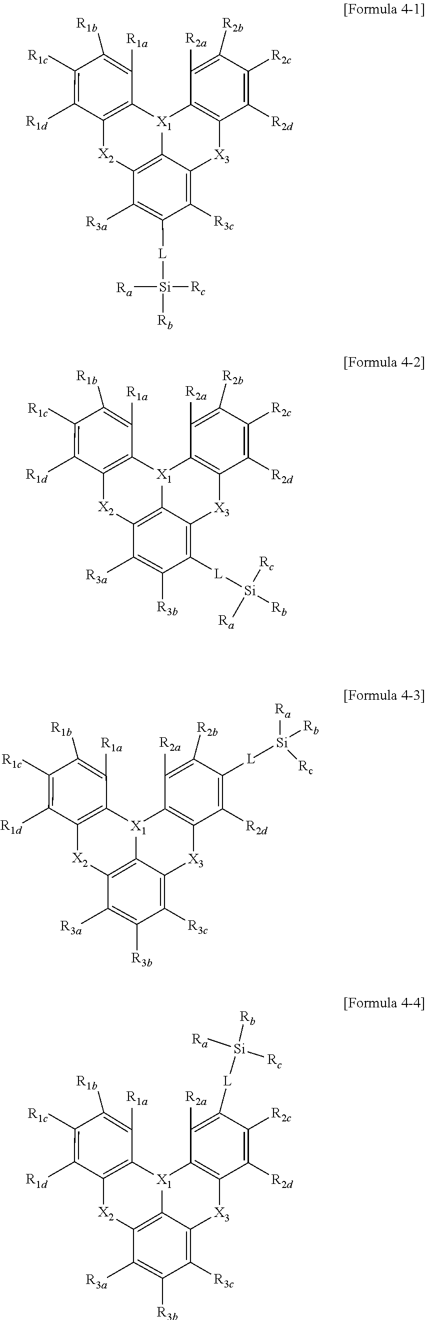
wherein in Formula 4-1 to Formula 4-4,
X₁ to X₃, L, Rₐ to R_{c}, R₁ₐ to R_{1d}, R₂ₐ to R_{2d}, and R₃ₐ to R_{3c} are each the same as defined in Formula 1, Formula 2, and Formula 3.

17. The fused polycyclic compound of claim 15, wherein the fused polycyclic compound represented by Formula 3 is represented by one of Formula 6-1 to Formula 6-4: 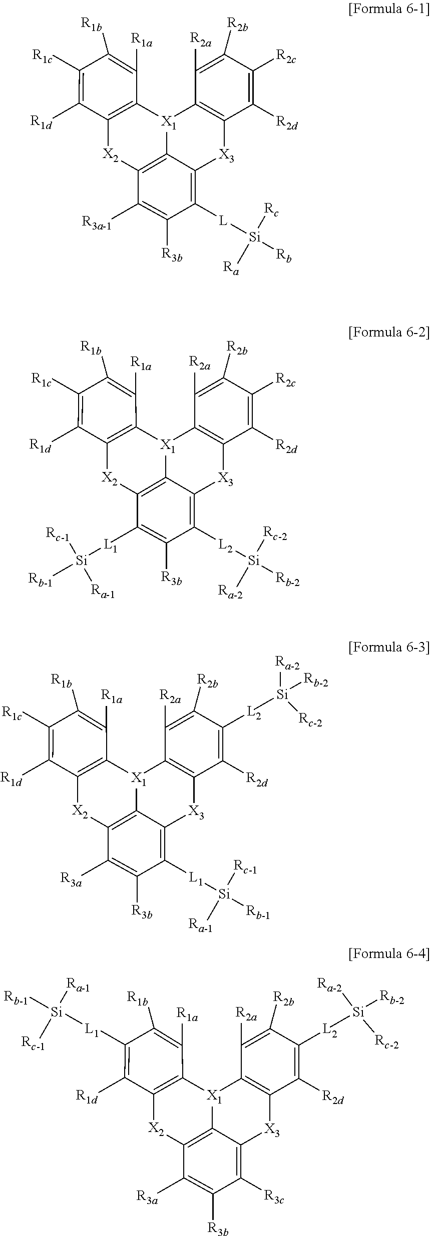
wherein in Formula 6-1 to Formula 6-4,
R₃ₐ₋₁ is a substituted or unsubstituted aryl group having 6 to 30 ring-forming carbon atoms, or a substituted or unsubstituted heteroaryl group having 2 to 30 ring-forming carbon atoms,
Rₐ₋₁ to R_{c-1} and Rₐ₋₂ to R_{c-2} are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
L₁ and L₂ are each independently a substituted or unsubstituted arylene group having 6 to 30 ring-forming carbon atoms, or a substituted or unsubstituted heteroarylene group having 2 to 30 ring-forming carbon atoms, and
X₁ to X₃, L, Rₐ to R_{c}, R₁ₐ to R_{1d}, R₂ₐ to R_{2d}, and R₃ₐ to R_{3c} are each the same as defined in Formula 1, Formula 2, and Formula 3.

18. The fused polycyclic compound of claim 15, wherein the fused polycyclic compound represented by Formula 3 is represented by one of Formula 8-1 to Formula 8-3: 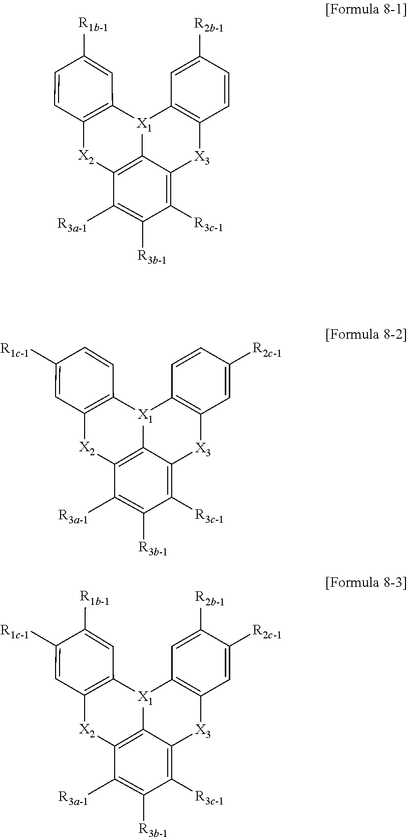
wherein in Formula 8-1 to Formula 8-3,
R_{1b-1}, R_{2b-1}, R_{1c-1}, R_{2c-1}, and R₃ₐ₋₁ to R_{3c-1} are each independently a hydrogen atom, a substituted or unsubstituted t-butyl group, a substituted or unsubstituted phenyl group, a substituted or unsubstituted biphenyl group, a substituted or unsubstituted terphenyl group, a substituted or unsubstituted pyridine group, a substituted or unsubstituted carbazole group, or a group represented by Formula 2,
at least one of R_{1b-1}, R_{2b-1}, R_{1c-1}, R_{2c-1}, and R₃ₐ₋₁ to R_{3c-1} is each independently a group represented by Formula 2, and
X₁ to X₃ are each the same as defined in Formula 1.

19. The fused polycyclic compound of claim 15, wherein the fused polycyclic compound represented by Formula 3 is represented by one of Formula 9-1 to Formula 9-6: 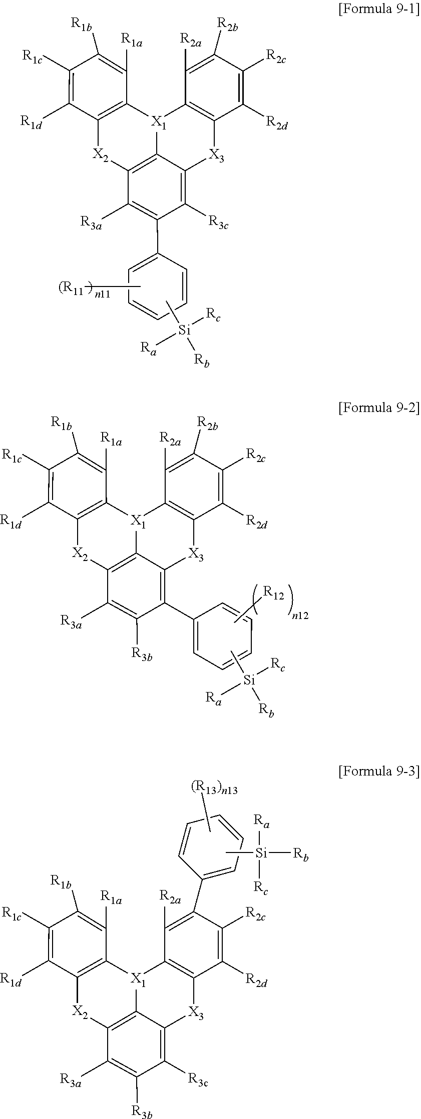 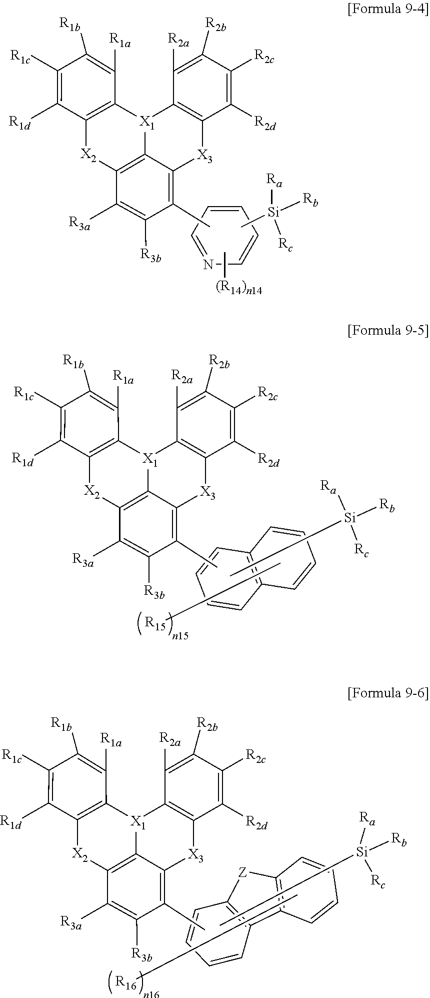
wherein in Formula 9-1 to Formula 9-6,
Z is N(R₁₇), O, or S,
R₁₁ to R₁₇ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n11 to n13 are each independently an integer from 0 to 4,
n14 is an integer from 0 to 3,
n15 and n16 are each independently an integer from 0 to 6, and
X₁ to X₃, Rₐ to R_{c}, R₁ₐ to R_{1d}, R₂ₐ to R_{2d}, and R₃ₐ to R_{3c} are each the same as defined in Formula 1, Formula 2, and Formula 3.

20. The fused polycyclic compound of claim 14, wherein the fused polycyclic compound represented by Formula 1 is selected from Compound Group 1: 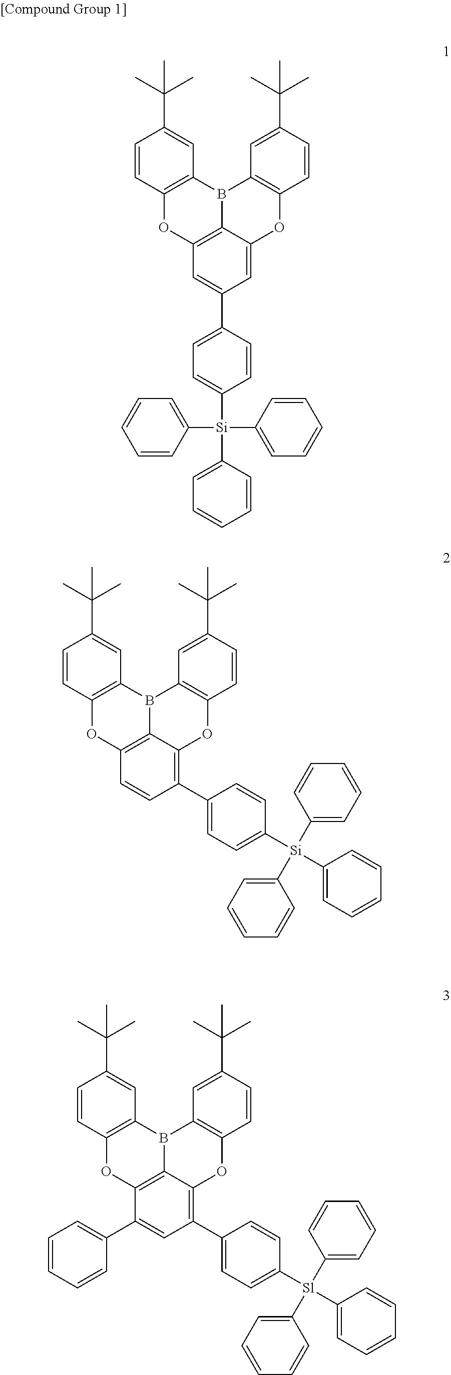 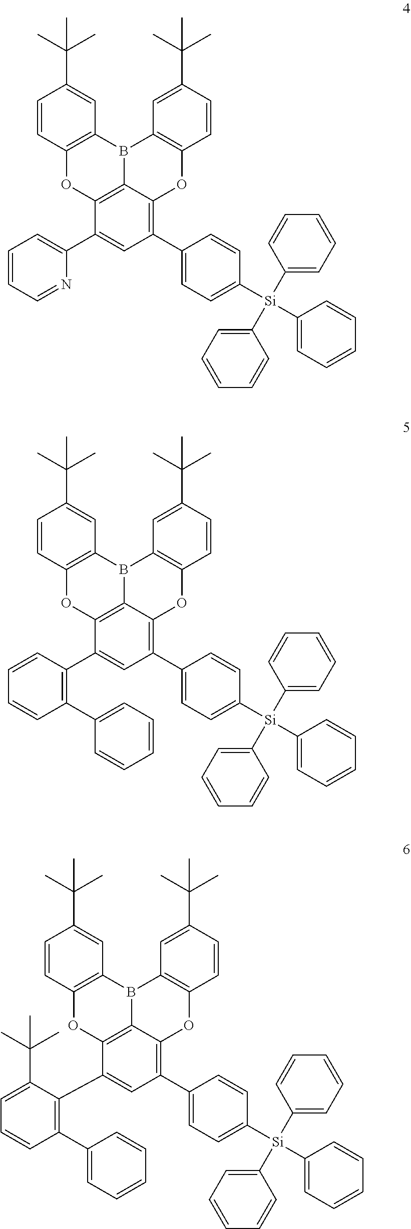 [SMILES: CC(C)(C)c1ccc2c(c1)B1c3cc(C(C)(C)C)ccc3Oc3c(-c4ccccn4)cc(-c4ccc([Si](c5ccccc5)(c5ccccc5)c5ccccc5)cc4)c(c31)O2 ; CC(C)(C)c1ccc2c(c1)B1c3cc(C(C)(C)C)ccc3Oc3c(-c4ccccc4-c4ccccc4)cc(-c4ccc([Si](c5ccccc5)(c5ccccc5)c5ccccc5)cc4)c(c31)O2 ; CC(C)(C)c1ccc2c(c1)B1c3cc(C(C)(C)C)ccc3Oc3c(-c4c(-c5ccccc5)cccc4C(C)(C)C)cc(-c4ccc([Si](c5ccccc5)(c5ccccc5)c5ccccc5)cc4)c(c31)O2] 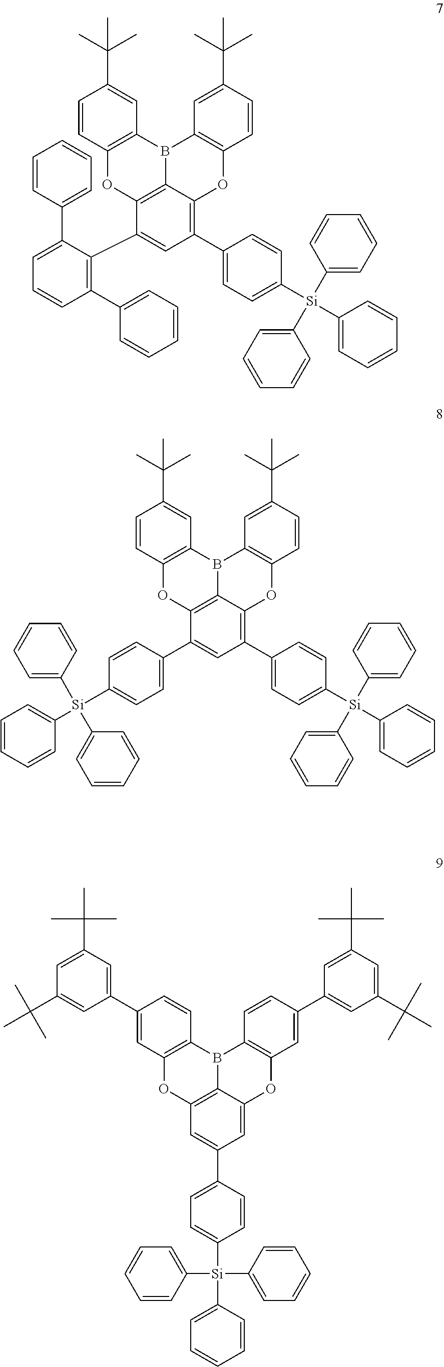 [SMILES: CC(C)(C)c1ccc2c(c1)B1c3cc(C(C)(C)C)ccc3Oc3c(-c4c(-c5ccccc5)cccc4-c4ccccc4)cc(-c4ccc([Si](c5ccccc5)(c5ccccc5)c5ccccc5)cc4)c(c31)O2 ; CC(C)(C)c1ccc2c(c1)B1c3cc(C(C)(C)C)ccc3Oc3c(-c4ccc([Si](c5ccccc5)(c5ccccc5)c5ccccc5)cc4)cc(-c4ccc([Si](c5ccccc5)(c5ccccc5)c5ccccc5)cc4)c(c31)O2 ; CC(C)(C)c1cc(-c2ccc3c(c2)Oc2cc(-c4ccc([Si](c5ccccc5)(c5ccccc5)c5ccccc5)cc4)cc4c2B3c2ccc(-c3cc(C(C)(C)C)cc(C(C)(C)C)c3)cc2O4)cc(C(C)(C)C)c1] 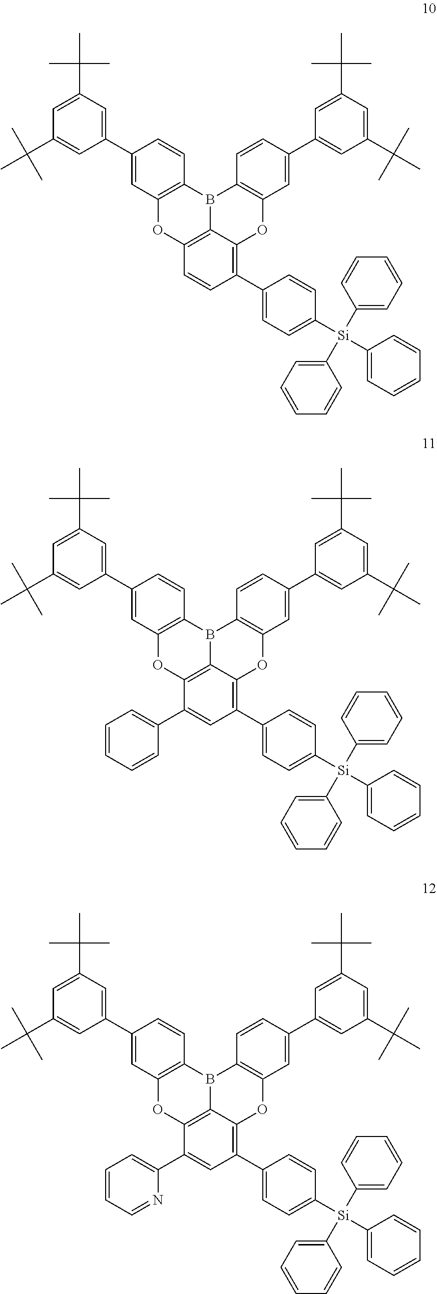 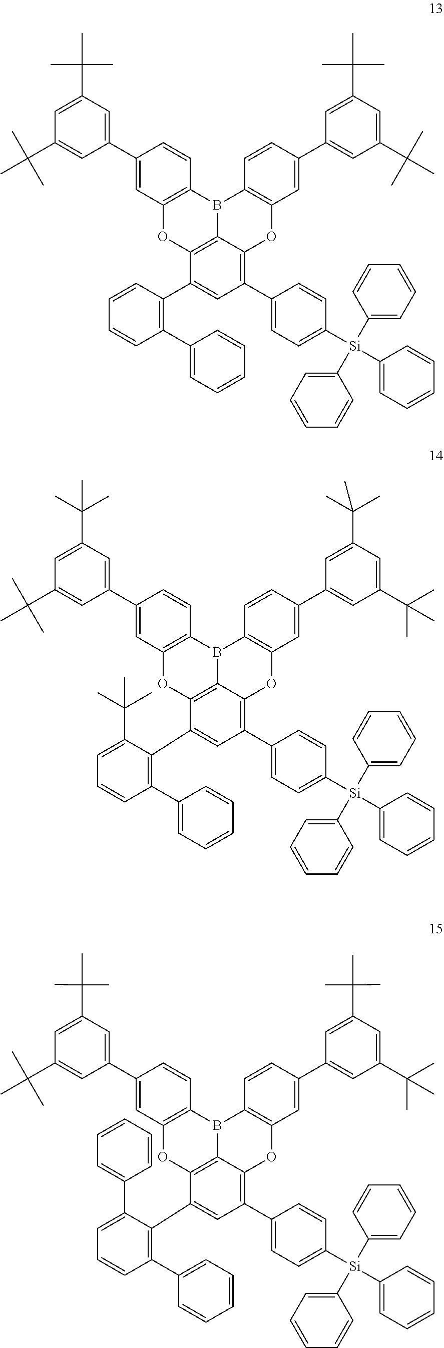 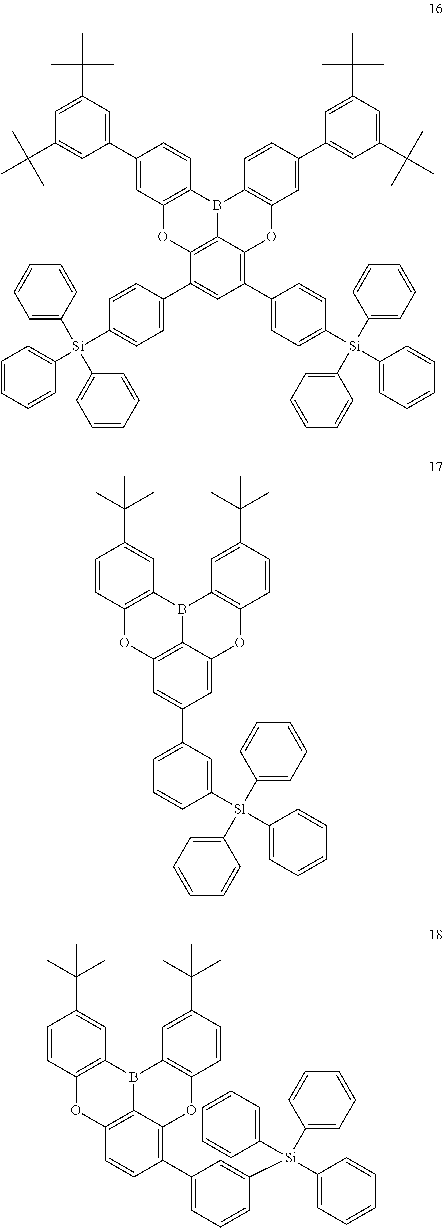 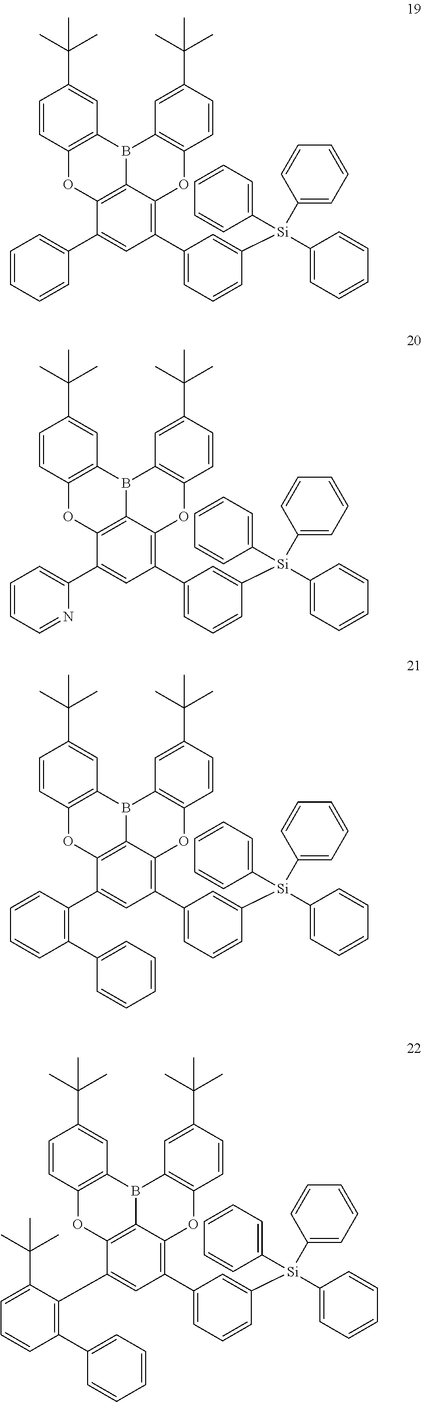 [SMILES: CC(C)(C)c1ccc2c(c1)B1c3cc(C(C)(C)C)ccc3Oc3c(-c4cccc([Si](c5ccccc5)(c5ccccc5)c5ccccc5)c4)cc(-c4ccccc4)c(c31)O2 ; CC(C)(C)c1ccc2c(c1)B1c3cc(C(C)(C)C)ccc3Oc3c(-c4ccccn4)cc(-c4cccc([Si](c5ccccc5)(c5ccccc5)c5ccccc5)c4)c(c31)O2 ; CC(C)(C)c1ccc2c(c1)B1c3cc(C(C)(C)C)ccc3Oc3c(-c4ccccc4-c4ccccc4)cc(-c4cccc([Si](c5ccccc5)(c5ccccc5)c5ccccc5)c4)c(c31)O2 ; CC(C)(C)c1ccc2c(c1)B1c3cc(C(C)(C)C)ccc3Oc3c(-c4c(-c5ccccc5)cccc4C(C)(C)C)cc(-c4cccc([Si](c5ccccc5)(c5ccccc5)c5ccccc5)c4)c(c31)O2] 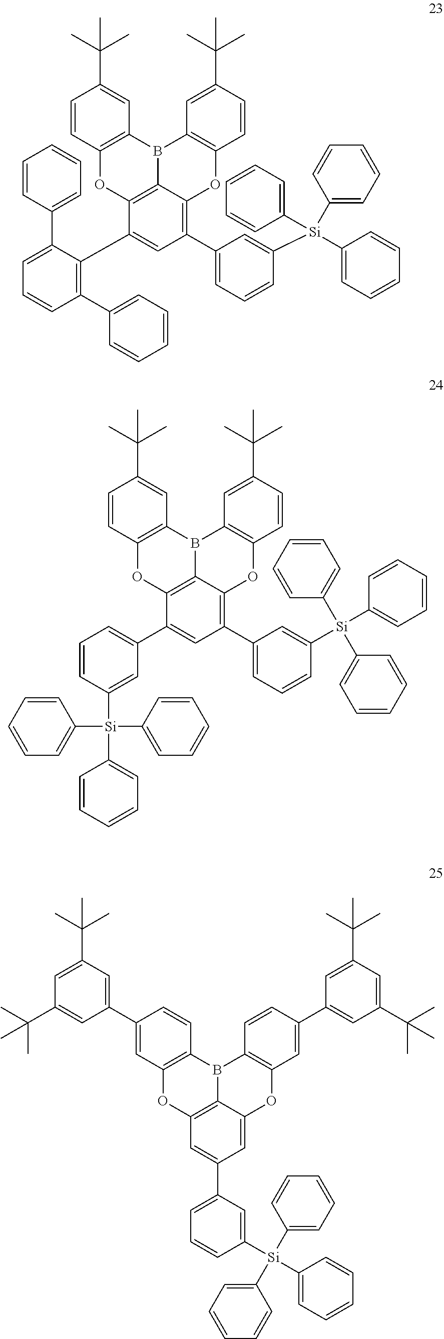 [SMILES: CC(C)(C)c1ccc2c(c1)B1c3cc(C(C)(C)C)ccc3Oc3c(-c4c(-c5ccccc5)cccc4-c4ccccc4)cc(-c4cccc([Si](c5ccccc5)(c5ccccc5)c5ccccc5)c4)c(c31)O2 ; CC(C)(C)c1ccc2c(c1)B1c3cc(C(C)(C)C)ccc3Oc3c(-c4cccc([Si](c5ccccc5)(c5ccccc5)c5ccccc5)c4)cc(-c4cccc([Si](c5ccccc5)(c5ccccc5)c5ccccc5)c4)c(c31)O2 ; CC(C)(C)c1cc(-c2ccc3c(c2)Oc2cc(-c4cccc([Si](c5ccccc5)(c5ccccc5)c5ccccc5)c4)cc4c2B3c2ccc(-c3cc(C(C)(C)C)cc(C(C)(C)C)c3)cc2O4)cc(C(C)(C)C)c1] 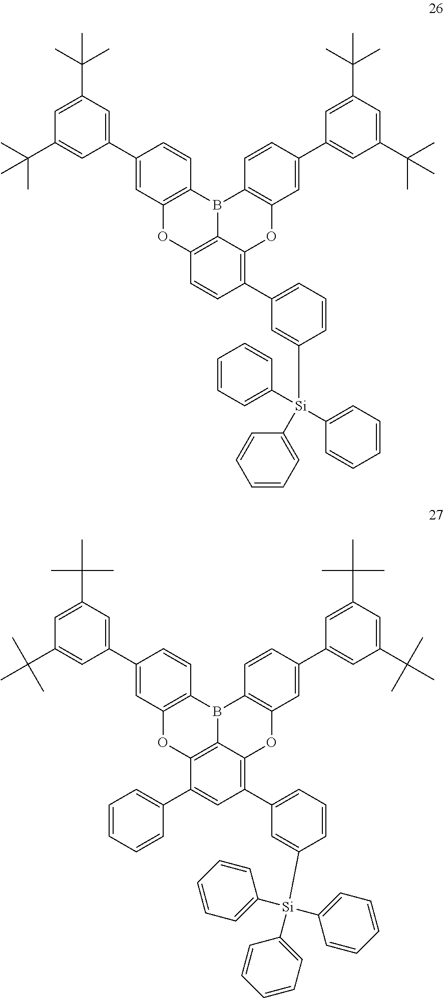 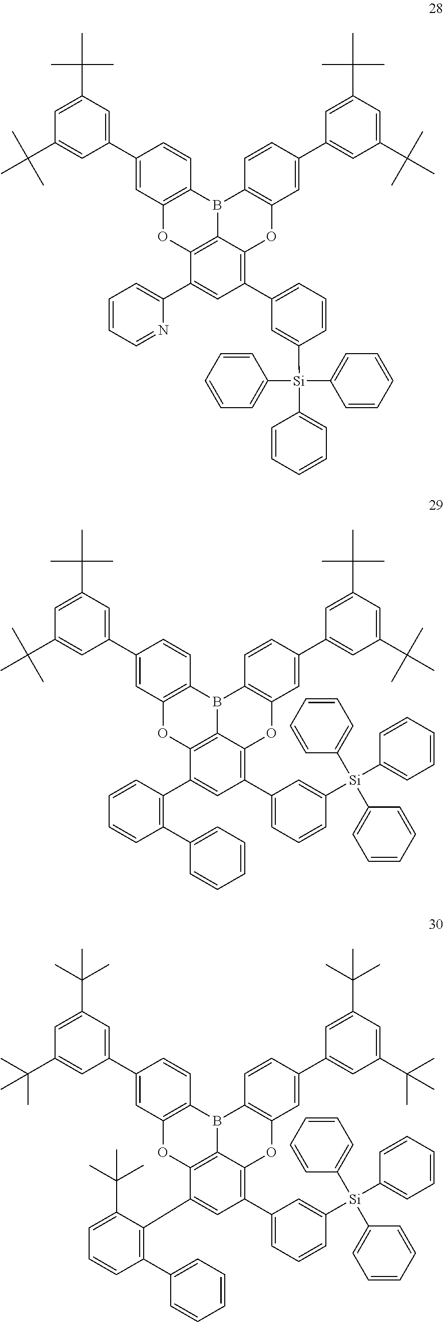 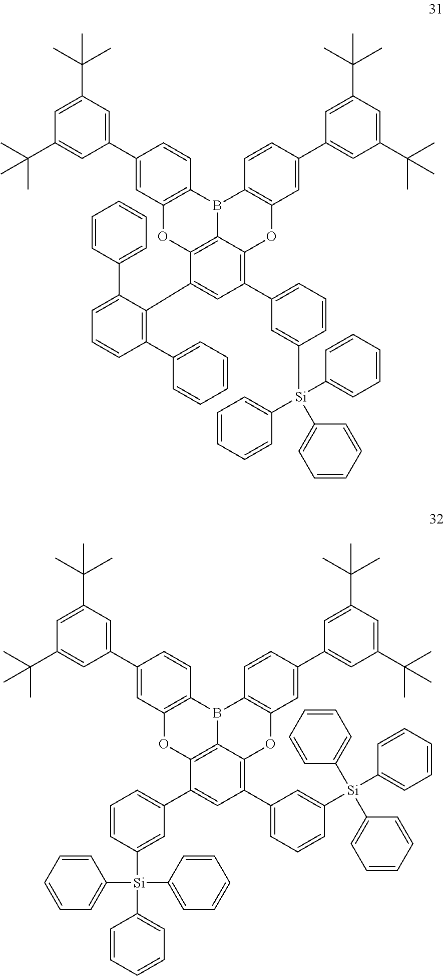 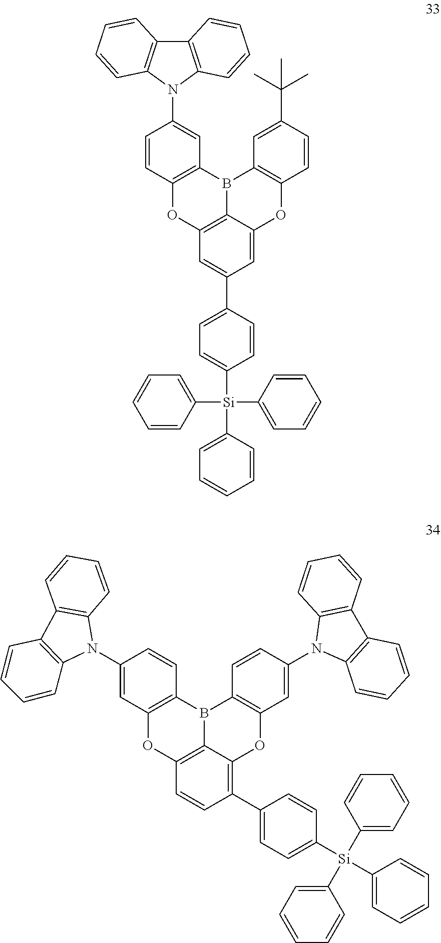 [SMILES: CC(C)(C)c1ccc2c(c1)B1c3cc(-n4c5ccccc5c5ccccc54)ccc3Oc3cc(-c4ccc([Si](c5ccccc5)(c5ccccc5)c5ccccc5)cc4)cc(c31)O2 ; c1ccc([Si](c2ccccc2)(c2ccccc2)c2ccc(-c3ccc4c5c3Oc3cc(-n6c7ccccc7c7ccccc76)ccc3B5c3ccc(-n5c6ccccc6c6ccccc65)cc3O4)cc2)cc1] 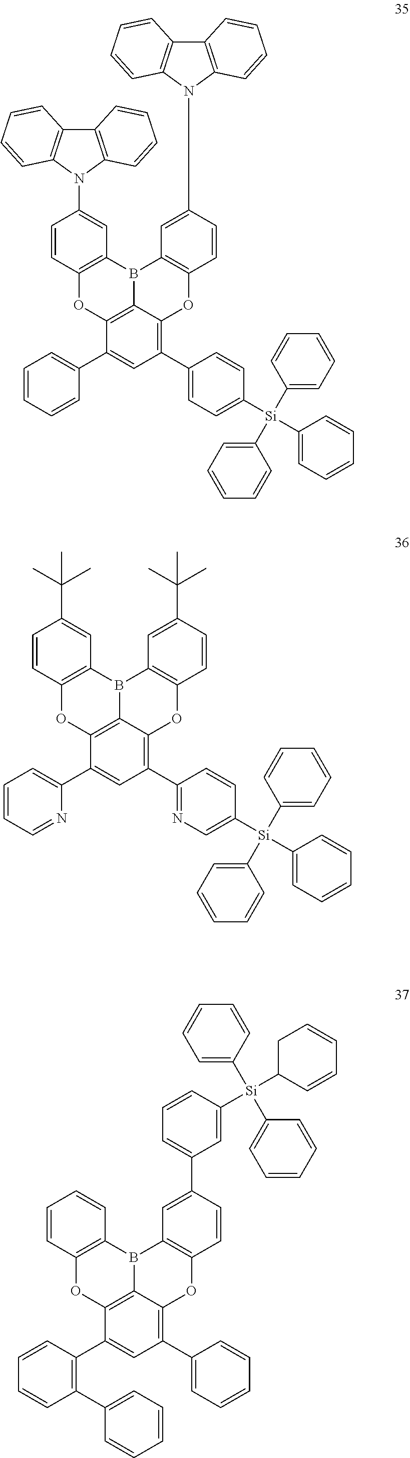 [SMILES: c1ccc(-c2cc(-c3ccc([Si](c4ccccc4)(c4ccccc4)c4ccccc4)cc3)c3c4c2Oc2ccc(-n5c6ccccc6c6ccccc65)cc2B4c2cc(-n4c5ccccc5c5ccccc54)ccc2O3)cc1 ; CC(C)(C)c1ccc2c(c1)B1c3cc(C(C)(C)C)ccc3Oc3c(-c4ccc([Si](c5ccccc5)(c5ccccc5)c5ccccc5)cn4)cc(-c4ccccn4)c(c31)O2 ; C1=CCC([Si](c2ccccc2)(c2ccccc2)c2cccc(-c3ccc4c(c3)B3c5ccccc5Oc5c(-c6ccccc6-c6ccccc6)cc(-c6ccccc6)c(c53)O4)c2)C=C1] 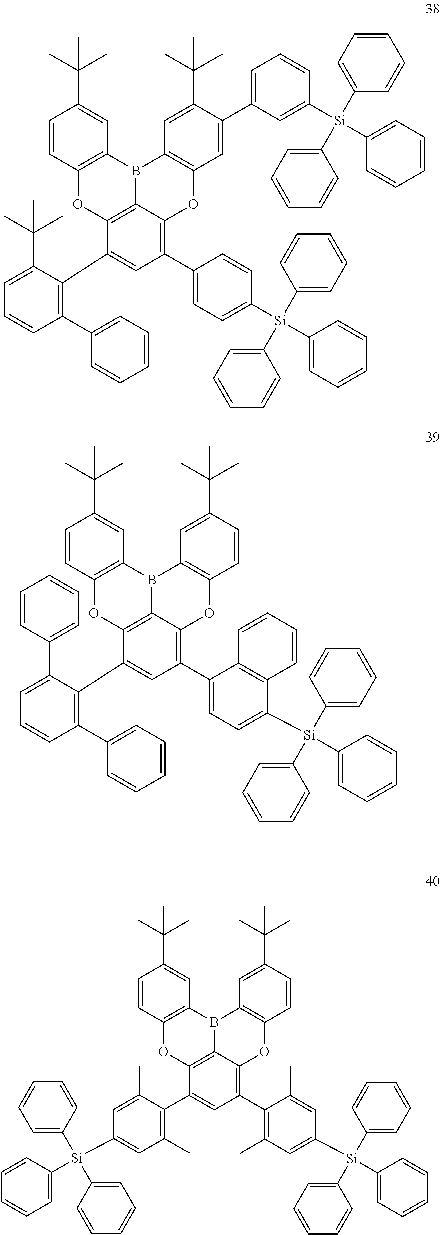 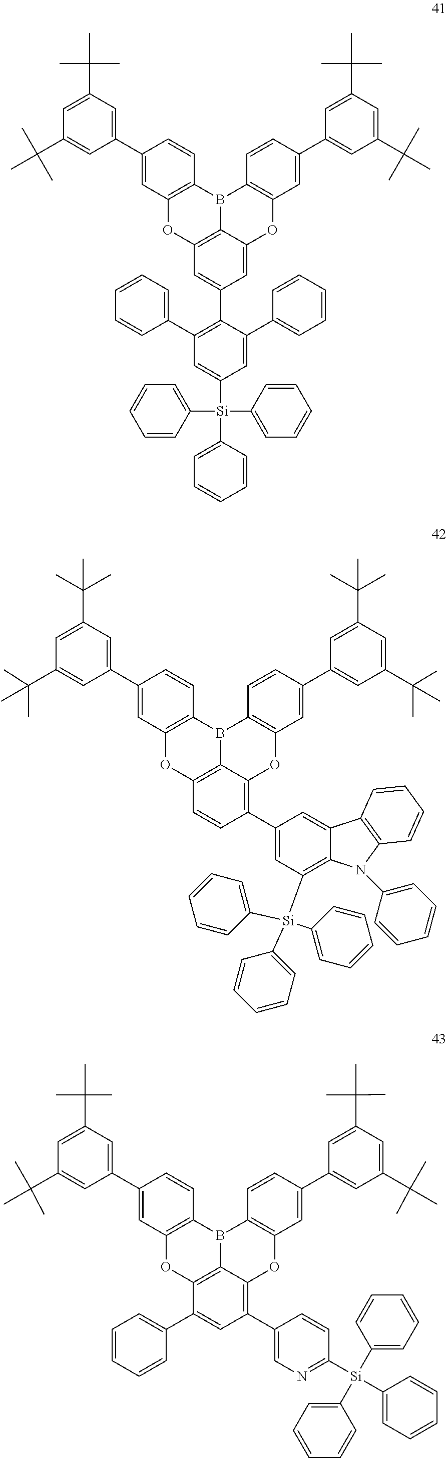 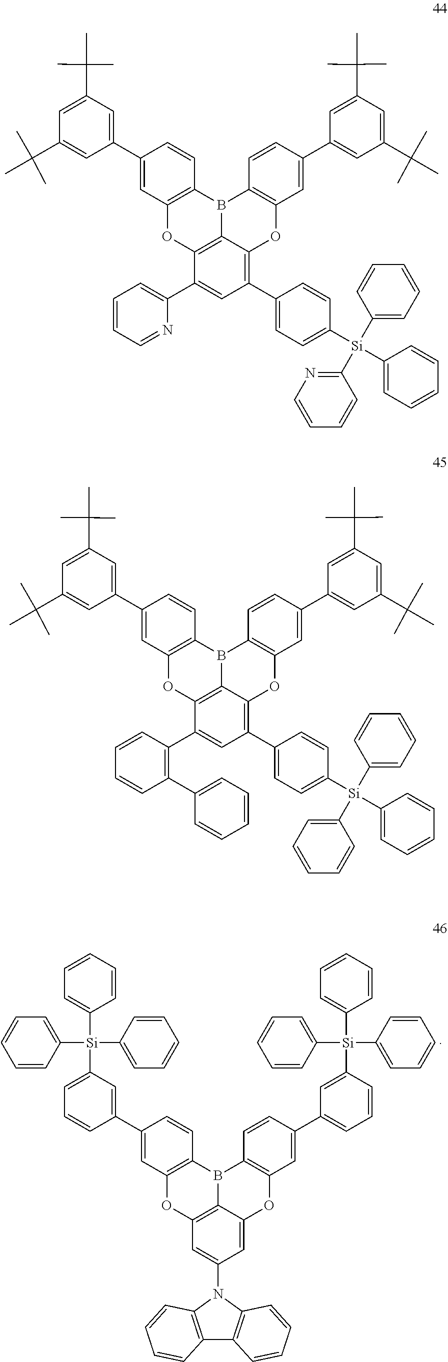 [SMILES: CC(C)(C)c1cc(-c2ccc3c(c2)Oc2c(-c4ccc([Si](c5ccccc5)(c5ccccc5)c5ccccn5)cc4)cc(-c4ccccn4)c4c2B3c2ccc(-c3cc(C(C)(C)C)cc(C(C)(C)C)c3)cc2O4)cc(C(C)(C)C)c1 ; CC(C)(C)c1cc(-c2ccc3c(c2)Oc2c(-c4ccc([Si](c5ccccc5)(c5ccccc5)c5ccccc5)cc4)cc(-c4ccccc4-c4ccccc4)c4c2B3c2ccc(-c3cc(C(C)(C)C)cc(C(C)(C)C)c3)cc2O4)cc(C(C)(C)C)c1 ; c1ccc([Si](c2ccccc2)(c2ccccc2)c2cccc(-c3ccc4c(c3)Oc3cc(-n5c6ccccc6c6ccccc65)cc5c3B4c3ccc(-c4cccc([Si](c6ccccc6)(c6ccccc6)c6ccccc6)c4)cc3O5)c2)cc1]
